(19) United States
(12) Patent Application Publication
(10) Pub. No.: US 2023/0309356 A1
(43) Pub. Date: Sep. 28, 2023

(54) DISPLAY PANEL AND ELECTRONIC DEVICE INCLUDING THE SAME

(71) Applicant: Samsung Display Co., Ltd., Yongin-si (KR)

(72) Inventors: SUYEON YUN, Yongin-si (KR); HYE WON JANG, Yongin-si (KR); XINXING LI, Yongin-si (KR); DONG-HYUN KIM, Yongin-si (KR); SEUNG-LYONG BOK, Yongin-si (KR); YOUNG-CHEOL JEONG, Yongin-si (KR)

(21) Appl. No.: 18/186,761

(22) Filed: Mar. 20, 2023

(30) Foreign Application Priority Data
Mar. 23, 2022 (KR) 10-2022-0036072

(51) Int. Cl. H10K 59/35

(52) U.S. Cl. CPC H10K 59/353; H10K 59/352; H10K 59/351; H10K 2102/311

(57) ABSTRACT

A display panel includes: a plurality of unit pixels, each of the plurality of unit pixels including a plurality of sub-pixels. Each of the sub-pixels includes a light emission pattern to emit light; the sub-pixels of one of the unit pixels includes one red sub-pixel, one blue sub-pixel, and two green sub-pixels; each of the blue sub-pixel and the red sub-pixel has a triangular shape; and a light emission area of each of the green sub-pixels is smaller than a light emission area of the blue sub-pixel.

### CROSS-REFERENCE TO RELATED APPLICATIONS

This application claims priority to and the benefit of Korean Patent Application No. 10-2022-0036072, filed on Mar. 23, 2022, the entire content of which is incorporated by reference herein.

### BACKGROUND

### 1. Field

Aspects of embodiments of the present disclosure relate to a display panel, and an electronic device including the display panel.

### 2. Description of the Related Art

An electronic device may be a device composed of various electronic components, such as a display panel and an electronic module. The electronic module may include a camera, an infrared sensing sensor, a proximity sensor, or the like. The electronic module may be disposed below the display panel. A transmittance of some regions of the display panel may be higher than the transmittance of other regions of the display panel. The electronic module may receive an external input through some regions of the display panel, or may provide an output through some regions of the display panel.

The above information disclosed in this Background section is for enhancement of understanding of the background of the present disclosure, and therefore, it may contain information that does not constitute prior art.

### SUMMARY

One or more embodiments of the present disclosure are directed to a display panel having improved visibility, and improved color reproducibility.

According to one or more embodiments of the present disclosure, a display panel includes: a plurality of unit pixels, each of the plurality of unit pixels including a plurality of sub-pixels. Each of the sub-pixels includes a light emission pattern configured to emit light; the sub-pixels of one of the unit pixels include one red sub-pixel, one blue sub-pixel, and two green sub-pixels; each of the blue sub-pixel and the red sub-pixel has a triangular shape; and a light emission area of each of the green sub-pixels is smaller than a light emission area of the blue sub-pixel.

In an embodiment, the blue sub-pixel and at least one of the green sub-pixels may include sides facing each other, and the sides may be parallel to each other.

In an embodiment, the blue sub-pixel may have a right triangle shape.

In an embodiment, the green sub-pixels may have shapes line-symmetrical to each other.

In an embodiment, the green sub-pixels may have the same shape as each other.

In an embodiment, each of the green sub-pixels may have a triangular shape.

In an embodiment, the red sub-pixel and the blue sub-pixel may have the same shape as each other.

In an embodiment, the blue sub-pixel and the red sub-pixel may have shapes point-symmetrical to each other.

In an embodiment, the green sub-pixels may have quadrangular shapes that are in a relationship line-symmetrical to each other.

In an embodiment, the green sub-pixels may have different areas from each other.

In an embodiment, each of the green sub-pixels may have a rectangular shape having long sides extending in one direction.

In an embodiment, the unit pixels may be located along a diagonal direction.

In an embodiment, the green sub-pixels may include a first sub-pixel and a second sub-pixel located along one direction crossing the diagonal direction, the first sub-pixel and a blue sub-pixel of another adjacent unit pixel may be located along the diagonal direction, and the first sub-pixel and a red sub-pixel of another adjacent unit pixel may be located along a direction perpendicular to the diagonal direction.

According to one or more embodiments of the present disclosure, a display panel includes: a plurality of unit pixels, each of the unit pixels including a plurality of sub-pixels. Each of the sub-pixels includes a light emission pattern configured to emit light; the sub-pixels of one of the unit pixels include one red sub-pixel, one green sub-pixel, one blue sub-pixel, and three white sub-pixels; and the red sub-pixel, the green sub-pixel, and the blue sub-pixel respectively surround the white sub-pixels.

In an embodiment, each of the white sub-pixels may include a red light emission region, a green light emission region, and a blue light emission region.

In an embodiment, the red sub-pixel, the green sub-pixel, and the blue sub-pixel may be located along one direction, and the red light emission region, the green light emission region, and the blue light emission region may be located along another direction crossing the one direction.

In an embodiment, each of the white sub-pixels may include two light emission regions, and the two light emission regions may have a color different from a color of a surrounding sub-pixel from among the red sub-pixel, the green sub-pixel, and the blue sub-pixel.

In an embodiment, each of the white sub-pixels may include a light emission element including a plurality of light emission patterns that overlap with each other.

In an embodiment, each of the white sub-pixels may have a circular shape, and each of the red sub-pixel, the green sub-pixel, and the blue sub-pixel may have a circular ring shape.

In an embodiment, each of the white sub-pixels may have a polygonal shape, and each of the red sub-pixel, the green sub-pixel, and the blue sub-pixel may have a polygonal ring shape.

### BRIEF DESCRIPTION OF THE DRAWINGS

The above and other aspects and features of the present disclosure will be more clearly understood from the following detailed description of the illustrative, non-limiting embodiments with reference to the accompanying drawings. In the drawings:

FIG. 1A-FIG. 1B are perspective views of an electronic device according to an embodiment of the present disclosure;

FIG. 2A is an exploded perspective view of an electronic device according to an embodiment of the present disclosure;

FIG. 2B is a block diagram of an electronic device according to an embodiment of the present disclosure;

FIG. 3 is a plan view of a display panel according to an embodiment of the present disclosure;

FIG. 4 is a plan view illustrating an enlarged view of the region XX′ illustrated in FIG. 3;

FIG. 5A-FIG. 5C are cross-sectional views of a display panel according to one or more embodiments of the present disclosure;

FIG. 6A-FIG. 6C are plan views illustrating pixel structures according to one or more embodiments of the present disclosure;

FIG. 7A-FIG. 7C are plan views illustrating pixel structures according to one or more embodiments of the present disclosure;

FIG. 8A-FIG. 8C are plan views illustrating pixel structures according to one or more embodiments of the present disclosure;

FIG. 9A-FIG. 9B are plan views illustrating pixel structures according to one or more embodiments of the present disclosure;

FIG. 10A-FIG. 10C are plan views illustrating pixel structures according to one or more embodiments of the present disclosure;

FIG. 11A is a plan view illustrating pixel structures according to an embodiment of the present disclosure;

FIG. 11B-FIG. 11D are plan views illustrating pixel electrodes of a pixel structure illustrated in FIG. 11A;

FIG. 12A-FIG. 12G are plan views illustrating pixel structures according to one or more embodiments of the present disclosure;

FIG. 13A-FIG. 13B are plan views illustrating pixel structures according to one or more embodiments of the present disclosure;

FIG. 14A-FIG. 14B are plan views illustrating pixel structures according to one or more embodiments of the present disclosure;

FIG. 15A-FIG. 15B are plan views illustrating pixel structures according to one or more embodiments of the present disclosure;

FIG. 16A-FIG. 16B are plan views illustrating pixel structures of a display panel according to one or more embodiments of the present disclosure;

FIG. 17 is a plan view illustrating a pixel structure of a display panel according to an embodiment of the present disclosure;

FIG. 18A is a plan view illustrating a pixel structure of a comparative example;

FIG. 18B is a plan view illustrating the pixel structure illustrated in FIG. 17;

FIG. 19A-FIG. 19C are plan views illustrating pixel structures according to one or more embodiments of the present disclosure;

FIG. 20A-FIG. 20E are plan views illustrating pixel structures according to one or more embodiments of the present disclosure;

FIG. 21A-FIG. 21D are plan views illustrating pixel structures according to one or more embodiments of the present disclosure;

FIG. 22A-FIG. 22D are plan views illustrating pixel structures according to one or more embodiment of the present disclosure;

FIG. 23A-FIG. 23D are plan views illustrating pixel structures according to one or more embodiments of the present disclosure;

FIG. 24A-FIG. 24B are plan views illustrating unit pixels according to one or more embodiments of the present disclosure; and

FIG. 25A-FIG. 25C are plan views illustrating unit pixels according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

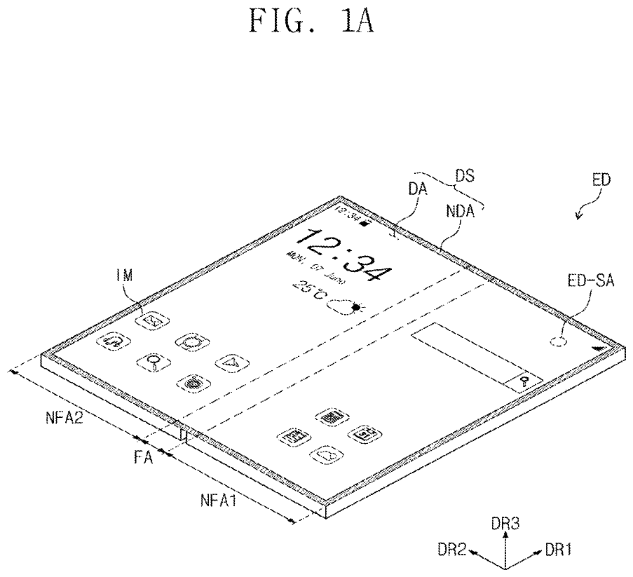

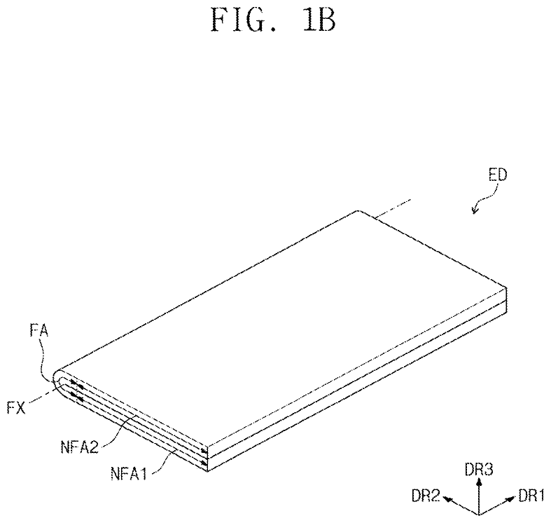

FIG. 1A and FIG. 1B are perspective views of an electronic device ED according to an embodiment of the present disclosure. FIG. 1A illustrates the electronic device ED in an unfolded state, and FIG. 1B illustrates the electronic device ED in a folded state.

Referring to FIG. 1A and FIG. 1B, the electronic device ED according to an embodiment of the present disclosure may include a display surface DS defined by a first direction DR1, and a second direction DR2 crossing the first direction DR1. The electronic device ED may provide an image IM to a user through the display surface DS.

The display surface DS may include a display region DA, and a non-display region NDA around (e.g., adjacent to) the display region DA. The display region DA may display the image IM, and the non-display region NDA may not display the image IM. The non-display region NDA may surround (e.g., around a periphery of) the display region DA. However, the present disclosure is not limited thereto. The shape of the display region DA and the shape of the non-display region NDA may be variously modified as needed or desired.

Hereinafter, a direction that perpendicularly or substantially perpendicularly crosses a plane defined by the first direction DR1 and the second direction DR2 is defined as a third direction DR3. In addition, as used in the present disclosure, the expressions “on a plane” and “in a plan view” may be defined as a state viewed in or from the third direction DR3.

A sensing region ED-SA may be defined at (e.g., in or on) the display region DA. FIG. 1A illustrates one sensing region ED-SA as an example, but the number of the sensing region ED-SA is not limited thereto. The sensing region ED-SA may be a portion of the display region DA. Therefore, the electronic device ED may display an image through the sensing region ED-SA.

In a region overlapping with the sensing region ED-SA, an electronic module (e.g., an electronic element, component, or sensor) may be disposed. The electronic module may receive an external input transmitted through the sensing region ED-SA, and/or may provide an output through the sensing region ED-SA. For example, the electronic module may be a camera module (e.g., a camera), a sensor for measuring a distance, such as a proximity sensor, a sensor for recognizing a part of a user's body (e.g., such as a fingerprint, an iris, or a face), or a small lamp for outputting light, but the present disclosure is not particularly limited thereto. Hereinafter, for convenience, an example in which the electronic module overlapping with the sensing region ED-SA is the camera module will be described in more detail.

The electronic device ED may include a folding region FA, and a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2 in the second direction DR2. The folding region FA may be referred to as a foldable region, and the first and second regions NFA1 and NFA2 may be referred to as first and second non-foldable regions.

As illustrated in FIG. 1B, the folding region FA may be folded with respect to a folding axis FX that is parallel to or substantially parallel to the first direction DR1. When the electronic device ED is in a folded state, the folding region FA has a suitable curvature (e.g., a predetermined curvature), and a suitable radius of curvature (e.g., a predetermined radius of curvature). The first non-folding region NFA1 and the second non-folding region NFA2 may face each other, and the electronic device ED may be inner-folded, such that the display surface DS is not exposed to the outside.

In an embodiment of the present disclosure, the electronic device ED may be outer-folded, such that the display surface DS is exposed to the outside. In an embodiment of the present disclosure, the electronic device ED may be configured, such that an inner-folding or outer-folding operation may be alternatively repeated with an un-folding operation, but the present disclosure is not limited thereto. In an embodiment of the present disclosure, the electronic device ED may be configured to select one of the un-folding operation, the inner-folding operation, or the outer-folding operation.

A foldable electronic device ED has been described as an example with reference to FIGS. 1A and 1B, but the present disclosure is not limited to the foldable electronic device ED. For example, the various embodiments described hereinafter may be applied to an electronic device that does not include a folding region FA, for example, such as a rigid electronic device.

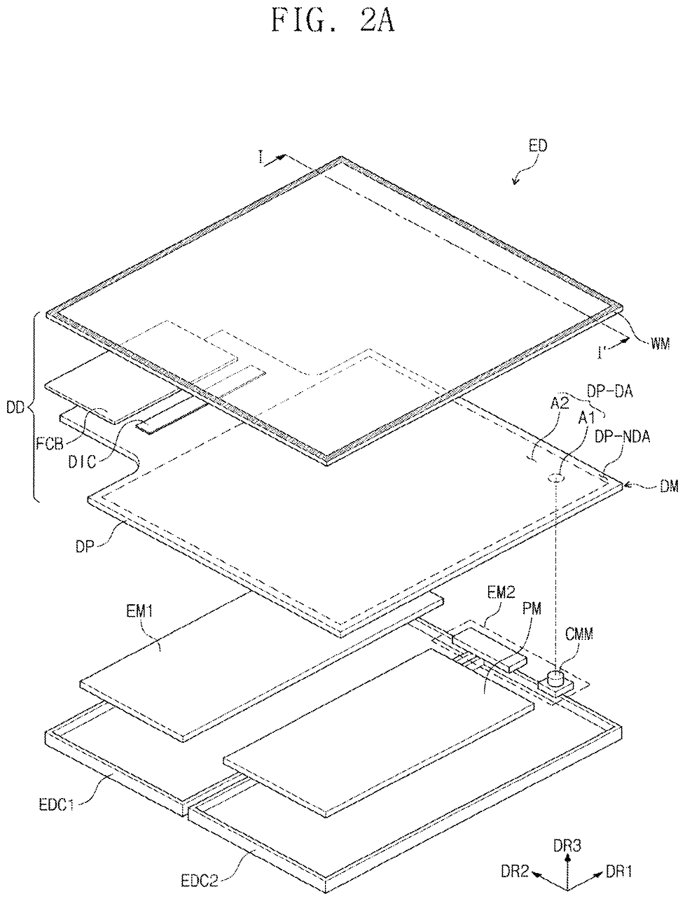

FIG. 2A is an exploded perspective view of the electronic device ED according to an embodiment of the present disclosure. FIG. 2B is a block diagram of the electronic device ED according to an embodiment of the present disclosure.

Referring to FIG. 2A and FIG. 2B, the electronic device ED may include a display device DD, a first electronic module (e.g., a first electronic component) EM1, a second electronic module (e.g., a second electronic component) EM2, a power supply module (e.g., a power supply) PM, and housings EDC1 and EDC2. The electronic device ED may further include instrument structures for controlling a folding operation of the display device DD.

The display device DD includes a window module (e.g., a window) WM and a display module (e.g., a display or a touch-display) DM. The window module WM provides a front surface of the electronic device ED. The display module DM may include at least a display panel DP. The display module DM generates images, and senses external inputs.

In FIG. 2A, for convenience of illustration, the display module DM is illustrated as being the same or substantially the same as the display panel DP, but the present disclosure is not limited thereto, and the display module DM may be a laminate structure or substantially a laminate structure, in which a plurality of components including the display panel DP are laminated. The laminated structure of the display module DM will be described in more detail below.

The display panel DP includes a display region DP-DA and a non-display region DP-NDA corresponding to the display region DA and the non-display region NDA (e.g., see FIG. 1A), respectively, of the electronic device ED. In the present disclosure, the expression “a region/portion corresponds to another region/portion” may mean that the region/portion overlaps with the other region/portion, but the regions/portions are not limited to having the same area.

The display region DP-DA may include a first region A1 and a second region A2. The first region A1 may overlap with or correspond to the sensing region ED-SA (e.g., see FIG. 1A) of the electronic device ED. In the present embodiment, the first region A1 is illustrated as having a circular shape, but the present disclosure is not limited thereto, and the first region A1 may have various suitable shapes, such as a polygon, an ellipse, a figure with at least one curved side, or an irregular shape, and is not limited to any particular embodiment. The first region A1 may be referred to as a component region, and the second region A2 may be referred to as a main display region or a general display region.

The first region A1 may have a higher transmittance than that of the second region A2. In addition, the resolution of the first region A1 may be lower than the resolution of the second region A2. The first region A1 may overlap with a camera module (e.g., a camera) CMM, which will be described in more detail below.

The display panel DP may include a display layer 100 and a sensor layer 200.

The display layer 100 may be a component that generates or substantially generates an image. The display layer 100 may be a light emission type display layer. For example, the display layer 100 may be an organic light emission display layer, an inorganic light emission display layer, an organic-inorganic display layer, a quantum-dot display layer, a micro-LED display layer, or a nano-LED display layer.

The sensor layer 200 may sense an external input applied from the outside. The external input may be a user input. The user input includes various suitable forms of external inputs, such as contact or a proximity of a part of a user's body or a pen, light, heat, pressure, and/or the like.

The display module DM may include a driving chip DIC disposed at (e.g., in or on) the non-display region DP-NDA. The display module DM may further include a flexible circuit film FCB connected to (e.g., attached to or coupled to) the non-display region DP-NDA.

The driving chip DIC may include driving elements, for example, such as a data driving circuit, for driving pixels of the display panel DP. FIG. 2A illustrates a structure in which the driving chip DIC is mounted on the display panel DP, but the present disclosure is not limited thereto. For example, the driving chip DIC may be mounted on the flexible circuit film FCB.

The power supply module PM supplies power used for the overall operation of the electronic device ED. The power supply module PM may include a battery module (e.g., a battery).

The first electronic module EM1 and the second electronic module EM2 include various suitable functional modules for operating the electronic device ED. The first electronic module EM1 and the second electronic module EM2 may each be directly mounted on a mother board electrically connected to the display panel DP, or may be mounted on a separate substrate and electrically connected to the mother board through a connector and the like.

The first electronic module EM1 may include a control module (e.g., a controller) CM, a wireless communication module (e.g., a wireless communication device) TM, an image input module (e.g., an image input device) IIM, a sound input module (e.g., a sound input device) AIM, a memory MM, and an external interface IF.

The control module CM controls the overall operation of the electronic device ED. The control module CM may be a microprocessor. For example, the control module CM may activate and/or deactivate the display panel DP. The control module CM may control the other modules, such as the image input module IIM and/or the sound input module AIM, on the basis of a touch signal received from the display panel DP.

The wireless communication module TM may communicate with an external electronic device through a first network (e.g., a near-field communication network such as Bluetooth, Wi-Fi direct, or infrared data association (IrDA)) or a second network (e.g., a telecommunication network such as a cellular network, the Internet, or a computer network (e.g., LAN or WAN)). Communication modules included in the wireless communication module TM may be integrated into one element (e.g., a single chip), or may be implemented as a plurality of elements (e.g., a plurality of chips). The wireless communication module TM may transmit/receive voice signals using a general communication line. The wireless communication module TM may include a transmittance unit (e.g., a transmitter) TM1 for modulating and then transmitting a signal, and a reception unit (e.g., a receiver) TM2 for demodulating a received signal.

The image input module IIM processes an image signal, and converts the processed image signal into image data displayable on the display panel DP. The sound input module AIM receives an external sound signal through a microphone in a recording mode, a voice recognition mode, and the like, and converts the received external sound signal into electrical voice data.

The external interface IF may include a connector that may physically connect the electronic device ED and an external electronic device to each other. For example, the external interface IF serves as an interface to be connected to an external charger, a wired/wireless data port, a card socket (e.g., a memory card, and/or a SIM/UIM card), and/or the like.

The second electronic module EM2 may include a sound output module (e.g., a sound output device) AOM, a light emission module (e.g., a light emission device) LTM, a light receiving module (e.g., a light receiving device) LRM, a camera module (e.g., a camera) CMM, and the like. The sound output module AOM converts sound data received from the wireless communication module TM or sound data stored in the memory MM, and then outputs the converted sound data to the outside.

The light emission module LTM generates and outputs light. The light emission module LTM may output an infrared ray. The light emission module LTM may include an LED element. The light receiving module LRM may sense an infrared ray. The light receiving module LRM may be activated when an infrared ray of a suitable level (e.g., a predetermined level or higher) is sensed. The light receiving module LRM may include a CMOS sensor. After generated infrared light is output from the light emission module LTM, the infrared light may be reflected by an external object (e.g., such as a user's finger or face), and the reflected infrared light may be incident on the light receiving module LRM.

The camera module CMM may capture a still image and/or a moving image. The camera module CMM may be provided in a plurality. From among the plurality of camera modules CMM, some of the camera modules CMM may overlap with the first region A1. An external input (e.g., light) may be provided to the camera module CMM through the first region A1. For example, the camera module CMM may capture an external image by receiving natural light through the first region A1.

The housings EDC1 and EDC2 accommodate the display module DM, the first and second electronic modules EM1 and EM2, and the power supply module PM. The housings EDC1 and EDC2 protect the components accommodated in the housings EDC1 and EDC2, such as the display module DM, the first and second electronic modules EM1 and EM2, and the power supply module PM. FIG. 2A illustrates two housings EDC1 and EDC2 that are separated from each other as an example, but the present disclosure is not limited thereto. In some embodiments, the electronic device ED may further include a hinge structure for connecting the housings EDC1 and EDC2 to each other. The housings EDC1 and EDC2 may be connected to (e.g., attached to or coupled to) the window module WM.

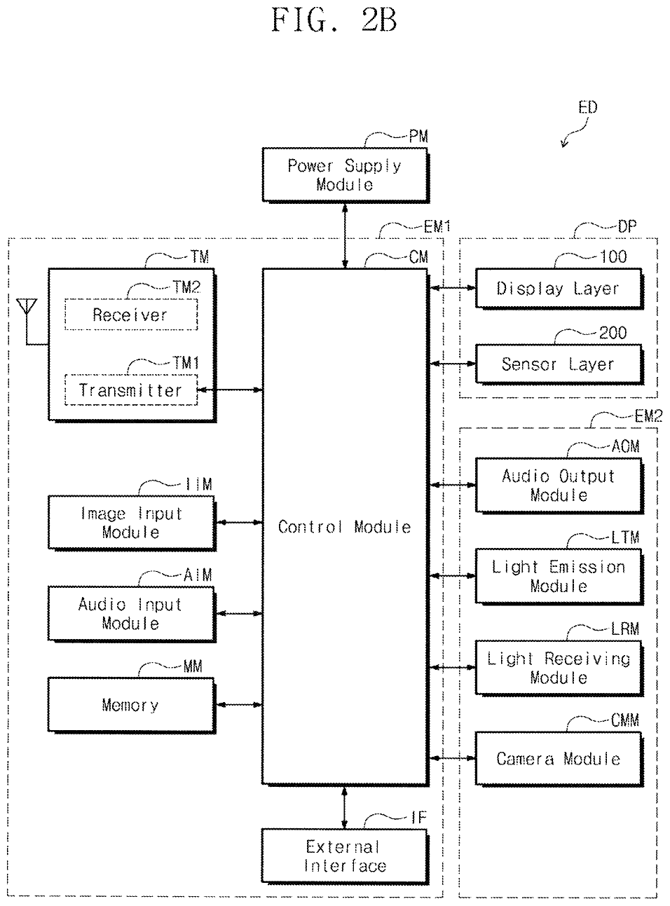

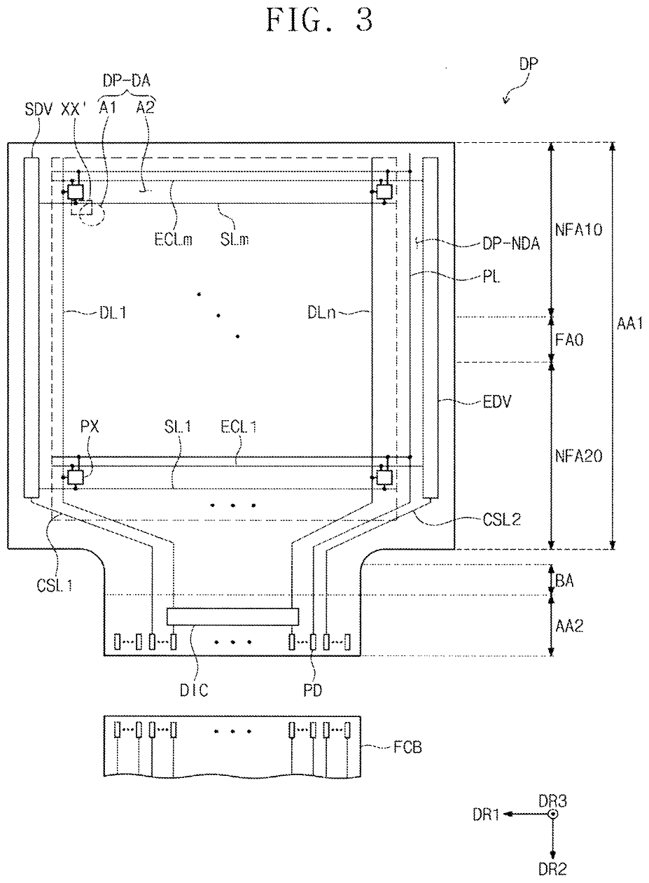

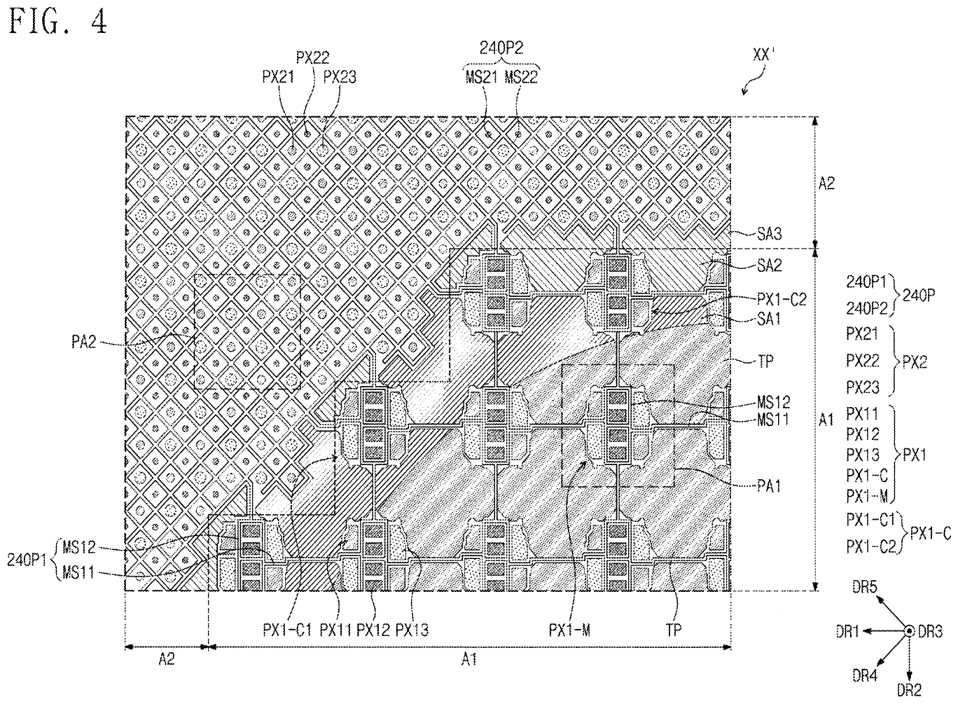

FIG. 3 is a plan view of the display panel DP according to an embodiment of the present disclosure. FIG. 4 is a plan view illustrating an enlarged view of the region XX′ illustrated in FIG. 3. Hereinafter, embodiments of the present disclosure will be described in more detail with reference to FIG. 3 and FIG. 4.

Referring to FIG. 3, in the display panel DP, the display region DP-DA, and the non-display region DP-NDA around (e.g., adjacent to) the display region DP-DA may be defined. The display region DP-DA and the non-display region DP-NDA may be divided according to the presence of a pixel PX. The pixel PX is disposed at (e.g., in or on) the display region DP-DA. A scan driver SDV, a data driver, and a light emission driver EDV may be disposed at (e.g., in or on) the non-display region DP-NDA. The data driver may be a circuit configured in the driving chip DIC.

The display region DP-DA may include the first region A1 and the second region A2. The first region A1 and the second region A2 may be divided according to an arrangement interval of the pixel PX, a size of the pixel PX, or the presence of a transmissive region TP. The first region A1 and the second region A2 will be described in more detail below.

The display panel DP may include a first panel region AA1, a bending region BA, and a second panel region AA2, which are defined along the second direction DR2. The second panel region AA2 and the bending region BA may be some regions of the non-display region DP-NDA. The bending region BA is disposed between the first panel region AA1 and the second panel region AA2.

The first panel region AA1 is a region corresponding to the display surface DS of FIG. 1A. The first panel region AA1 may include a first non-folding region NFA10, a second non-folding region NFA20, and a folding region FA0. The first non-folding region NFA10, the second non-folding region NFA20, and the folding region FA0 correspond to the first non-folding region NFA1, the second non-folding region NFA2, and the folding region FA, respectively, illustrated in FIG. 1A and FIG. 1B.

The bending region BA may correspond to a region that is to be bent when the electronic device ED is assembled. Because the display panel DP is provided with the bending region BA, the electronic device ED having a narrower bezel may be easily implemented.

The width (or length) of the bending region BA and the width (or length) of the second panel region AA2, which are parallel to or substantially parallel to the first direction DR1, may be smaller than the width (or length) of the first panel region AA1 that is parallel to or substantially parallel to the first direction DR1. A region having a short length in a bending axis direction may be more easily bent.

The display panel DP may include the plurality of pixels PX, a plurality of scan lines SL1 to SLm, a plurality of data lines DL1 to DLn, a plurality of light emission lines ECL1 to ECLm, first and second control lines CSL1 and CSL2, a driving voltage line PL, and a plurality of pads PD. Here, m and n are natural numbers. The pixels PX may be connected to the scan lines SL1 to SLm, the data lines DL1 to DLn, and the light emission lines ECL1 to ECLm.

The scan lines SL1 to SLm may be extended in the first direction DR1, and may be electrically connected to the scan driver SDV. The data lines DL1 to DLn may be extended in the second direction DR2, and may be electrically connected to the driving chip DIC via the bending region BA. The light emission lines ECL1 to ECLm may be extended in the first direction DR1, and may be electrically connected to the light emission driver EDV.

The driving voltage line PL may include a portion extended in the first direction DR1, and a portion extended in the second direction DR2. The portion extended in the first direction DR1 and the portion extended in the second direction DR2 may be disposed at (e.g., in or on) different layers from each other. The portion of the driving voltage line PL extended in the second direction DR2 may be extended to the second panel region AA2 via the bending region BA. The driving voltage line PL may provide a first voltage to the pixels PX.

The first control line CSL1 may be connected to the scan driver SDV, and may be extended toward a lower end of the second panel region AA2 via the bending region BA. The second control line CSL2 may be connected to the light emission driver EDV, and may be extended toward the lower end of the second panel region AA2 via the bending region BA.

When viewed on a plane (e.g., in a plan view), the pads PD may be disposed to be adjacent to the lower end of the second panel region AA2. The driving chip DIC, the driving voltage line PL, the first control line CSL1, and the second control line CSL2 may be electrically connected to the pads PD. The flexible circuit film FCB may be electrically connected to the pads PD through an anisotropic conductive adhesive layer.

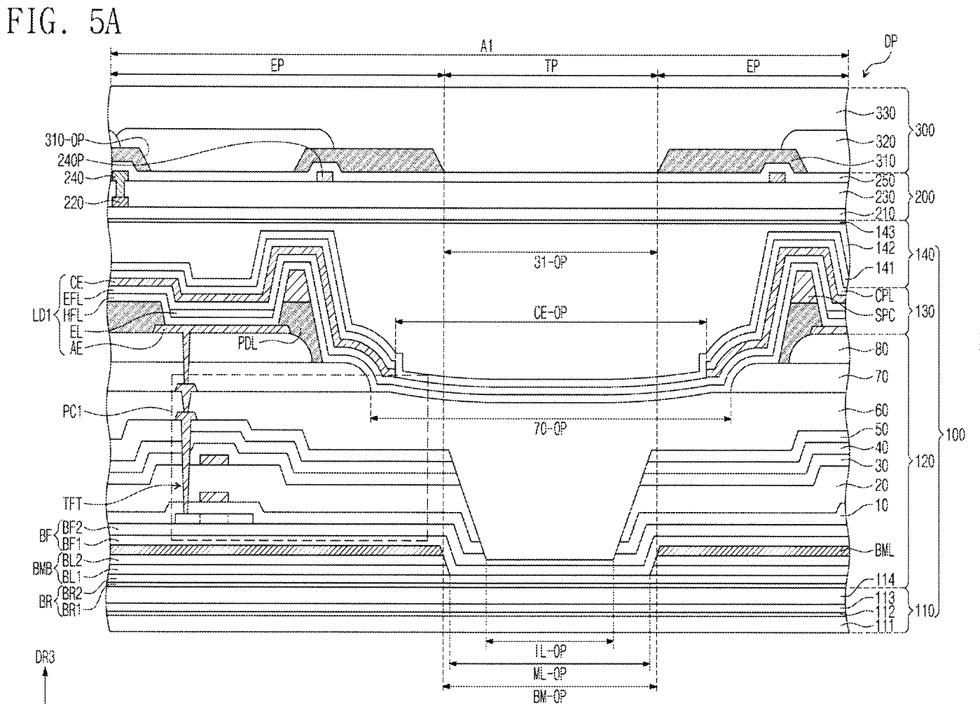

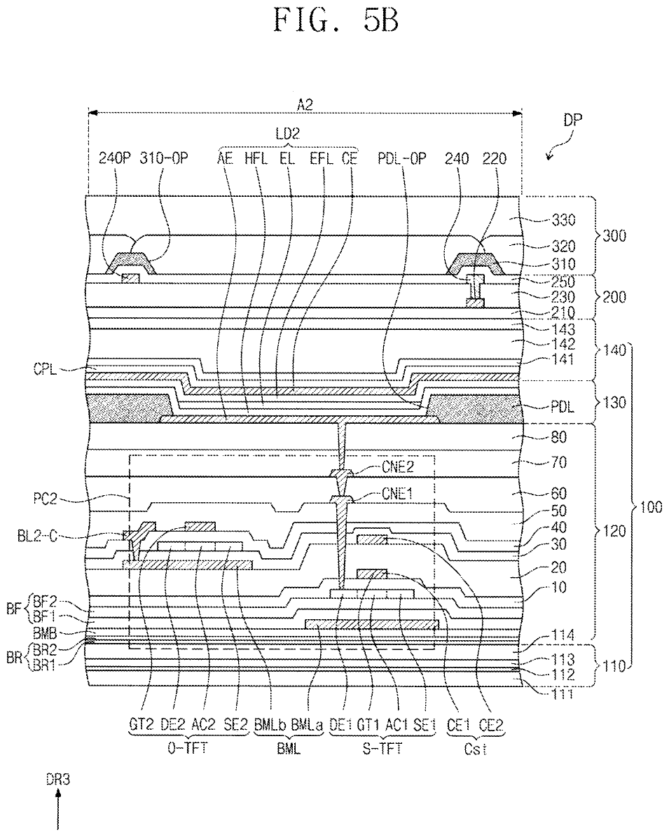

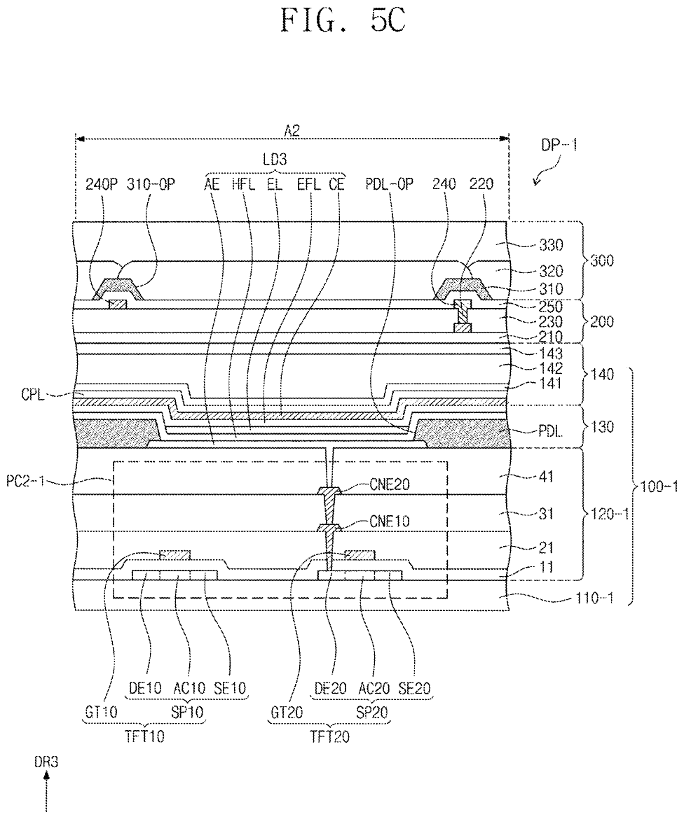

Referring to FIG. 4, the pixels PX are provided in a plurality, and the plurality of pixels PX may include a first pixel group PX1 disposed in the first region A1 and a second pixel group PX2. The first pixel group PX1 is composed of a plurality of first pixels PX11, PX12, and PX13. The second pixel group PX2 may include a plurality of second pixels PX21, PX22, and PX23 disposed in the second region A2. A planar shape of each of the plurality of first pixels PX11, PX12, and PX13 and the plurality of second pixels PX21, PX22, and PX23 illustrated in FIG. 4 may correspond to a light emission area of one corresponding light emission element LD1 (e.g., see FIG. 5A) or LD2 (e.g., see FIG. 5B).

A number (e.g., a first number) of the plurality of first pixels PX11, PX12, and PX13 disposed in a region (e.g., a predetermined region) PA1 may be smaller than a number (e.g., a second number) of the plurality of second pixels PX21, PX22, and PX23 disposed in a region (e.g., a predetermined region) PA2. Therefore, the resolution of the first region A1 may be lower than the resolution of the second region A2. The region PA1 displayed in the first region A1 and the region PA2 displayed in the second region A2 may be regions having the same or substantially the same shape and the same or substantially the same size as each other. For example, the first number may be 8, and the second number may be 25. However, the present disclosure is not limited thereto, and the first number and the second number may be variously modified as needed or desired.

In the plan view shown in FIG. 4, the pixels PX11, PX12, PX13, PX21, PX22, PX23 may correspond to a plurality of light emission regions, respectively, in which each of the pixels PX11, PX12, PX13, PX21, PX22, PX23 emit light. In addition, in a pixel structure described in more detail below, the corresponding pixels may correspond to sub-pixels. This will be described in more detail below.

The plurality of first pixels PX11, PX12, and PX13 may include a first red pixel PX11, a first green pixel PX12, and a first blue pixel PX13. The plurality of second pixels PX21, PX22, and PX23 may include a second red pixel PX21, a second green pixel PX22, and a second blue pixel PX23.

A plurality of transmissive regions TP may be defined at (e.g., in or on) the first region A1 of the display panel DP. The transmission regions TP may be defined to be spaced apart from each other at (e.g., in or on) the first region A1. Two first red pixels PX11, four first green pixels PX12, and two first blue pixels PX13 may be defined as one group, and at least a portion of the one group may be adjacent to one transmissive region TP. As the transmissive regions TP are defined at (e.g., in or on) the first region A1, the transmittance of the first region A1 may be higher than the transmittance of the second region A2.

The first region A1 may include the transmissive regions TP, and a first sub-region SA1 and a second sub-region SA2 adjacent thereto. The transmittance of the transmissive regions TP may be higher than the transmittances of the first sub-region SA1 and the second sub-region SA2.

For example, the first sub-region SA1 may be a portion covered by a partition layer 310 (e.g., see FIG. 5A). In addition, the second sub-region SA2 may be entirely covered by the partition layer 310 (e.g., see FIG. 5A). Therefore, the second sub-region SA2 and the first sub-region SA1 may not transmit light, and may have a transmittance lower than that of the transmissive region TP. In FIG. 4, for convenience of illustration, different hatchings are used to mark the transmissive region TP and the first sub-region SA1 to distinguish one from the other. In addition, in FIG. 4, a different hatching is used to mark the second sub-region SA2 to distinguish the second sub-region SA2 from the other regions.

The second sub-region SA2 may be adjacent to the second region A2. For example, the second sub-region SA2 may contact the boundary between the first region A1 and the second region A2. The second sub-region SA2 may be defined at (e.g., in or on) the first region A1 between the first pixels PX11, PX12, and PX13 and the second pixels PX21, PX22, and PX23. Therefore, the second sub-region SA2 may be adjacent to a pixel group disposed at (e.g., in or on) the first region A1, and a pixel group disposed at (e.g., in or on) the second region A2. The area of the second sub-region SA2 may be smaller than the area of the transmissive region TP.

In the second region A2 of the display panel DP, even in a portion adjacent to the first region A1, a boundary region in which the second pixels PX21, PX22, and PX23 are not disposed may be defined. A third sub-region SA3 may be disposed at (e.g., in or on) the second region A2 in a portion adjacent to the first region A1. The third sub-region SA3 may contact the boundary between the first region A1 and the second region A2. The third sub-region SA3 may have a shape that is connected to the second sub-region SA2 defined at (e.g., in or on) the first region A1.

A pixel definition film PDL (e.g., see FIG. 5A) may not be disposed at (e.g., in or on) the transmissive regions TP. The first sub-region SA1 may be a region that may not overlap with the pixel definition film PDL, but may overlap with the partition layer 310 (e.g., see FIG. 5A). The boundary between the transmissive region TP and the first sub-region SA1 may include a curved line. When the boundary between the transmissive region TP and the first sub-region SA1 are connected to one another, a circular shape may be derived. The second sub-region SA2 disposed at (e.g., in or on) the first region A1 and the third sub-region SA3 disposed at (e.g., in or on) the second region A2 may be regions overlapping with the pixel definition film PDL (e.g., see FIG. 5A). The transmissive region TP may be a region not overlapping with the pixel definition film PDL and the partition layer 310 (e.g., see FIG. 5A). However, the present disclosure is not limited thereto, and in a display panel according to an embodiment of the present disclosure, the pixel definition film PDL may be disposed both at (e.g., in or on) the first region A1 and the second region A2, and is not limited to any particular embodiment.

The second sub-region SA2 and the first sub-region SA1 are disposed at (e.g., in or on) the first region A1 adjacent to the second region A2, and the third sub-region SA3 is disposed at (e.g., in or on) the second region A2 adjacent to the first region A1. A region in which the second sub-region SA2 and the first sub-region SA1 are defined at (e.g., in or on) the first region A1, and a region in which the third sub-region SA3 is disposed at (e.g., in or on) the second region A2 may be defined as a boundary region. In the boundary region, two first red pixels PX11, four first green pixels PX12, and two first blue pixels PX13 may be disposed to be adjacent to each other, while forming one pixel group, and the one pixel group may be adjacent to at least one second sub-region SA1 and/or at least one first sub-region SA1, which are covered by the partition layer 310 (e.g., see FIG. 5A), and thus, have a relatively low light transmittance compared to the transmissive regions TP.

For example, the first pixel group PX1 disposed at (e.g., in or on) the first region A1 may include a connection portion pixel group PX1-C, and a central portion pixel group PX1-M. The central portion pixel group PX1-M may be a portion surrounded (e.g., around a periphery thereof) by the transmissive region TP, the first sub-region SA1, and the like. The connection pixel group PX1-C may include a first connection portion pixel group PX1-C1, and a second connection portion pixel group PX1-C2. The first connection portion pixel group PX1-C1 may have two sides that are adjacent to the second region A2, and the second connection portion pixel group PX1-C2 may have one side that is adjacent to the second region A2. The first connection portion pixel group PX1-C1 may be a pixel group disposed at a corner portion of the first region A1, and the second connection portion pixel group PX1-C2 may be a pixel group disposed at upper, lower, left, and right sides of the first region A1. The connection portion pixel group PX1-C is a pixel group disposed at a boundary portion, such that the first connection portion pixel group PX1-C1 may be a pixel group disposed at a corner portion in the boundary region, and the second connection portion pixel group PX1-C2 may be a pixel group disposed in upper, lower, left, and right sides of the boundary region.

In the second region A2, the second red pixel PX21 and the second green pixel PX22 may be arranged one by one alternately and repeatedly along each of a fourth direction DR4 and a fifth direction DR5. In addition, in the second region A2, the second blue pixel PX23 and the second green pixel PX22 may be arranged one by one alternately and repeatedly along each of the fourth direction DR4 and the fifth direction DR5. The fourth direction DR4 may be a direction between the first direction DR1 and the second direction, and the fifth direction DR5 may be a direction crossing (e.g., perpendicular to or substantially perpendicular to) the fourth direction DR4. Based on one second green pixel PX22, the second red pixel PX21 may be spaced apart in the fourth direction DR4, and the second blue pixel PX23 may be spaced apart in the fifth direction DR5.

In the second region A2, the second red pixel PX21 and the second blue pixel PX23 may be arranged one by one alternately and repeatedly along each of the first direction DR1 and the second direction DR2. The second green pixel PX22 may be arranged repeatedly along the first direction DR1 and the second direction DR2. The area of the first red pixel PX11 may be greater than the area of the second red pixel PX21. The area of the first green pixel PX12 may be greater than the area of the second green pixel PX22. The area of the first blue pixel PX13 may be greater than the area of the second blue pixel PX23. However, the present disclosure is not limited thereto, and the area relationships between the first red, first green, and first blue pixels PX11, PX12, and PX13 and the second red, second green, and second blue pixels PX21, PX22, and PX23 are not limited to the above-described example.

In addition, the shape of the first red pixel PX11 may be different from the shape of the second red pixel PX21. The shape of the first green pixel PX12 may be different from the shape of the second green pixel PX22. The shape of the first blue pixel PX13 may be different from the shape of the second blue pixel PX23. However, the present disclosure is not limited thereto, and the shapes of the first red, first green, and first blue pixels PX11, PX12, and PX13 may be the same or substantially the same as the shapes of the second red, second green, and second blue pixels PX21, PX22, and PX23, respectively.

In FIG. 4, a conductive pattern 240P constituting the sensor layer 200 (e.g., see FIG. 5A) is further illustrated. The conductive pattern 240P may include a first pattern 240P1 and a second pattern 240P2.

The first pattern 240P1 is disposed at (e.g., in or on) the transmissive region TP. The first pattern 240P1 may include a plurality of mesh lines. The first pattern 240P1 may include a plurality of first mesh lines MS11 extended in the first direction DR1, and a plurality of second mesh lines MS12 extended in the second direction DR2. The first mesh lines MS11 and the second mesh lines MS12 may be electrically connected to each other to configure one sensor pattern, and the sensor layer 200 may be provided with a plurality of sensor patterns to sense an external input applied to the transmissive region TP.

The first mesh lines MS11 and the second mesh lines MS12 may be disposed to not overlap with each of the pixels PX11, PX12, and PX13, which correspond to the light emission regions. Accordingly, it may be possible to prevent or substantially prevent display properties of a display panel from being degraded due to the sensor layer 200. However, the present disclosure is not limited thereto, and to the extent that the visibility of an image is not degraded, some of the first mesh lines MS11 and the second mesh lines MS12 may be disposed to overlap with some of the pixels PX11, PX12, and PX13, or when the first mesh lines MS11 and the second mesh lines MS12 are transparent, the first mesh lines MS11 and the second mesh lines MS12 may be disposed to overlap with the pixels PX11, PX12, and PX13, but the present disclosure is not limited thereto.

The second pattern 240P2 is disposed at (e.g., in or on) the second region A2. The second pattern 240P2 may include a plurality of mesh lines. The second pattern 240P2 may include a plurality of third mesh lines MS21 extended in the fourth direction DR4, and a plurality of fourth mesh lines MS22 extended in the fifth direction DR5. The third mesh lines MS21 and the fourth mesh lines MS22 may be electrically connected to each other to configure one sensor pattern, and the sensor layer 200 may be provided with a plurality of sensor patterns to sense an external input applied to the second region A2.

From among the first pattern 240P1 and the second pattern 240P2, patterns constituting the same electrode may be electrically connected to each other. For example, mesh lines passing through the second connection portion pixel group PX1-C2 are electrically connected to some of the fourth mesh lines MS22. Therefore, even or substantially even touch sensitivity may be provided to the entire or substantially entire surfaces of the first region A1 and the second region A2.

In FIG. 4, according to an embodiment of the present disclosure, the mesh lines constituting the first pattern 240P1 and the second pattern 240P2 are illustrated to have different shapes from each other. Accordingly, the arrangement shapes of the first pixel group PX1 and the second pixel group PX2 may be different from each other. However, the present disclosure is not limited thereto, and the first pixel group PX1 and the second pixel group PX2 may have the same or substantially the same form of arrangement, and accordingly, the mesh lines constituting the first pattern 240P1 and the second pattern 2402 may be provided in the same or substantially the same shape as each other. In addition, in FIG. 4, according to an embodiment of the present disclosure, the sensor layer 200 is illustrated as including the conductive pattern 240P composed of the mesh lines, but the present disclosure is not limited thereto, and the sensor layer 200 may include a transparent conductive pattern overlapping with the plurality of pixels PX1 and PX2, and is not limited to any particular embodiment.

FIG. 5A through FIG. 5C are cross-sectional views of a display panel according to one or more embodiments of the present disclosure. FIG. 5A illustrates a cross-sectional view of the first region A1 of the display panel DP according to an embodiment of the present disclosure, and in more detail, illustrates a cross-sectional view of a portion of a first light emission element LD1 and a first pixel circuit PC1 disposed at (e.g., in or on) the first region A1. FIG. 5B illustrates the second region A2 of the display panel DP according to an embodiment of the present disclosure, and in more detail, illustrates a cross-sectional view of a portion of a second light emission element LD2 and a second pixel circuit PC2 disposed at (e.g., in or on) the second region A2. FIG. 5C illustrates a cross-sectional view of the second region A2 of a display panel DP-1 according to an embodiment of the present disclosure. FIG. 5C illustrates a display panel including layered structures that may be different from those of FIG. 5B. Hereinafter, embodiments of the present disclosure will be described in more detail with reference to FIG. 5A through FIG. 5C.

Referring to FIG. 5A and FIG. 5B, the display panel DP may include the display layer 100, the sensor layer 200, and a refection prevention layer 300. The display layer 100 may include a substrate 110, a circuit layer 120, a light emission element layer 130, and an encapsulation layer 140.

The substrate 110 may include a plurality of layers 111, 112, 113, and 114. For example, the substrate 110 may include a first sub-base layer 111, a first intermediate barrier layer 112, a second intermediate barrier layer 113, and a second sub-base layer 114. The first sub-base layer 111, the first intermediate barrier layer 112, the second intermediate barrier layer 113, and the second sub-base layer 114 may be sequentially laminated in the third direction DR3.

The first sub-base layer 111 and the second sub-base layer 114 may each include at least one of a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. As used in the present disclosure, the expression “-based” resin means that a functional group of “ ” is included. A barrier layer BR may be disposed on the substrate 110. The barrier layer BR may include a first sub-barrier layer BR1 disposed on the substrate 110, and a second sub-barrier layer BR2 disposed on the first sub-barrier layer BR1.

The first and second intermediate barrier layers 112 and 113 and the first and second sub-barrier layers BR1 and BR2 may each include an inorganic matter. The first and second intermediate barrier layers 112 and 113 and the first and second sub-barrier layers BR1 and BR2 may each include at least one of silicon oxide, silicon nitride, silicon oxynitride, or amorphous silicon. For example, the first and second sub-base layers 111 and 114 may each include polyimide having a refractive index of approximately 1.9. The first intermediate barrier layer 112 and the first sub-barrier layer BR1 may each include silicon oxynitride (SiON) having a refractive index of approximately 1.72. The second intermediate barrier layer 113 and the second sub-barrier layer BR2 may each include silicon oxynitride (SiON) having a refractive index of approximately 1.5.

In other words, the refractive index of the first intermediate barrier layer 112 may have a value between the refractive index of the first sub-base layer 111 and the refractive index of the second intermediate barrier layer 113. The refractive index of the first sub-barrier layer BR1 may have a value between the refractive index of the second sub-base layer 114 and the refractive index of the second sub-barrier layer BR2. Because the difference in the refractive index between layers that are in contact with each other is reduced, a reflection at an interface between the layers that are in contact with each other may be reduced. As a result, the transmittance of light at the transmissive region TP may be improved.

The thickness of the first sub-base layer 111 may be greater than the thickness of the second sub-base layer 114, but the present disclosure is not limited thereto. The thickness of the first intermediate barrier layer 112 may be less than the thickness of the second intermediate barrier layer 113, and the thickness of the first sub-barrier layer BR1 may be less than the thickness of the second sub-barrier layer BR2. However, the thickness of each of the first and second intermediate barrier layers 112 and 113 and the first and second sub-barrier layers BR1 and BR2 is not limited thereto.

A light blocking layer BML may be disposed on the barrier layer BR. The light blocking layer BML may have an opening BM-OP (hereinafter, referred to as a first opening) that defines the transmissive region TP. In other words, in the present embodiment, the first opening BM-OP may correspond to the shape of the transmissive region TP.

The light blocking layer BML may be a pattern that serves as a mask when an electrode opening CE-OP is formed in a common electrode CE. For example, light irradiated from the rear surface of the substrate 110 toward the common electrode CE may pass through the first opening BM-OP, and may be incident at a portion of each of the common electrode CE and a capping layer CPL. In other words, by the light that has passed through the opening BM-OP of the light blocking layer BML, the portion of each of the common electrode CE and the capping layer CPL may be removed. The light may be a laser beam.

The light blocking layer BML may include molybdenum (Mo), an alloy containing molybdenum, silver (Ag), an alloy containing silver, aluminum (Al), an alloy containing aluminum, aluminum nitride (AlN), tungsten (W), tungsten nitride (WN), copper (Cu), titanium (Ti), p+-doped amorphous silicon, MoTaOx, and/or the like, but is not particularly limited thereto. The light blocking layer BML may be referred to as a rear surface metal layer, or a rear surface layer.

In the first region A1, a region overlapping with a portion overlapping with the first opening BM-OP may be defined as the transmissive region TP, and the other remaining regions may be defined as an element region EP. Each of the plurality of first pixels PX11, PX12, an PX13 (e.g., see FIG. 4) may be disposed at (e.g., in or on) the element region EP, and each of the plurality of first pixels PX11, PX12, an PX13 may be spaced apart from the transmissive region TP.

At least one lower insulation layer BMB may be disposed between the light blocking layer BML and the barrier layer BR. A lower insulation layer opening ML-OP overlapping with the first opening BM-OP may be defined in the at least one lower insulation layer BMB. The first opening BM-OP and the lower insulation layer opening ML-OP may be concurrently (e.g., simultaneously or substantially simultaneously) formed with each other through the same or substantially the same process. Therefore, a side wall of the light blocking layer BML defining the first opening BM-OP may be aligned or substantially aligned with a side wall of the lower insulation layer BMB defining the lower insulation layer opening ML-OP.

The first pixel circuit PC1 may be spaced apart from the first opening BM-OP of the light blocking layer BML and the lower insulation layer opening ML-OP of the lower insulation layer BMB. In other words, when viewed on a plane (e.g., in a plan view), the first pixel circuit PC1 may not overlap with either the first opening BM-OP of the light blocking layer BML or the lower insulation layer opening ML-OP of the lower insulation layer BMB.

The at least one lower insulation layer BMB may include a first lower insulation layer BL1 disposed between the barrier layer BR and the light blocking layer BML, and a second lower insulation layer BL2 disposed between the first lower insulation layer BL1 and the light blocking layer BML.

The first and second lower insulation layers BL1 and BL2 may each include an inorganic matter. For example, the first and second lower insulation layers BL1 and BL2 may each include at least one of silicon oxide, silicon nitride, silicon oxynitride, or amorphous silicon. For example, the first lower insulation layer BL1 may include silicon oxide having a refractive index of approximately 1.5, and the second lower insulation layer BL2 may include amorphous silicon having a refractive index of approximately 1.7.

The refractive index of the first lower insulation layer BL1 and the refractive index of the second lower insulation layer BL2 may be different from each other. For example, the refractive index of the first lower insulation layer BL1 may be lower than the refractive index of the second lower insulation layer BL2, but the present disclosure is not particularly limited thereto. For example, the refractive index of the first lower insulation layer BL1 may be higher than the refractive index of the second lower insulation layer BL2.

As the first and second lower insulation layers BL1 and BL2 are sequentially disposed on a lower portion of the light blocking layer BML, the reflectance in the light blocking layer BML may be reduced. For example, light incident toward the rear surface of the light blocking layer BML, or light reflected from the rear surface of the light blocking layer BML, may be destructively interfered with in the first and second lower insulation layers BL1 and BL2. As a result, a probability of a noise image, for example, such as a ghost phenomenon, occurring in an image obtained at the camera module CMM (e.g., see FIG. 2A) may be reduced or eliminated. Therefore, the quality of a signal obtained or received at the camera module CMM (e.g., see FIG. 2A) may be improved. The first and second lower insulation layers BL1 and BL2 may also be referred to as first and second noise prevention layers. For convenience of illustration, FIG. 5B illustrates a single lower insulation layer BMB, but this is provided as an example. The lower insulation layer BMB disposed at (e.g., in or on) the second region A2 may include the first and second lower insulation layers BL1 and BL2 like the first region A1, and is not limited to any particular embodiment.

The buffer layer BF may be disposed above the lower insulation layer BMB and the barrier layer BR, and may cover the light blocking layer BML. The buffer layer BF may prevent or substantially prevent metal atoms and/or impurities from diffusing into a first semiconductor pattern from the substrate 110. In addition, the buffer layer BF may control a rate of providing heat during a crystallization process for forming the first semiconductor pattern, thereby allowing the first semiconductor pattern to be uniformly or substantially uniformly formed.

The buffer layer BF may include a first sub-buffer layer BF1, and a second sub-buffer layer BF2 disposed on the first sub-buffer layer BF1. Each of the first sub-buffer layer BF1 and the second sub-buffer layer BF2 may include at least one of silicon oxide, silicon nitride, or silicon oxynitride. For example, the first sub-buffer layer BF1 may include silicon nitride, and the second sub-buffer layer BF2 may include silicon oxide.

In the present embodiment, a portion of the second sub-buffer layer BF2 may be removed from the first region A1. Therefore, the thickness of a portion of the second sub-buffer layer BF2 disposed at (e.g., in or on) the element region EP may be greater than the thickness of a portion of the second sub-buffer layer BF2 disposed at (e.g., in or on) the transmissive region TP. However, the present disclosure is not limited thereto, and the second sub-buffer layer BF2 may be provided to have a uniform or substantially uniform thickness in the entire region of the first region A1 and the second region A2, and is not limited to any particular embodiment.

The plurality of first pixels PX11, PX12, and PX13 (e.g., see FIG. 4) may each include a corresponding first light emission element LD1 and a corresponding first pixel circuit PC1. The plurality of second pixels PX21, PX22, and PX23 (e.g., see FIG. 4) may each include a corresponding second light emission element LD2 and a corresponding second pixel circuit PC2. The first light emission element LD1 may be disposed at (e.g., in or on) the element region EP in the first region A1, and the second light emission element LD2 may be disposed at (e.g., in or on) the second region A2. The second pixel circuit PC2 may include a silicon thin film transistor S-TFT and an oxide thin film transistor O-TFT.

A first light blocking layer BMLa may be disposed at (e.g., in or on) a lower portion of the silicon thin film transistor S-TFT, and a second light blocking layer BMLb may be disposed at (e.g., in or on) a lower portion of the oxide thin film transistor O-TFT. Each of the first light blocking layer BMLa and the second light blocking layer BMLb may be disposed to overlap with the second pixel circuit PC2 to protect the second pixel circuit PC2. The first light blocking layer BMLa and the second light blocking layer BMLb may not be disposed at (e.g., in or on) the first region A1.

The first and second light blocking layers BMLa and BMLb may block an electric potential due to a polarization of the first sub-base layer 111 or the second sub-base layer 114 from affecting the second pixel circuit PC2. In an embodiment of the present disclosure, the second light blocking layer BMLb may be omitted as needed or desired.

In the present embodiment, the first light blocking layer BMLa may be disposed on the lower insulation layer BMB. On the other hand, the first light blocking layer BMLa may be disposed in the second sub-barrier layer BR2. For example, a portion in a thickness direction of the second sub-barrier layer BR2 may be formed, and then a remaining portion in the thickness direction of the second sub-barrier layer BR2 may cover the first light blocking layer BMLa. However, the present disclosure is not limited thereto, and the first light blocking layer BMLa may be disposed at (e.g., in or on) various suitable positions, and is not limited to any particular embodiment.

The second light blocking layer BMLb may be disposed between a second insulation layer 20 and a third insulation layer 30. The second light blocking layer BMLb may be disposed at (e.g., in or on) the same layer as that of a second electrode CE2 of a storage capacitor Cst. The second light blocking layer BMLb may be connected to a contact electrode BL2-C to receive a constant or substantially constant voltage or a signal applied thereto. The contact electrode BL2-C may be disposed at (e.g., in or on) the same layer as that of a gate GT2 of the oxide thin film transistor O-TFT. The first and second light blocking layers BMLa and BMLb may include the same material as each other, or may include different metals from each other. However, the present disclosure is not limited thereto. The contact electrode BL2-C may be disposed at (e.g., in or on) the same layer as that of a first connection electrode CNE1 or a second connection electrode CNE2, which will be described in more detail below, and is not limited to any particular embodiment.

The first semiconductor pattern may be disposed on the buffer layer BF. The first semiconductor pattern may include a silicon semiconductor. For example, the silicon semiconductor may include amorphous silicon, polycrystalline silicon, and/or the like. For example, the first semiconductor pattern may include low temperature polysilicon.

For convenience of illustration, FIG. 5A and FIG. 5B illustrate a portion of the first semiconductor pattern disposed on the buffer layer BF, and the first semiconductor pattern may further be disposed at (e.g., in or on) another region. The first semiconductor pattern may be arranged according to a a suitable rule (e.g., a predetermined or specific rule) across the pixels. The first semiconductor pattern may have different electrical properties depending on whether or not the first semiconductor pattern is doped. The first semiconductor pattern may include a first region having a high conductivity rate, and a second region having a low conductivity rate. The first region may be doped with an N-type dopant or a P-type dopant. A P-type transistor may include a doped region that has been doped with the P-type dopant, and an N-type transistor may include a doped region that has been doped with the N-type dopant. The second region may be a non-doped region, or a region doped to a concentration lower than that of the first region.

The conductivity of the first region may be greater than the conductivity of the second region, and the first region may serve or substantially serve as an electrode or a signal line. The second region may correspond to or substantially correspond to an active region (e.g., a channel) of a transistor. In other words, a portion of a semiconductor pattern may be an active region of a transistor, another portion thereof may be a source or a drain of the transistor, and another portion thereof may be a connection electrode or a connection signal line.

A source region SE1, an active region AC1, and a drain region DE1 of the silicon thin film transistor S-TFT may be formed from the first semiconductor pattern. The source region SE1 and the drain region DE1 may be extended in opposite directions from the active region AC1 in a cross section.

The circuit layer 120 may include a plurality of inorganic insulation layers disposed on the light blocking layer BML. In an embodiment, at least some of a first insulation layer 10 to a fifth insulation layer 50 that are sequentially laminated on the buffer layer BF may be inorganic insulation layers. For example, the first insulation layer 10 to the fifth insulation layer 50 may all be inorganic insulation layers.

The first insulation layer 10 may be disposed on the buffer layer BF. The first insulation layer 10 commonly overlaps with a plurality of pixels, and may cover the first semiconductor pattern. The first insulation layer 10 may be an inorganic layer and/or an organic layer, and may have a single-layer structure or a multi-layered structure. The first insulation layer 10 may include at least one of an aluminum oxide, a titanium oxide, a silicon oxide, a silicon nitride, a silicon oxynitride, a zirconium oxide, or a hafnium oxide. In the present embodiment, the first insulation layer 10 may be a single layer silicon oxide layer. In addition to the first insulation layer 10, an insulation layer of the circuit layer 120 described in more detail below may also have a single-layer structure or a multi-layered structure.

A gate GT1 of the silicon thin film transistor S-TFT is disposed on the first insulation layer 10. The gate GT1 may be a portion of a metal pattern. The gate GT1 overlaps with the active region AC1. In a process of doping the first semiconductor pattern, the gate GT1 may function as a mask. The gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), and/or the like, but is not particularly limited thereto.

The second insulation layer 20 is disposed on the first insulation layer 10, and may cover the gate GT1. The second insulation layer 20 may be an inorganic layer, and may have a single-layer structure or a multi-layered structure. The second insulation layer 20 may include at least one of a silicon oxide, a silicon nitride, or a silicon oxynitride. In the present embodiment, the second insulation layer 20 may have a multi-layered structure including a silicon oxide layer and a silicon nitride layer.

The third insulation layer 30 may be disposed on the second insulation layer 20. The third insulation layer 30 may be an inorganic layer, and may have a single-layer structure or a multi-layered structure. For example, the third insulation layer 30 may have a multi-layered structure including a silicon oxide layer and a silicon nitride layer. The second electrode CE2 of the storage capacitor Cst may be disposed between the second insulation layer 20 and the third insulation layer 30. In addition, a first electrode CE1 of the storage capacitor Cst may be disposed between the first insulation layer 10 and the second insulation layer 20.

A second semiconductor pattern may be disposed on the third insulation layer 30. The second semiconductor pattern may include an oxide semiconductor. The oxide semiconductor may include a plurality of regions that are distinguished according to whether a metal oxide has been reduced or not. A region in which the metal oxide has been reduced (hereinafter, referred to as a reduction region) has greater conductivity than a region in which the metal oxide has not been reduced (hereinafter, referred to as a non-reduction region). The reduction region serves or substantially serves as a source/drain or signal line of a transistor. The non-reduction region corresponds to or substantially corresponds to an active region (e.g., a semiconductor region, a channel, or the like) of a transistor. In other words, a portion of the second semiconductor pattern may be an active region of a transistor, another portion thereof may be a source/drain region of the transistor, and another portion thereof may be a signal transmissive region.

A source region SE2, an active region AC2, and a drain region DE2 of the oxide thin film transistor O-TFT may be formed from the second semiconductor pattern. The source region SE2 and the drain region DE2 may be extended in opposite directions from the active region AC2 in a cross section.

A fourth insulation layer 40 may be disposed on the third insulation layer 30. The fourth insulation layer 40 commonly overlaps with a plurality of pixels, and may cover the second semiconductor pattern. The fourth insulation layer 40 may be an inorganic layer, and may have a single-layer structure or a multi-layered structure. The fourth insulation layer 40 may include at least one of an aluminum oxide, a titanium oxide, a silicon oxide, a silicon nitride, a silicon oxynitride, a zirconium oxide, or a hafnium oxide.

The gate GT2 of the oxide thin film transistor O-TFT is disposed on the fourth insulation layer 40. The gate GT2 may be a portion of a metal pattern. The gate GT2 overlaps with the active region AC2. In a process of doping the second semiconductor pattern, the gate GT2 may function as a mask.

The fifth insulation layer 50 is disposed on the fourth insulation layer 40, and may cover the gate GT2. The fifth insulation layer 50 may be an inorganic layer and/or an organic layer, and may have a single-layer structure or a multi-layered structure.

The first connection electrode CNE1 may be disposed on the fifth insulation layer 50. The first connection electrode CNE1 may be connected to the drain region DE1 of the silicon thin film transistor S-TFT through a contact hole passing through (e.g., penetrating) the first to fifth insulation layers 10, 20, 30, 40, and 50. In some embodiments, the display panel DP may further include a connection electrode defined at a position corresponding to the first connection electrode CNE1 and connected to the drain region DE2 or the source region SE2 of the oxide thin film transistor O-TFT, and is not limited to any particular embodiment.

The first pixel circuit PC1 may include a thin film transistor TFT. The thin film transistor TFT may correspond to (e.g., may be the same or substantially the same as) the silicon thin film transistor S-TFT. However, the present disclosure is not limited thereto. The thin film transistor TFT may correspond to (e.g., may be the same or substantially the same as) the oxide thin film transistor O-TFT, or the first pixel circuit PC1 may be designed to have the same or substantially the same configuration as that of the second pixel circuit PC2, but is not limited to any particular embodiment.

The circuit layer 120 may include a plurality of organic insulation layers disposed on a plurality of inorganic insulation layers. For example, at least one from among sixth to eighth insulation layers 60, 70, and 80 may be an organic insulation layer.

The sixth insulation layer 60 may be disposed on the fifth insulation layer 50. The sixth insulation layer 60 may include an organic matter, and for example, may include a polyimide-based resin. The second connection electrode CNE2 may be disposed on the sixth insulation layer 60. The second connection electrode CNE2 may be connected to the first connection electrode CNE1 through a contact hole passing through (e.g., penetrating) the sixth insulation layer 60.

The seventh insulation layer 70 is disposed on the sixth insulation layer 60, and may cover the second connection electrode CNE2. The eighth insulation layer 80 may be disposed on the seventh insulation layer 70.

The sixth insulation layer 60, the seventh insulation layer 70, and the eighth insulation layer 80 may each be an organic layer. Hereinafter, the sixth insulation layer 60 may be referred to as a first organic insulation layer, the seventh insulation layer 70 may be referred to as a second organic insulation layer, and the eighth insulation layer 80 may be referred to as a third organic insulation layer. For example, the sixth insulation layer 60, the seventh insulation layer 70, and the eighth insulation layer 80 may each include a general purpose polymer, such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and/or a suitable blend thereof.

In the buffer layer BF and at least some of the insulation layers from among the plurality of insulation layers 10, 20, 30, 40, 50, 60, 70, and 80, which are included in the circuit layer 120, a second opening IL-OP overlapping with the transmissive region TP may be defined. For example, as illustrated in FIG. 5A, in the first region A1, the second opening IL-OP may be defined in a portion in a thickness direction of the second sub-buffer layer BF2, and in the first to fifth insulation layers 10, 20, 30, 40, and 50. The second opening IL-OP may overlap with the first opening BM-OP.

In other words, because the portion in the thickness direction of the second sub-buffer layer BF2 that overlaps with the transmissive region TP, and a portion of each of the first to fifth insulation layers 10, 20, 30, 40, and 50 are removed, the transmittance of the transmissive region TP may be improved. However, the present disclosure is not limited thereto. Depending on a desired transmission rate of the transmissive region TP, positions of the insulation layers at which the openings are defined may be different from each other, and are not limited to any particular embodiment.

The light emission element layer 130 including the first and second light emission elements LD1 and LD2 may be disposed above the circuit layer 120. Each of the first and second light emission elements LD1 and LD2 may include a pixel electrode AE, a first functional layer HFL, a light emission layer EL, a second functional layer EFL, and the common electrode CE. The first functional layer HFL, the second functional layer EFL, and the common electrode CE may be connected to the pixels PX (e.g., see FIG. 4), and may be commonly provided.

The pixel electrode AE may be disposed on the eighth insulation layer 80. The pixel electrode AE may be a (semi)transmissive electrode or a reflective electrode. In an embodiment, the pixel electrode AE may be provided with a reflective layer formed of Ag, Mg, Al, Pt, Pd, Au, Ni, Nd, Ir, Cr, or a suitable compound thereof, and a transparent or translucent electrode layer formed on the reflective layer. The transparent or translucent electrode layer may be provided with at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). For example, the pixel electrode AE may be provided as multi-layers of ITO/Ag/ITO.

In the present embodiment, it is illustrated that the pixel electrode AE is connected to the silicon thin film transistor S-TFT through the first connection electrode CNE1 and the second connection electrode CNE2. However, the present disclosure is not limited thereto. The pixel electrode AE may be connected to the oxide thin film transistor O-TFT, and is not limited to any particular embodiment.

The pixel definition film PDL may be disposed on the eighth insulation layer 80. The pixel definition film PDL may have a property of absorbing light, and for example, may have a black color. The pixel definition film PDL may include a black coloring agent. The black coloring agent may include a black dye and/or a black pigment. The black coloring agent may include carbon black, a metal such as chromium, or an oxide thereof.

The pixel definition film PDL may have an opening PDL-OP, which exposes a portion of the pixel electrode AE. In other words, the pixel definition film PDL may cover an edge of the pixel electrode AE. In addition, the pixel definition film PDL may cover a side surface of the eighth insulation layer 80, which is adjacent to the transmissive region TP.

The first functional layer HFL may be disposed on the pixel electrode AE and the pixel definition film PDL. The first functional layer HFL may include one of a hole transport layer HTL or a hole injection layer HIL, or both the hole transport layer HTL and the hole injection layer HIL. The first functional layer HFL may be disposed throughout the first region A1 and the second region A2, and the first functional layer HFL may also be disposed at (e.g., in or on) the transmissive region TP.

The light emission layer EL is disposed on the first functional layer HFL, and may be disposed in a region corresponding to the opening PDL-OP of the pixel definition film PDL. The light emission layer EL may include an organic matter, an inorganic matter, or an organic-inorganic matter, which emits light of a desired color (e.g., a predetermined color). The light emission layer EL may be disposed at (e.g., in or on) the first region A1 and the second region A2. The light emission layer EL disposed at (e.g., in or on) the first region A1 may be disposed in a region spaced apart from the transmissive region TP, or in other words, at (e.g., in or on) the element region EP.

The second functional layer EFL is disposed on the first functional layer HFL, and may cover the light emission layer EL. The second functional layer EFL may include one of an electron transport layer ETL or an electron injection layer EIL, or both the electron transport layer ETL and the electron injection layer EIL. The second functional layer EFL may be disposed throughout the first region A1 and the second region A2, and the second functional layer EFL may also be disposed at (e.g., in or on) the transmissive region TP.

The common electrode CE may be disposed on the second functional layer EFL. The common electrode CE may be disposed at (e.g., in or on) the first region A1 and the second region A2. In the common electrode CE, the electrode opening CE-OP overlapping with the first opening BM-OP may be defined. A minimum width of the electrode opening CE-OP may be greater than a minimum width of the first opening BM-OP of the light blocking layer BML.

The light emission element layer 130 may further include the capping layer CPL disposed on the common electrode CE. The capping layer CPL may include LiF, an inorganic matter, and/or an organic matter. A portion of the capping layer CPL overlapping with the electrode opening CE-OP of the common electrode CE may be removed. Because a portion of the capping layer CPL including a portion overlapping with the transmissive region TP, and a portion of the common electrode CE are removed, the light transmittance of the transmissive region TP may be further improved.

the light emission element layer 130 may further include a spacer SPC. Referring to FIG. 5A, the spacer SPC may be disposed on the pixel definition film PDL at (e.g., in or on) the first region A1. The spacer SPC may be a component for supporting other components, such that the components included in the circuit layer 120 and the light emission element layer 130, which are disposed at (e.g., in or on) a lower portion, and the components included in the sensor layer 200 and the refection prevention layer 300 disposed at (e.g., in or on) an upper portion maintain a suitable distance (e.g., a predetermined distance). The spacer SPC may include an organic matter. Like the pixel definition film PDL, the spacer SPC may include a black coloring agent.

The encapsulation layer 140 may be disposed above the light emission element layer 130. The encapsulation layer 140 may include an inorganic layer 141, an organic layer 142, and an inorganic layer 143 that are sequentially laminated, but the layers constituting the encapsulation layer 140 are not limited thereto.

The inorganic layers 141 and 143 may protect the light emission element layer 130 from moisture and oxygen, and the organic layer 142 may protect the light emission element layer 130 from foreign materials, such as dust particles. The inorganic layers 141 and 143 may include a silicon nitride layer, a silicon oxynitride layer, a silicon oxide layer, a titanium oxide layer, an aluminum oxide layer, or the like. The organic layer 142 may include an acrylic organic layer, but is not limited thereto.

The sensor layer 200 may be disposed above the display layer 100. The sensor layer 200 may be referred to as a sensor, an input sensing layer, or an input sensing panel. The sensor layer 200 may include a sensor base layer 210, a first sensor conductive layer 220, a sensor insulation layer 230, a second sensor conductive layer 240, and a sensor cover layer 250.

The sensor base layer 210 may be directly disposed above the display layer 100. The sensor base layer 210 may be an inorganic layer including at least one of silicon nitride, silicon oxynitride, or silicon oxide. As another example, the base sensor layer 210 may be an organic layer including an epoxy resin, an acrylic resin, or an imide-based resin. The sensor base layer 210 may have a single-layer structure, or a multi-layered structure in which a plurality of layers are laminated along the third direction DR3.

Each of the first sensor conductive layer 220 and the second sensor conductive layer 240 may have a single-layer structure, or a multi-layered structure in which a plurality of layers are laminated along the third direction DR3.

A conductive layer of a single-layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide (ITO), indium zinc oxide (IZO), zinc oxide (ZnO), indium tin zinc oxide (ITZO), or the like. In addition, the transparent conductive layer may include a conductive polymer such as PEDOT, a metal nanowire, graphene, and/or the like.

A conductive layer of a multi-layered structure may include a plurality of metal layers. The metal layers may have, for example, a three-layered structure of titanium/aluminum/titanium. The conductive layer of a multi-layered structure may include at least one metal layer, and at least one transparent conductive layer.

The sensor insulation layer 230 may be disposed between the first sensor conductive layer 220 and the second sensor conductive layer 240. The sensor insulation layer 230 may include an inorganic film. The inorganic film may include at least one of an aluminum oxide, a titanium oxide, a silicon oxide, a silicon nitride, a silicon oxynitride, a zirconium oxide, or a hafnium oxide.

As another example, the sensor insulation layer 230 may include an organic film. The organic film may include at least one of an acrylic resin, a methacryl-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The sensor cover layer 250 is disposed on the sensor insulation layer 230, and may cover the second sensor conductive layer 240. The second sensor conductive layer 240 may include the conductive pattern 240P (e.g., see FIG. 4). The sensor cover layer 250 covers the conductive pattern 240P, and may reduce or eliminate the probability of damage that may occur to the conductive pattern 240P in a subsequent process.

The sensor cover layer 250 may include an inorganic matter. For example, the sensor cover layer 250 may include silicon nitride, but is not particularly limited thereto.

The refection prevention layer 300 may be disposed above the sensor layer 200. The refection prevention layer 300 may include the partition layer 310, a plurality of color filters 320, and a planarization layer 330. The partition layer 310 and the color filters 320 are not disposed at (e.g., in or on) the transmissive region TP of the first region A1.

The partition layer 310 may be disposed to overlap with the second sensor conductive layer 240. In the present embodiment, the conductive pattern 240P may correspond to the second sensor conductive layer 240. The sensor cover layer 250 may be disposed between the partition layer 310 and the second sensor conductive layer 240. The partition layer 310 may prevent or substantially prevent external light reflection by the second sensor conductive layer 240. A material constituting the partition layer 310 is not particularly limited, as long as the material absorbs light. For example, the partition layer 310 may be a layer having a black color, and in an embodiment, the partition layer 310 may include a black coloring agent. The black coloring agent may include a black dye and/or a black pigment. The black coloring agent may include carbon black, a metal such as chromium, or an oxide thereof.

In the partition layer 310, a plurality of partition openings 310-OP and a transmissive opening 31-OP may be defined. The plurality of partition openings 310-OP may overlap with a plurality of light emission layers EL, respectively. The color filters 320 may be disposed to correspond to each of the plurality of partition openings 310-OP. The color filter 320 may transmit light provided from the light emission layer EL overlapping with the color filter 320.

The transmissive opening 31-OP of the partition layer 310 may overlap with the first opening BM-OP of the light blocking layer BML. The minimum width of the transmissive opening 31-OP of the partition layer 310 may be the same or substantially the same as the minimum width of the first opening BM-OP of the light blocking layer BML. In other words, an end of the partition layer 310 in a region adjacent to the transmissive region TP may be aligned or substantially aligned with an end of the light blocking layer BML. As used in the present disclosure, the expression that components are “substantially aligned” with each other or that the width and the like of the components are “substantially the same” as each other includes the components being completely aligned with or each other or the width and the like of the components are physically the same size as each other, as well as deviations therefrom within the margin of error that may occur in a process despite the components being identical or substantially identical in design with each other.

The end of the partition layer 310 in a region adjacent to the transmissive region TP may protrude more than an end of the pixel definition film PDL and/or an end of the common electrode CE. The transmissive opening 31-OP of the partition layer 310 may define the transmissive region TP.

The planarization layer 330 may cover the partition layer 310 and the color filters 320. The planarization layer 330 may include an organic matter, and a flat or substantially flat surface may be provided at an upper surface of the planarization layer 330. In an embodiment, the planarization layer 330 may be omitted as needed or desired.

Referring to FIG. 5C, the display panel DP-1 may include a display layer 100-1 including a layered structure that may be different from that of the display panel DP illustrated in FIG. 5B. The display layer 100-1 may include a substrate 110-1, a circuit layer 120-1, a light emission element layer 130, and an encapsulation layer 140. Because the light emission element layer 130 and the encapsulation layer 140 may have the same or substantially the same structures as those shown in FIGS. 5A and 5B, redundant description thereof may not be repeated.

The substrate 110-1 may have a single-layer structure. The substrate 110-1 may be a glass substrate, a plastic substrate, or a metal substrate. The plastic substrate may include at least one of a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. However, the present disclosure is not limited thereto, and the substrate 110-1 may have a multi-layered structure, and is not limited to any particular embodiment.

The circuit layer 120-1 is disposed on the substrate 110-1. The circuit layer 120-1 may include a plurality of thin film transistors TFT10 and TFT20, and a plurality of insulation layers 11, 21, 31, and 41. The plurality of thin film transistors TFT10 and TFT20 constituting a second pixel circuit PC2-1 may include a first thin film transistor TFT10 and a second thin film transistor TFT20.

The first thin film transistor TFT10 may include a first gate GT10 and a first semiconductor pattern SP10. The first gate GT10 may be disposed to overlap with the first semiconductor pattern layer SP10 on a plane (e.g., in a plan view). The first gate GT10 is spaced apart from the first semiconductor pattern SP10 in a cross-section, with a first insulation layer 11 interposed therebetween. In the present embodiment, the first gate GT10 is illustrated as being disposed on the first semiconductor pattern SP10, but according to another embodiment of the present invention, the first gate GT10 of the first thin film transistor TFT10 may be disposed under (e.g., underneath) the first semiconductor pattern SP10, and is not limited to any particular embodiment.

The first semiconductor pattern SP10 includes a semiconductor material. For example, the first semiconductor pattern SP10 may include a silicon semiconductor or an oxide semiconductor. In other words, the first semiconductor pattern SP10 may be formed of the same material as that of the above-described first semiconductor pattern, or may be formed of the same material as that of the above-described second semiconductor pattern.

The first semiconductor pattern SP10 may include an active region AC10, a source region SE10, and a drain region DE10. The active region AC10, the source region SE10, and the drain region DE10 may correspond to the active region AC1, the source region SE1, and the drain region DE1, respectively, of the silicon thin film transistor S-TFT described above, or may correspond to the active region AC2, the source region SE2, and the drain region DE2, respectively, of the oxide thin film transistor O-TFT described above. Accordingly, redundant description thereof may not be repeated.

The first thin film transistor TFT10 may further include a source electrode and a drain electrode connected to the source region SE10 and the drain region DE10 described above, respectively, and formed of a conductive material, but is not limited to any particular embodiment.

The second thin film transistor TFT20 may include a second gate GT20 and a second semiconductor pattern SP20. The second gate GT20 may be disposed to overlap with the second semiconductor pattern layer SP20 on a plane (e.g., in a plan view). The second gate GT20 is spaced apart from the second semiconductor pattern SP20 in a cross-section, with the first insulation layer 11 interposed therebetween.

The second semiconductor pattern SP20 includes a semiconductor material. For example, the second semiconductor pattern SP20 may include a silicon semiconductor or an oxide semiconductor. In other words, the second semiconductor pattern SP20 may be formed of the same material as that of the above-described first semiconductor pattern, or may be formed of the same material as that of the above-described second semiconductor pattern.

The second semiconductor pattern SP20 may include an active region AC20, a source region SE20, and a drain region DE20. The active region AC20, the source region SE20, and the drain region DE20 may correspond to the active region AC1, the source region SE1, and the drain region DE1, respectively, of the silicon thin film transistor S-TFT described above, or may correspond to the active region AC2, the source region SE2, and the drain region DE2, respectively, of the oxide thin film transistor O-TFT described above.

In the present embodiment, the second gate GT20 and the first gate GT10 are illustrated as being disposed at (e.g., in or on) the same layer as each other, and the second semiconductor pattern SP20 and the first semiconductor pattern SP10 are illustrated as being disposed at (e.g., in or on) the same layer as each other, but the present disclosure is not limited thereto. The second thin film transistor TFT20 according to an embodiment of the present disclosure may have a different structure from a structure of the first thin film transistor TFT10, or may be disposed at (e.g., in or on) a different layer from that of the first thin film transistor TFT10, and is not limited to any particular embodiment.

A second insulation layer 21 covers the thin film transistors TFT10 and TFT20. On the second insulation layer 21, a third insulation layer 31 and a fourth insulation layer 41 are sequentially disposed. A light emission element LD3 may be connected to the thin film transistor TFT20 through a first connection electrode CNE10 disposed on the second insulation layer 21, and a second connection electrode CNE20 disposed on the third insulation layer 31. However, the present disclosure is not limited thereto. The number of connection electrodes between the light emission element LD3 and the thin film transistor TFT20 may be variously modified, and the light emission element LD3 and the thin film transistor TFT20 may be directly connected to each other, but are not limited to any particular embodiment.

As illustrated in FIG. 5A through FIG. 5C, the display panels DP and DP-1 according to embodiments of the present disclosure may have various suitable layered structures in a cross-section, and are not limited to any particular embodiment.

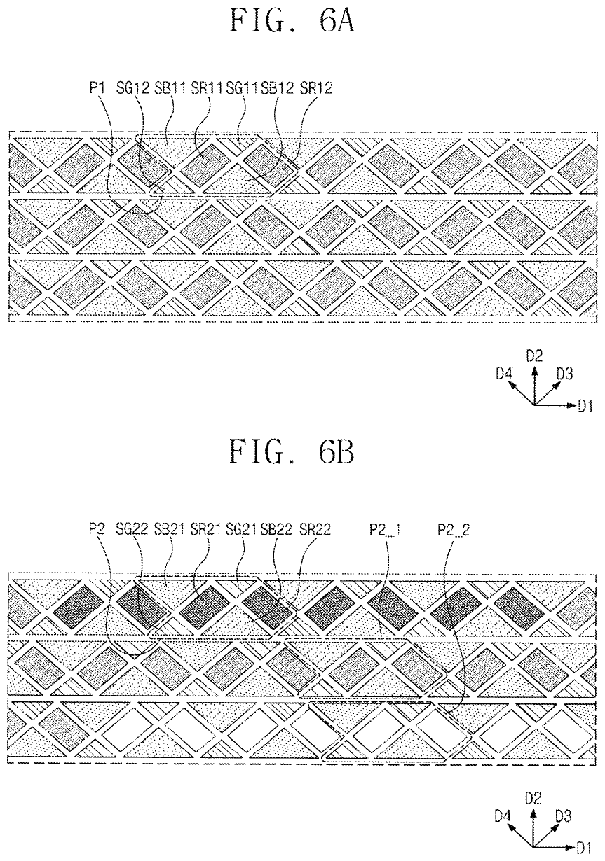

FIG. 6A through FIG. 6C are plan views illustrating pixel structures according to one or more embodiments of the present disclosure. For convenience of illustration, FIG. 6A through FIG. 6C illustrate partial regions. Hereinafter, embodiments of the present disclosure will be described with reference to FIG. 6A to FIG. 6C.

As described above, a pixel may include a plurality of sub-pixels. The sub-pixels have various suitable shapes and arrangements, and thus, may provide various suitable pixel structures. A display panel includes a display region in which a plurality of unit pixels are arranged. As illustrated in FIG. 6A and FIG. 6B, a unit pixel may have a pixel structure in which 6 sub-pixels are included. In an embodiment, each of the sub-pixels may correspond to any one from among the pixels PX11, PX12, PX13, PX21, PX22, and PX23.

As illustrated in FIG. 6A, a unit pixel P1 may include two red sub-pixels SR11 and SR12, two green sub-pixels SG11 and SG12, and two blue sub-pixels SB11 and SB12. The two red sub-pixels SR11 and SR12 may be spaced apart from each other in a first direction D1, and may have symmetric or substantially symmetric shapes with each other with respect to a symmetry axis extended along a second direction D2. One of the two red sub-pixels SR11 and SR12 may have a quadrangular shape having long sides extended in a third direction D3 and short sides extended in a fourth direction D4, and the other thereof may have a quadrangular shape that is line-symmetrical thereto. Here, the first to fourth directions D1, D2, D3, and D4 are defined independently from the aforementioned directions DR1, DR2, DR3, DR4, and DR5 shown in FIG. 1 through FIG. 5C.

The two green sub-pixels SG11 and SG12 may be spaced apart from each other in the third direction D3, with the red sub-pixel SR11 interposed therebetween, and may have shapes that are symmetric or substantially symmetric to each other with respect to a symmetry axis extended along the first direction D1. The two green sub-pixels SG11 and SG12 may have a triangular shape, with a base extended in the first direction D1, and a height extended in the second direction D2.

The two blue sub-pixels SB11 and SB12 may be spaced apart from each other in the fourth direction D4, with the red sub-pixel SR11 interposed therebetween, and may have shapes that are symmetrical or substantially symmetrical to each other with respect to a symmetry axis extended along the first direction D1. The two blue sub-pixels SB11 and SB12 may have a triangular shape, with a base extended along the first direction D1, and a height extended along the second direction D2.

In the unit pixel P1, the symmetry axis between the two red sub-pixels SR11 and SR12 may be arranged to match the height of the green sub-pixel SG11 and the height of the blue sub-pixel SB11. However, the present disclosure is not limited thereto, and arrangements of the sub-pixels SR11, SR12, SG11, SG12, SB11, and SB12 may be variously modified, and are not limited to any particular embodiment.

As illustrated in FIG. 6A, the unit pixels P1 may be arranged in parallel or substantially in parallel along the first direction D1 and the second direction D2. The unit pixels P1 may be arranged in a matrix form along the first direction D1 and the second direction D2.

As illustrated in FIG. 6B, unit pixels P2_1 and P2_2 may be arranged by being shifted along the second direction D2. The center of each of the unit pixels P2_1 and P2_2 may be arranged by being shifted by a suitable interval (e.g., a predetermined interval) when viewed in the second direction D2. Sub-pixels SR21, SR22, SG21, SG22, SB21, and SB22 constituting each of the unit pixels P2_1 and P2_2 may correspond to the sub-pixels SR11, SR12, SG11, SG12, SB11, and SB12 of FIG. 6A, respectively.

As illustrated in FIG. 6C, a unit pixel P3 may be composed of two red sub-pixels SR31 and SR32, one green sub-pixel SG3, and one blue sub-pixel SB3. In this case, the green sub-pixel SG3 and the the blue sub-pixel SB3 may have shapes that are different from the shapes of the green sub-pixels and blue sub-pixels illustrated in FIG. 6A and FIG. 6B. For example, each of the green sub-pixel SG3 and the blue sub-pixel SB3 may have a rhombic shape.

The two red sub-pixels SR31 and SR32 may have shapes that are line-symmetrical to each other with respect to a diagonal line, which is a symmetry axis, passing through the center of the green sub-pixel SG3. In the present embodiment, the red sub-pixels SR31 and SR32 may be disposed to have shapes that are symmetrical or substantially symmetrical to each other with respect to the blue sub-pixel SB3 in the third direction D3 or the fourth direction D4. In addition, the red sub-pixels SR31 and SR32 may be disposed to have shapes that are symmetrical or substantially symmetrical to each other with respect to the green sub-pixel SG3 in the third direction D3 or the fourth direction D4.

As described above, the unit pixels P1, P2, and P3 may be disposed at (e.g., in or on) the first region A1 or the second region A2, and may be commonly disposed at (e.g., in or on) both the first region A1 and the second region A2. A display panel according to an embodiment of the present disclosure may be defined in various suitable pixel structures, and is not limited to any particular embodiment.

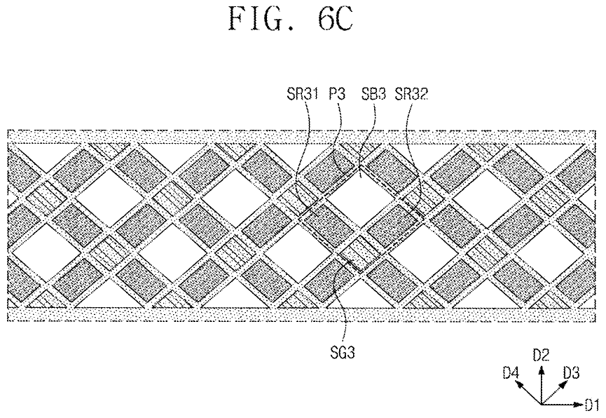

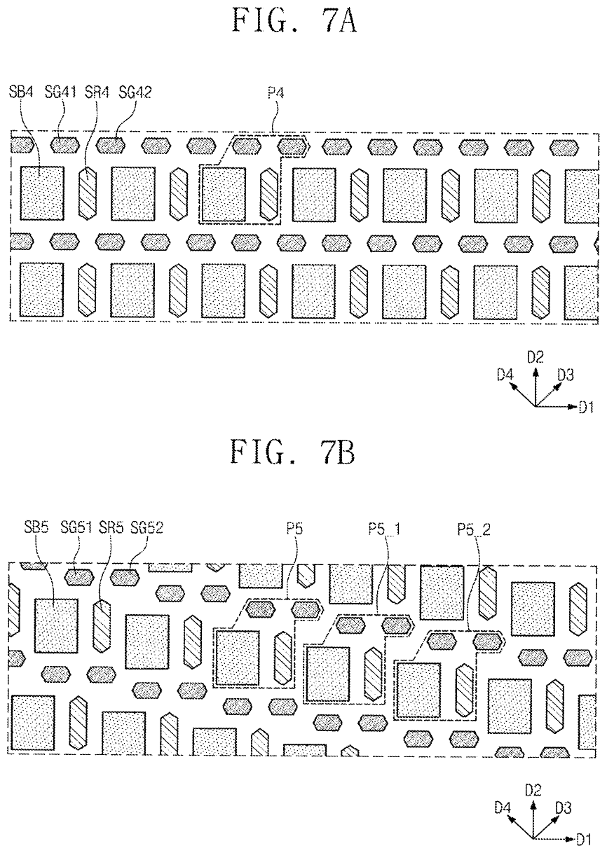

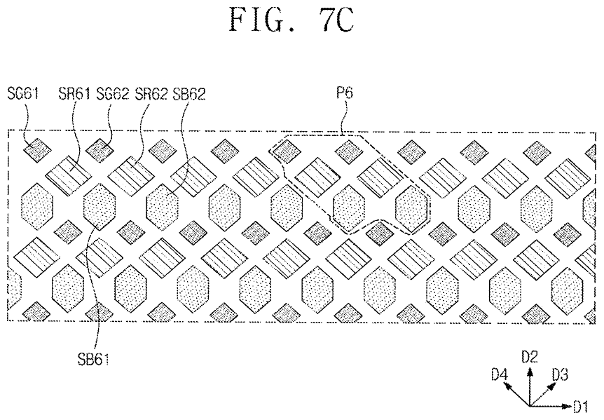

FIG. 7A to FIG. 7C are plan views illustrating pixel structures according to one or more embodiments of the present disclosure. For convenience of illustration, FIG. 7A to FIG. 7C illustrate partial regions. Hereinafter, embodiments of the present disclosure will be described with reference to FIG. 7A to FIG. 7C.

As illustrated in FIG. 7A, a pixel structure may include a unit pixel P4 composed of one red sub-pixel SR4, two green sub-pixels SG41 and SG42, and one blue sub-pixel SB4. The red sub-pixel SR4 may have a hexagonal shape with a length extended along the second direction D2.

The two green sub-pixels SG41 and SG42 may each have a hexagonal shape with a length extended along the first direction D1. The two green sub-pixels SG41 and SG42 may be spaced apart from each other along the first direction D1, and may have shapes line-symmetrical to each other with respect to a symmetry axis extended along the second direction D2. In the present embodiment, the symmetry axis of the two green sub-pixels SG41 and SG42 may pass through the center of the red sub-pixel SR4.

The blue sub-pixel SB4 is disposed to be spaced apart from the red sub-pixel SR4 in the first direction D1. The blue sub-pixel SB4 may have a rectangular shape with a length extended along the second direction D2.

In the present pixel structure, the red sub-pixels SR4 and the blue sub-pixels SR4 may be alternatively arranged along the first direction D1, and the green sub-pixels SG41 and SG42 may be continuously arranged along the first direction D1.

In the unit pixel P4, the blue sub-pixel SB4 may have an area relatively larger compared to the area of each of the other sub-pixels SR4, SG41, and SG42. The green sub-pixels SG41 and SG42 may be provided in a plurality in the unit pixel P4.

Accordingly, in the unit pixel P4, a green light emission region with relatively high visibility is dispersed, and the area of a blue light emission region with relatively low luminescence efficiency is increased compared to the area of a red light emission region with relatively high luminescence efficiency, so that the unit pixel P4 according to an embodiment of the present disclosure may have uniform or substantially uniform color reproducibility.

As illustrated in FIG. 7B, in a pixel structure according to an embodiment of the present disclosure, a unit pixel P5 may be arranged by being shifted along the first direction D1. Unit pixels P5_1 and P5_2 that are adjacent to each other in the first direction D1 are disposed to be shifted from each other when viewed in the first direction D1. Sub-pixels SR5, SG51, SG52, and SB5 constituting the unit pixel P5 illustrated in FIG. 7B may correspond to the sub-pixels SR4, SG41, SG42, and SB4 illustrated in FIG. 7A, respectively, and thus, redundant description thereof may not be repeated.

As illustrated in FIG. 7C, a unit pixel P6 may be composed of two red sub-pixels SR61 and SR62, two green sub-pixels SG61 and SG62, and two blue sub-pixels SB61 and SB62. The unit pixel P6 may be provided in a plurality arranged along the first direction D1, and may be arranged by being shifted by a suitable interval (e.g., a predetermined interval) in the second direction D2.

Each of the red sub-pixels SR61 and SR62 may have a rhombic shape. The two red sub-pixels SR61 and SR62 are disposed to be spaced apart from each other in the first direction D1. Each of the green sub-pixels SG61 and SG62 may have a rhombic shape. In this case, the shape of each of the green sub-pixels SG61 and SG62 may be smaller than the shape of each of the red sub-pixels SR61 and SR62. The green sub-pixels SG61 and SG62 are disposed to be spaced apart from each other in the first direction D1.

Each of the blue sub-pixels SB61 and SB62 may have a hexagonal shape. In the unit pixel P6, the red sub-pixels SR61 and SR62 may be disposed between the green sub-pixels SG61 and SG62 and the blue sub-pixels SB61 and SB62. Each of the blue sub-pixels SB61 and SB62 may have an area greater than the area of the red sub-pixels SR61 and SR62 and/or the area of the green sub-pixels SG61 and SG62. Accordingly, a blue light emission region with relatively low luminescence efficiency may be provided to be relatively large, so that the color reproducibility of the unit pixel P6 may be improved. A display panel according to an embodiment of the present disclosure may include various suitable pixel structures, and is not limited to any particular embodiment.

FIG. 8A to FIG. 8C are plan views illustrating pixel structures according to one or more embodiments of the present disclosure. For convenience of illustration, FIG. 8A to FIG. 8C illustrate partial regions. Hereinafter, embodiments of the present disclosure will be described with reference to FIG. 8A to FIG. 8C.

As illustrated in FIG. 8A, a pixel structure may include a unit pixel P7 composed of one red sub-pixel SR7, two green sub-pixels SG71 and SG72, and one blue sub-pixel SB7. The outer periphery line of the unit pixel P7 may have a square shape.

In more detail, the red sub-pixel SR7 may have a triangular shape, with a base extended along the third direction D3, and a height extended along the fourth direction D4. The vertex of the red sub-pixel SR7 may be disposed to correspond to one vertex of the unit pixel P7.

Each of the two green sub-pixels SG71 and SG72 may have a triangular shape, with a base extended along the fourth direction D4, and a height extended along the third direction D3. The green sub-pixels SG71 and SG72 may have shapes that are line-symmetrical with respect to a symmetry axis extended along the fourth direction D4. Vertexes of the green sub-pixels SG71 and SG72 may be disposed to correspond to two vertexes, respectively, of the unit pixel P7.

The blue sub-pixel SB7 may have a pentagonal shape. The blue sub-pixel SB7 may occupy the remaining region in the square shape of the unit pixel P7, except for the regions occupied by the red sub-pixel SR7 and the green sub-pixels SG71 and SG72.

In the present embodiment, the blue sub-pixel SB7 may have an area greater than the area of the red sub-pixel SR7 and/or the area of each of the green sub-pixels SG71 and SG72. Accordingly, in the unit pixel P7, an area of a blue light emission region with relatively low luminescence efficiency may be increased.

In addition, the green sub-pixels SG71 and SG72 may be disposed to be spaced apart from each other, and symmetrical or substantially symmetrical to each other. Accordingly, a green light emission region with relatively high visibility may be dispersed, to allow the green light emission region to be more evenly distributed in the unit pixel P7. Therefore, a display panel with improved color reproducibility may be provided.

As illustrated in FIG. 8B, a unit pixel P8 may be arranged by being shifted along the second direction D2. In more detail, unlike the unit pixel P7 illustrated in FIG. 8A that is arranged in a matrix shape aligned along the first direction D1 and the second direction D2, unit pixels P8_1 and P8_2 illustrated in FIG. 8B may be arranged by being shifted from each other along the second direction D2. Sub-pixels SR8, SG81, SG82, and SB8 constituting the unit pixel P8 may correspond to the sub-pixels SR7, SG71, SG72, and SB7 illustrated in FIG. 8A, respectively. Accordingly, redundant description thereof may not be repeated.

As illustrated FIG. 8C, a unit pixel P9 according to an embodiment of the present disclosure may include one red sub-pixel SR9, two green sub-pixels SG91 and SG92, and one blue sub-pixel SB9. The unit pixel P9 illustrated in FIG. 8C may correspond to a shape in which each of the unit pixels P7 and P8 illustrated in FIG. 8A and FIG. 8B is rotated by 90 degrees in a clockwise direction. Accordingly, the unit pixel P9 has a rhombic shape, and sub-pixels SR9, SG91, SG92, and SB9 constituting the unit pixel P9 may correspond to shapes in which the sub-pixels SR7, SG71, SG72, and SB7 illustrated in FIG. 8A or the sub-pixels SR8, SG81, SG82, and SB8 illustrated in FIG. 8B, respectively, are rotated by 90 degrees in a clockwise direction.

According to one or more embodiments of the present disclosure, a display panel may be designed in various suitable pixel structures including unit pixels with various suitable structures and arrangements. Accordingly, a display panel with improved visibility and color reproducibility may be provided.

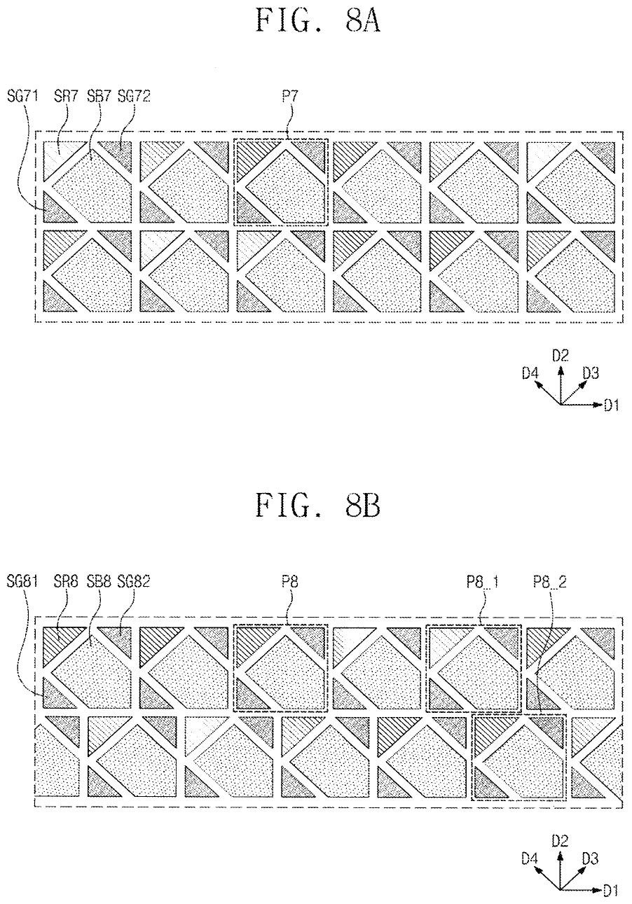

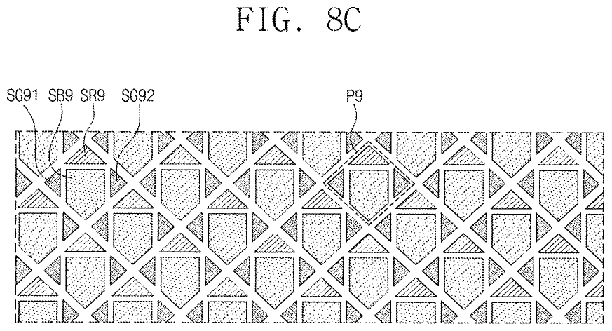

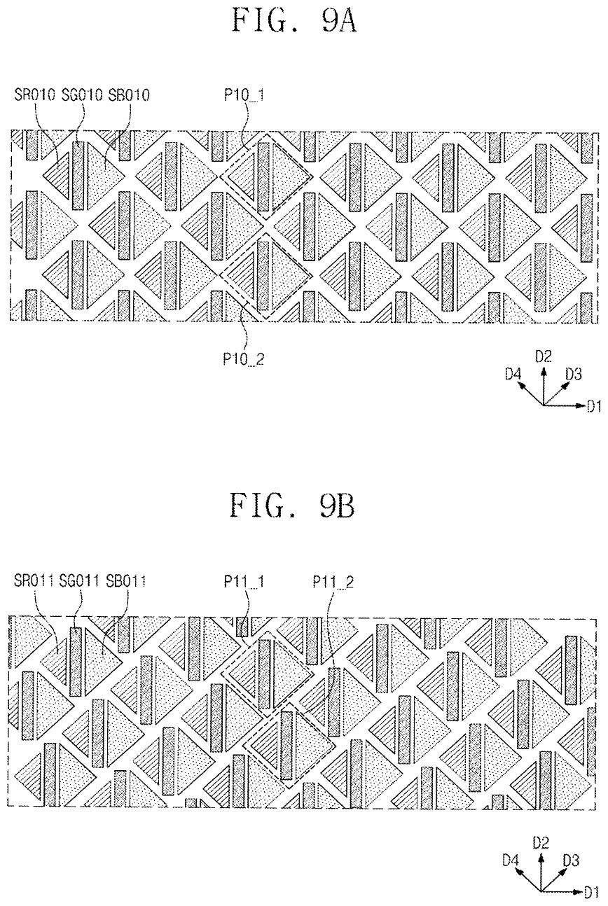

FIG. 9A and FIG. 9B are plan views illustrating pixel structures according to one or more embodiments of the present disclosure. For convenience of illustration, FIG. 9A and FIG. 9B illustrate partial regions. Hereinafter, embodiments of the present disclosure will be described with reference to FIG. 9A and FIG. 9B.

As illustrated in FIG. 9A, a pixel structure may include unit pixels P10_1 and P10_2, each composed of one red sub-pixel SR010, one green sub-pixel SG010, and one blue sub-pixel SB010. The outer periphery lines of the unit pixels P10_1 and P10_2 may each have an approximate rhombic shape.

In more detail, the red sub-pixel SR010 and the blue sub-pixel SB010 are disposed to be spaced apart from each other in the first direction D1. Each of the red sub-pixel SR010 and the blue sub-pixel SB010 may have a triangular shape, with a base extended along the second direction D2, and a height extended along the first direction D1.

The green sub-pixel SG010 is disposed between the red sub-pixel SR010 and the blue sub-pixel SB010. The green sub-pixel SG010 may have a rectangular shape, with a length extended along the second direction D2.

In the present embodiment, the area of the blue sub-pixel SB010 may be greater than the area of the red sub-pixel SR010 and/or the area of the green sub-pixel SG010. Therefore, a blue light emission region with relatively low luminescence efficiency may be provided to be relatively large, so that the color reproducibility of the unit pixels P10_1 and P10_2 may be improved.

In the present embodiment, the unit pixels P10_1 and P10_2 disposed to be adjacent to each other in the second direction D2 may be arranged in parallel or substantially in parallel with each other along the second direction D2.

As illustrated in FIG. 9B, a display panel may include unit pixels P11_1 and P11_2 that are arranged to be shifted along the second direction D2. Each of the unit pixels P11_1 and P11_2 illustrated in FIG. 9B may be composed of three sub-pixels SR011, SG011, and SB011 corresponding to those of the unit pixels P10_1 and P10_2 illustrated in FIG. 9A. In ther words, the pixel structure illustrated in FIG. 9B may correspond to the pixel structure illustrated in FIG. 9A, except for the arrangement form of the unit pixels P11_1 and P11_2. According, redundant description there may not be repeated. A display panel according to an embodiment of the present disclosure may include various suitable pixel structures, and is not limited to any particular embodiment.

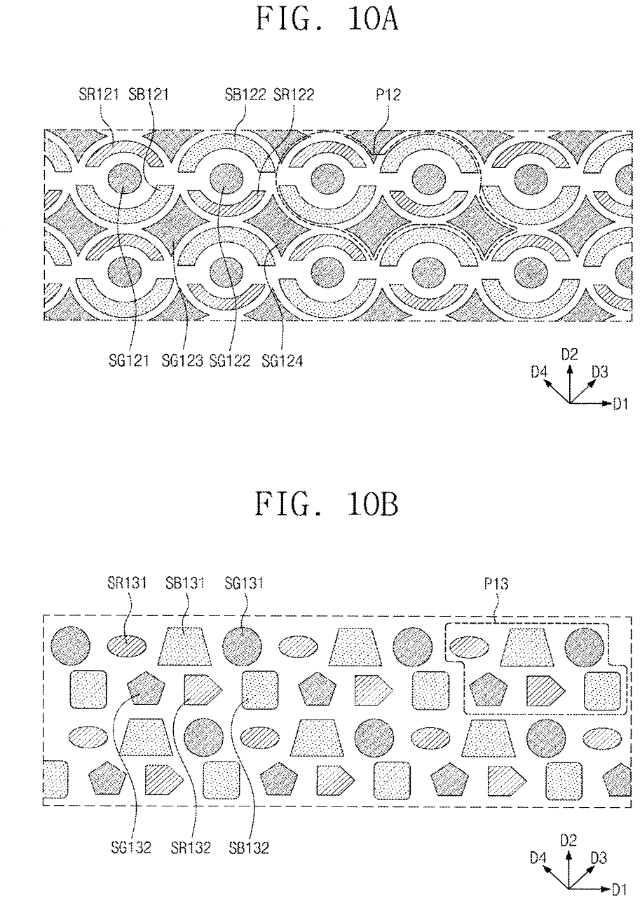

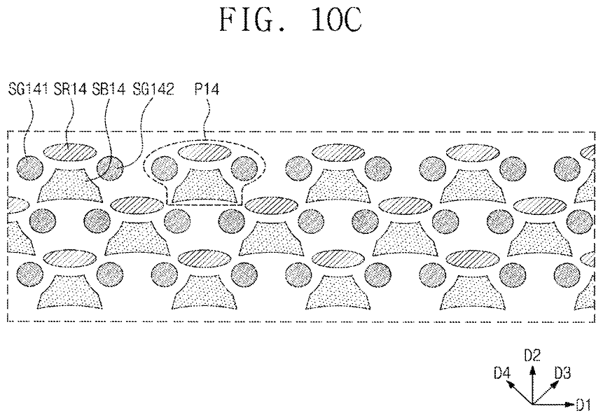

FIG. 10A to FIG. 10C are plan views illustrating pixel structures according to one or more embodiments of the present disclosure. For convenience of illustration, FIG. 10A to FIG. 10C illustrate partial regions. Hereinafter, embodiments of the present disclosure will be described with reference to FIG. 10A to FIG. 10C.

As illustrated in FIG. 10A, a pixel structure may include a unit pixel P12 composed of two red sub-pixels SR121 and SR122, four green sub-pixels SG121, SG122, SG123, and SG124, and two blue sub-pixels SB121 and SB122. The unit pixel P12 may have an atypical shape.

In the present embodiment, the two red sub-pixels SR121 and SR122 and the two blue sub-pixels SB121 and SB122 may each have a semi-circular band shape. From among the four green sub-pixels SG121, SG122, SG123, and SG124, two green sub-pixels SG121 and SG122 may each have a circular shape, and two green sub-pixels SG123 and SG124 may each have an atypical shape. The two green sub-pixels SG123 and SG124 may each have a shape that may fill an empty space in which a circular shape defined by a first red sub-pixel SR121 and a first blue sub-pixel SB121 and a circular shape defined by a second red sub-pixel SR122 and a second blue sub-pixel SB122 are not disposed. For example, the two green sub-pixels SG123 and SG124 may each have an atypical four-sided shape, with four vertexes, and curved sides concaved towards the center.

In more detail, the first red sub-pixel SR121 and the first blue sub-pixel SB121 are disposed to be spaced apart from each other in the second direction D2, with a first green sub-pixel SG121 interposed therebetween. The second red sub-pixel SR122 and the second blue sub-pixel SB122 are disposed to be spaced apart from each other in the second direction D2, with a second green sub-pixel SG122 interposed therebetween. The first and second green sub-pixels SG121 and SG122 are disposed to be spaced apart from each other in the first direction D1.

The first red sub-pixel SR121 and the first blue sub-pixel SB121 may have different areas from each other, and may be convexly disposed in opposite directions. The second blue sub-pixel SB122 and the second red sub-pixel SR122 may have different areas from each other, and may be convexly disposed in opposite directions. The sum of the areas of the blue sub-pixels SB121 and SB122 may be greater than the sum of the areas of the red sub-pixels SR121 and SR122. Accordingly, a blue light emission region with relatively low luminescence efficiency may be provided to be larger than a red light emission region with relatively high luminescence efficiency, so that the color reproducibility of the unit pixel P12 may be improved.

In the unit pixel P12, in regions other than the region in which the red sub-pixels SR121 and SR122, the blue sub-pixels SB121 and SB122, and the two green sub-pixels SG121 and SG122 are disposed, the third and fourth green sub-pixels may be disposed, respectively. According to an embodiment of the present disclosure, a green light emission region with relatively high visibility may be dispersed to allow the green light emission region to be evenly distributed in the unit pixel P12. Therefore, a display panel with improved color reproducibility may be provided.

As illustrated in FIG. 10B, a display panel may have a pixel structure including a unit pixel P13 composed of sub-pixels in various suitable shapes. The unit pixel P13 may be composed of two red sub-pixels SR131 and SR132, two green sub-pixels SG131 and SG132, and two blue sub-pixels SB131 and SB132.

The sub-pixels SR131, SR132, SG131, SG132, SB131, and SB132 may have different shapes from each other. In more detail, a first red sub-pixel SR131 may have an elliptical shape, with a length extended along the first direction D1. A first blue sub-pixel SB131 may have a trapezoidal shape including an upper side and a lower side, which are extended along the first direction D1. A first green sub-pixel SG131 may have an elliptical shape, with a length extended along the second direction D2.

A second red sub-pixel SR132 may have a regular pentagonal shape. The second red sub-pixel SR132 may have a pentagonal shape with different interior angles. A second blue sub-pixel SB132 may have a quadrangular shape, with a length extended along the second direction D2, and with rounded vertexes.

FIG. 10B illustrates that first sub-pixels SR131, SG131, and SB131 and second sub-pixels SR132, SG132, and SB132 are arranged along the first direction D1, and spaced apart in the second direction D2, but the present disclosure is not limited thereto. The sub-pixels SR131, SR132, SG131, SG132, SB131, and SB132 may be randomly arranged in the unit pixel P1, and are not limited to any particular embodiment.

In the present embodiment, the sum of the areas of the blue sub-pixels SB131 and SB132 may be greater than the sum of the areas of the red sub-pixels SR131 and SR132. Accordingly, a blue light emission region with relatively low luminescence efficiency may be provided to be larger than a red light emission region with relatively high luminescence efficiency, so that the color reproducibility of the unit pixel P13 may be improved.

As illustrated in FIG. 10C, a display panel may include a pixel structure including a unit pixel P14 composed of one red sub-pixel SR14, two green sub-pixels SG141 and SG142, and one blue sub-pixel SB14. The red sub-pixel SR14 may have an elliptical shape, with a length extended along the first direction D1. The blue sub-pixel SB14 is spaced apart from the red sub-pixel SR14.

The green sub-pixels SG141 and SG142 are spaced apart from each other in the first direction D1, with the red sub-pixel SR14 and the blue sub-pixel SB14 interposed therebetween. Each of the green sub-pixels SG141 and SG142 may have a circular shape. The green sub-pixels SG141 and SG142 may be disposed at a position that is line-symmetrical with respect to a symmetry axis extended along the second direction D2, and crossing the red sub-pixel SR14 and the blue sub-pixel SB14, and may have shapes that are line-symmetrical to each other.

According to an embodiment of the present disclosure, the area of the blue sub-pixel SB14 may be greater than the area of the red sub-pixel SR14. Accordingly, a blue light emission region with relatively low luminescence efficiency may be provided to be larger than a red light emission region with relatively high luminescence efficiency. In addition, the green sub-pixels SG141 and SG142 may be disposed to be spaced apart from each other, and are symmetrical or substantially symmetrical to each other. Accordingly, a green light emission region with relatively high visibility may be dispersed to allow the green light emission region to be evenly distributed in the unit pixel P14. Therefore, the light emission of each of red light, green light, and blue light may be balanced in the unit pixel P14, so that a display panel with improved color reproducibility may be provided.

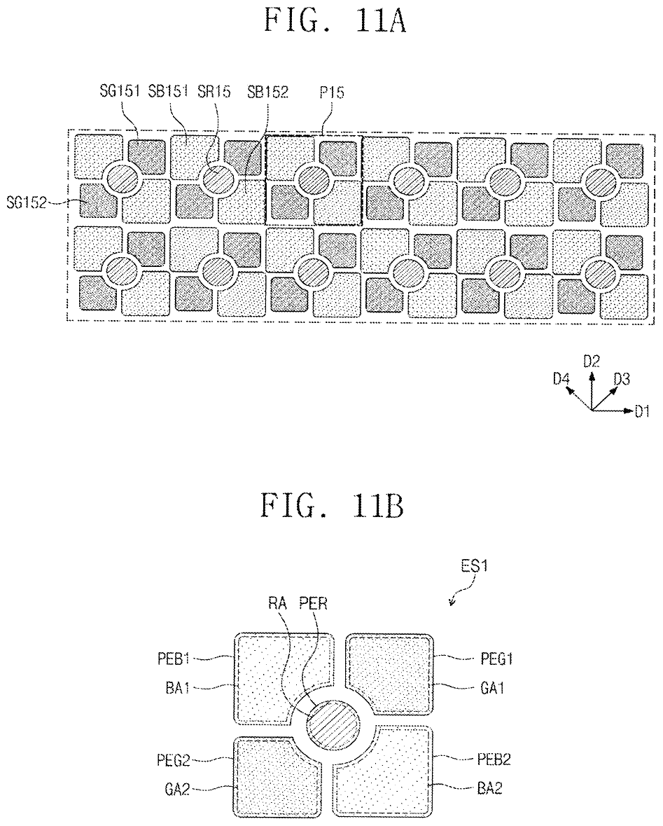

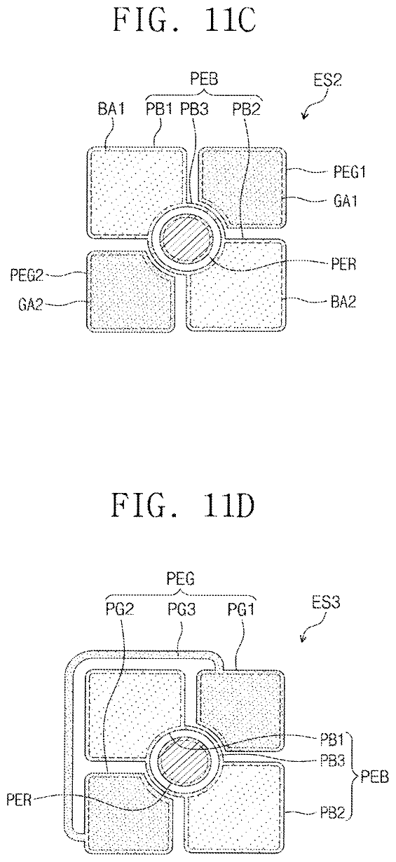

FIG. 11A is a plan view illustrating pixel structures according to an embodiment of the present disclosure. FIG. 11B to FIG. 11D illustrate pixel electrodes of a pixel structure illustrated in FIG. 11A. Hereinafter, embodiments of the present disclosure will be described with reference to FIG. 11A to FIG. 11D.

As illustrated in FIG. 11A, a display panel may be designed to include a pixel structure including a unit pixel P15 composed of one red sub-pixel SR15, two green sub-pixels SG151 and SG152, and two blue sub-pixels SB151 and SB152. The red sub-pixel SR15 may be disposed in the center of the unit pixel P15. The red sub-pixel SR15 may have a circular shape.

The two green sub-pixels SG151 and SG152 may be disposed to be spaced apart from each other in the third direction D3, with the red sub-pixel SR15 interposed therebetween. The center of the red sub-pixel SR15 and the centers of the two green sub-pixels SG151 and SG152 may be arranged along the third direction D3. According to an embodiment of the present disclosure, the two green sub-pixels SG151 and SG152 may be disposed to be spaced apart from each other, and symmetrical or substantially symmetrical to each other with the red sub-pixel SR15 interposed therebetween. Accordingly, a green light emission region with relatively high visibility may be dispersed to allow the green light emission region to be evenly distributed in the unit pixel P15. Therefore, a display panel with improved color reproducibility may be provided.

The two blue sub-pixels SB151 and SB152 may be disposed to be spaced apart from each other in the fourth direction D4, with the red sub-pixel SR15 interposed therebetween. The center of the red sub-pixel SR15 and the centers of the two blue sub-pixels SB151 and SB152 may be arranged along the fourth direction D4. In other words, directions in which the green sub-pixels and the blue sub-pixels are arranged may be 90 degrees with respect to each other.

According to the present disclosure, the unit pixel P15 may include the blue sub-pixels SB151 and SB152 and the green sub-pixels SG151 and SG152, which are disposed surrounding (e.g., around a periphery of) the edge of the red sub-pixel SR15. The boundary line of the unit pixel P15 defined by the blue sub-pixels SB151 and SB152 and the green sub-pixels SG151 and SG152 may have an approximate quadrangular shape, and may have a different shape from the shape of the red sub-pixel SR15, which is circular.

The areas of the red sub-pixel SR15, the green sub-pixels SG151 and SG152, and the blue sub-pixels SB151 and SB152 may be independently designed. In the present embodiment, the areas of the blue sub-pixels SB151 and SB152 may be designed to be relatively larger than the area of the red sub-pixel SR15. Accordingly, a blue light emission region with relatively low luminescence efficiency may be provided to be relatively large, so that the color reproducibility of the unit pixel P15 may be improved.

The green sub-pixels SG151 and SG152 are disposed to be symmetrical to or substantially symmetrical to each other, and spaced apart from each other in the third direction D3. Therefore, a problem in which a green light emission region with relatively high visibility is agglomerated and visually recognized may be prevented or substantially prevented. Accordingly, uniform color expression may be possible, which may improve color reproducibility. A display panel according to an embodiment of the present disclosure may include various suitable pixel structures, and is not limited to any particular embodiment.

The unit pixel P15 may have various suitable pixel electrode structures. FIG. 11B to FIG. 11D illustrate various pixel electrode structures that may be implemented for the unit pixel P15, and light emission regions (e.g., sub-pixel regions) are marked with dotted lines and illustrated for convenience. The light emission regions (sub-pixel regions) may respectively correspond to the shapes of the sub-pixels SR15, SG151, SG152, SB151, and SB152 illustrated in FIG. 11A.

Referring to FIG. 11B, a pixel electrode structure ES1 may be composed of one red sub-pixel electrode PER, two green sub-pixel electrodes PEG1 and PEG2, and two blue sub-pixel electrodes PEB1 and PEB2. In the present embodiment, the sub-pixel electrodes PER, PEG1, PEG2, PEB1, and PEB2 are disposed to respectively overlap with corresponding sub-pixel regions RA, GA1, GA2, BA1, and BA2. The sub-pixel electrodes PER, PEG1, PEG2, PEB1, and PEB2 may have shapes similar to those of the corresponding sub-pixel regions RA, GA1, GA2, BA1, and BA2.

In more detail, the red sub-pixel electrode PER may have a circular shape that has substantially the same area as the area of a red sub-pixel region RA. The green sub-pixel electrodes PEG1 and PEG2, and the blue sub-pixel electrodes PEB1 and PEB2 are disposed along the edge of the red sub-pixel electrode PER, and may have shapes respectively corresponding to shapes of the green sub-pixel regions GA1 and GA2 and the blue sub-pixel regions BA1 and BA2.

According to an embodiment of the present disclosure, the sub-pixel electrodes PER, PEG1, PEG2, PEB1, PEB2 may be connected to transistors, respectively, through contact holes. Accordingly, the sub-pixel electrodes PER, PEG1, PEG2, PEB1, PEB2 may be independently controlled through respective driving circuits.

Referring to FIG. 11C, a pixel electrode structure ES2 may be composed of one red sub-pixel electrode PER, two green sub-pixel electrodes PEG1 and PEG2, and one blue sub-pixel electrode PEB. The red sub-pixel electrode PER and the green sub-pixel electrodes PEG1 and PEG2 correspond to those shown in FIG. 11B, and thus, redundant description thereof may not be repeated.

The blue sub-pixel electrode PEB may include a first electrode portion PB1, a second electrode portion PB2, and a third electrode portion PB3. The first electrode portion PB1 and the second electrode portion PB2 may respectively overlap with the blue sub-pixel regions BA1 and BA2. The first electrode portion PB1 and the second electrode portion PB2 may respectively correspond to the blue sub-pixel electrodes PEB1 and PEB2 illustrated in FIG. 11B.

The third electrode portion PB3 connects the first electrode portion PB1 and the second electrode portion PB2 to each other. The third electrode portion PB3 is extended along the edge of the red sub-pixel electrode PER, and connects the first electrode portion PB1 and the second electrode portion PB2 to each other. The third electrode portion PB3 may not overlap with the sub-pixel regions RA, GA1, GA2, BA1, and BA2.

In the present embodiment, the third electrode portion PB3 is illustrated as two portions that are spaced apart from each other with the red sub-pixel electrode PER interposed therebetween, but the present disclosure is not limited thereto. In the pixel electrode structure ES2 according to an embodiment of the present disclosure, the third electrode portion PB3 may have various suitable shapes, as long as it connects the first electrode portion PB2 and the second electrode portion PB2 to each other, and is not limited to any particular embodiment.

The blue sub-pixel electrode PEB may be connected to one transistor. Therefore, the blue sub-pixel regions BA1 and BA2 may be driven through one driving circuit. Because two sub-pixel regions that are spatially separated are driven through one driving circuit, the density of a current flowing through a blue sub-pixel is reduced, and the lifespan of the sub-pixel may be extended.

Referring to FIG. 11D, a pixel electrode structure ES3 may be composed of one red sub-pixel electrode PER, one green sub-pixel electrode PEG, and one blue sub-pixel electrode PEB. The red sub-pixel electrode PER and the blue sub-pixel electrode PEB correspond to those illustrated in FIG. 11C, and thus, redundant description thereof may not be repeated.

The green sub-pixel electrode PEG may include a fourth electrode portion PG1, a fifth electrode portion PG2, and a sixth electrode portion PG3. The fourth electrode portion PG1 and the fifth electrode portion PG2 may respectively overlap with the green sub-pixel regions GA1 and GA2 (e.g., see FIG. 11B). The fourth electrode portion PG1 and the fifth electrode portion PG2 may respectively correspond to the green sub-pixel electrodes PEG1 and PEG2 illustrated in FIG. 11B.

The sixth electrode portion PG3 connects the fourth electrode portion PG1 and the fifth electrode portion PG2 to each other. The sixth electrode portion PG3 is extended along the edge of the blue sub-pixel electrode PEB, and connects the fourth electrode portion PG1 and the fifth electrode portion PG2 to each other. The sixth electrode portion PG3 may not overlap with the sub-pixel regions RA, GA1, GA2, BA1, and BA2 (e.g., see FIG. 11B).

In the present embodiment, the sixth electrode portion PG3 is extended along the outer side of the first electrode portion PB1, and connects the fourth electrode portion PG1 and the fifth electrode portion PG2 to each other. However, the present disclosure is not limited thereto, and in the pixel electrode structure ES3 according to an embodiment of the present disclosure, the sixth electrode portion PG3 may have various suitable shapes, as long as it connects the fourth electrode portion PG1 and the fifth electrode portion PG2 to each other, and is not limited to any particular embodiment.

According to an embodiment of the present disclosure, the blue sub-pixel electrode PEB is connected to one transistor, and the green sub-pixel electrode PEG may be driven by one transistor. Because two blue sub-pixels and green sub-pixels are respectively driven through a single driving circuit, design may be simplified, and the lifespan of a display panel may be improved. A display panel according to an embodiment of the present disclosure may include various suitable pixel structures, and is not limited to any particular embodiment.

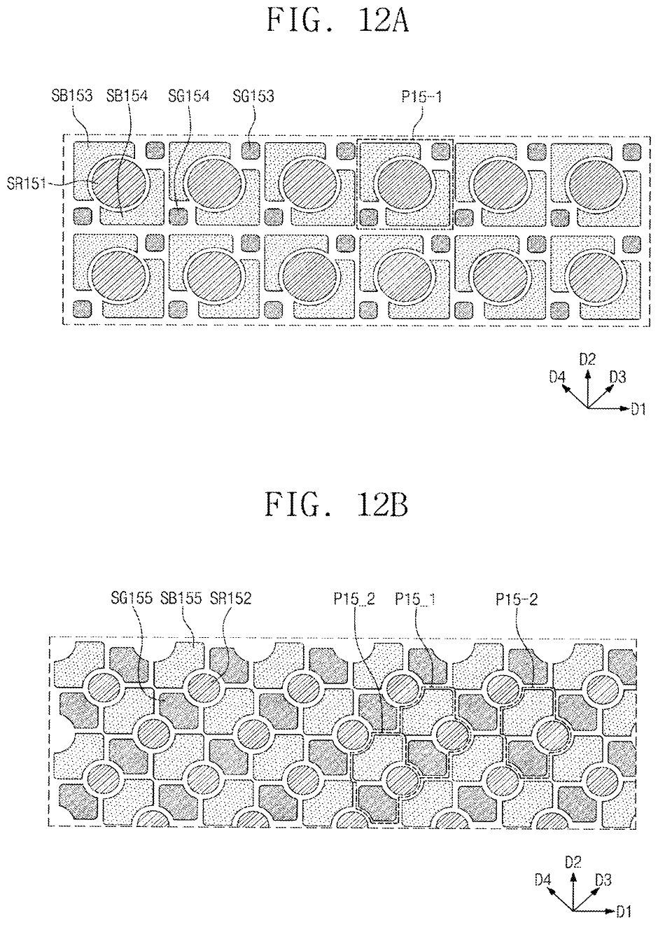

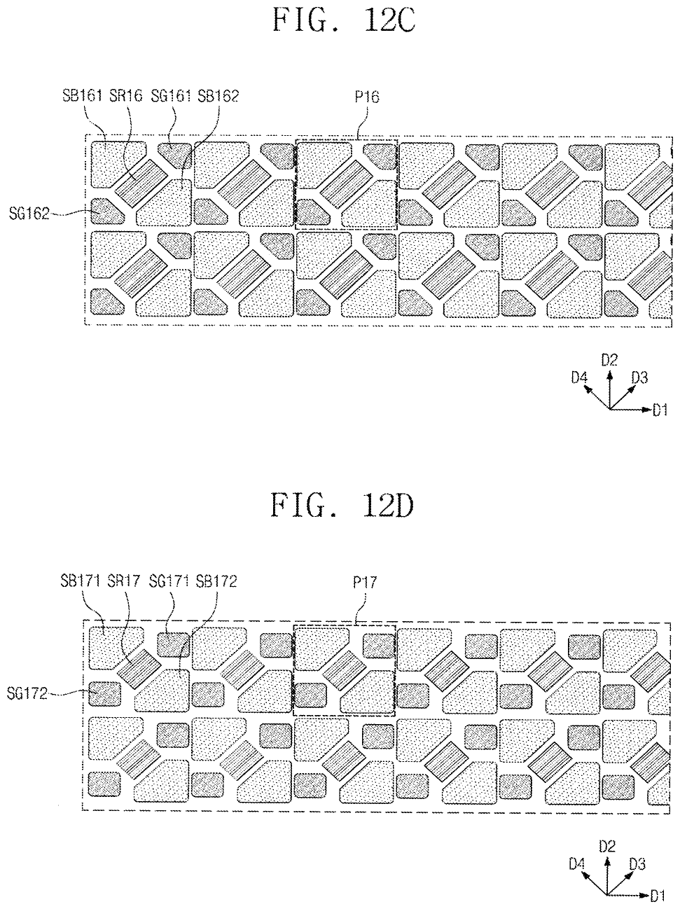

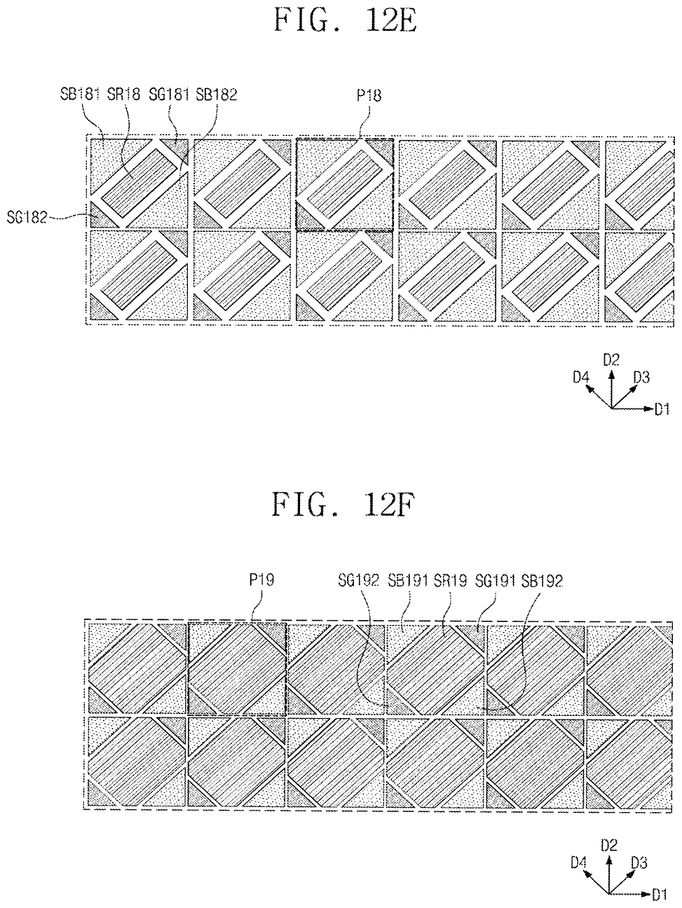

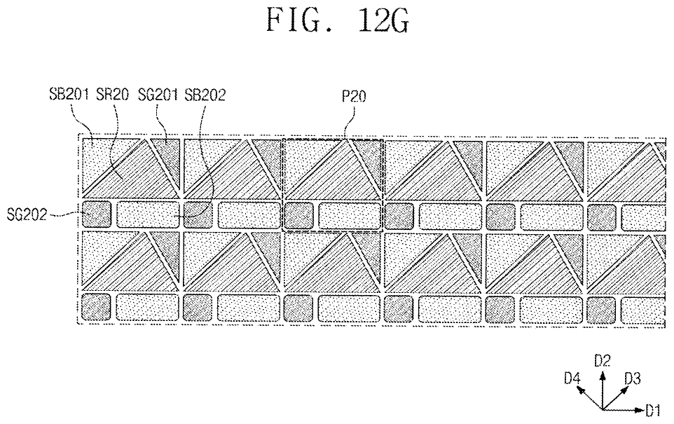

FIG. 12A to FIG. 12G are plan views illustrating pixel structures according to one or more embodiments of the present disclosure. For convenience of illustration, FIG. 12A to FIG. 12G illustrate partial regions. Hereinafter, embodiments of the present disclosure will be described with reference to FIG. 12A to FIG. 12G.

As illustrated in FIG. 12A, a display panel may be designed to include a pixel structure including a unit pixel P15-1 composed of one red sub-pixel SR151, two green sub-pixels SG153 and SG154, and two blue sub-pixels SB153 and SB154.

While having the same or substantially the same arrangement as that of the unit pixel P15 illustrated in FIG. 11A, the unit pixel P15-1 may be composed of sub-pixels SR151, SG153, SG154, SB153, and SB154 that are designed to have different areas. The red sub-pixel SR151 may have an area greater than the area of the red sub-pixel SR15 illustrated in FIG. 11A. The green sub-pixels SG153 and SG154 may have areas smaller than the areas of the green sub-pixels SG151 and SG152 illustrated in FIG. 11A. The blue sub-pixels SB153 and SB154 may have areas smaller than the areas of the blue sub-pixels SB151 and SB152 illustrated in FIG. 11A.

As illustrated in FIG. 12B, a display panel may be designed to include a pixel structure including a unit pixel P15-2 composed of one red sub-pixel SR152, one green sub-pixel SG155, and one blue sub-pixel SB155. The blue sub-pixel SB155 and the green sub-pixel SG155 are disposed to be spaced apart from each other along the second direction D2. The sub-pixels SG155, SG82, and SB155 constituting the unit pixel P15-2 may correspond to three sub-pixels SR15, SG152, and SB151 of the unit pixel P15 illustrated in FIG. 11A.

The unit pixel P15-2 may be provided in a plurality, and arranged along the third direction D3. For example, a first unit pixel P15_1 and a second unit pixel P15_2, which are adjacent to each other in the first direction D1, may be arranged along the third direction D3.

The red sub-pixel SR152 and the green sub-pixel SG155 of each unit pixel P15-2 are alternately disposed along the third direction D3. A line connecting the center of the red sub-pixel SR152 and the center of the green sub-pixels SG152 may be parallel to or substantially parallel to the third direction D3. The red sub-pixel SR152 and the blue sub-pixel SB155 of each unit pixel P15-2 are alternately disposed along the fourth direction D4. A line connecting the center of the red sub-pixel SR152 and the center of the blue sub-pixels SB152 may be parallel to or substantially parallel to the fourth direction D4.

According to an embodiment of the present disclosure, each of the red sub-pixels is arranged by being surrounded (e.g., around a periphery thereof) by blue sub-pixels and green sub-pixels. A boundary of the green sub-pixels may be partially curved, so as not to interfere with adjacent red sub-pixels. The curve may correspond to an arc of the red sub-pixel.

As illustrated in FIG. 12C, a display panel may be designed to include a pixel structure including a unit pixel P16 composed of one red sub-pixel SR16, two green sub-pixels SG161 and SG162, and two blue sub-pixels SB161 and SB162. While having the same or substantially the same arrangement as that of the unit pixel P15 illustrated in FIG. 11A, the unit pixel P16 may be composed of sub-pixels SR16, SG161, SG162, SB161, and SB162 that are designed in different shapes.

The red sub-pixel SR16 may have a quadrangular shape, which includes long sides extended along the third direction D3, and short sides extended along the fourth direction D4. The green sub-pixels SG161 and SG162 are disposed to be spaced apart from each other in the third direction D3, with the red sub-pixel SR16 interposed therebetween. Each of the green sub-pixels SG161 and SG162 may have a pentagonal shape, which includes a side facing the red sub-pixel SR16 in a quadrangular shape.

The blue sub-pixels SB161 and SB162 are disposed to be spaced apart from each other in the fourth direction D4, with the red sub-pixel SR16 interposed therebetween. Each of the blue sub-pixels SB161 and SB162 may have a pentagonal shape, which includes a side facing the red sub-pixel SR16 in a quadrangular shape.

In the present embodiment, the areas of the blue sub-pixels SB161 and SB162 may be designed to be relatively larger than the area of the red sub-pixel SR16. Accordingly, a blue light emission region with relatively low luminescence efficiency may be provided to be relatively large, so that the color reproducibility of the unit pixel P16 may be improved. A display panel according to an embodiment of the present disclosure may include various suitable pixel structures, and is not limited to any particular embodiment.

In addition, the green sub-pixels SG161 and SG162 are disposed to be symmetrical to or substantially symmetrical to each other, and spaced apart from each other in the third direction D3. Therefore, a problem in which a green light emission region with relatively high visibility is agglomerated and visually recognized may be prevented or substantially prevented. Accordingly, uniform color expression is possible, which may improve color reproducibility.

As illustrated FIG. 12D, a display panel may be designed to include a pixel structure including a unit pixel P17 composed of one red sub-pixel SR17, two green sub-pixels SG171 and SG172, and two blue sub-pixels SB171 and SB172. While having the same or substantially the same arrangement as that of the unit pixel P15 illustrated in FIG. 11A, the unit pixel P17 may be composed of sub-pixels SR17, SG171, SG172, SB171, and SB172 that are designed in different shapes.

The red sub-pixel SR17 may have a quadrangular shape, which includes sides extended along the third direction D3, and sides extended along the fourth direction D4. The red sub-pixel SR17 may have a shorter side in the third direction D3 than the side of the red sub-direction SR16 illustrated in FIG. 12C.

The green sub-pixels SG171 and SG172 are disposed to be spaced apart from each other in the third direction D3, with the red sub-pixel SR17 interposed therebetween. Each of the green sub-pixels SG171 and SG172 may have a quadrangular shape, which includes sides extended along the first direction D1, and sides extended along the second direction D2.

The blue sub-pixels SB171 and SB172 are disposed to be spaced apart from each other in the fourth direction D4, with the red sub-pixel SR17 interposed therebetween. Each of the blue sub-pixels SB171 and SB172 may have a pentagonal shape, which includes a side facing the red sub-pixel SR17 in a quadrangular shape.

In the present embodiment, the areas of the blue sub-pixels SB171 and SB172 may be designed to be relatively larger than the area of the red sub-pixel SR17. Accordingly, a blue light emission region with relatively low luminescence efficiency may be provided to be relatively large, so that the color reproducibility of the unit pixel P17 may be improved. A display panel according to an embodiment of the present disclosure may include various suitable pixel structures, and is not limited to any particular embodiment.

In addition, the green sub-pixels SG171 and SG172 are disposed to be symmetrical to or substantially symmetrical to each other, and spaced apart from each other in the third direction D3. Therefore, a problem in which a green light emission region with relatively high visibility is agglomerated and visually recognized may be prevented or substantially prevented. Accordingly, uniform color expression is possible, which may improve color reproducibility.

As illustrated FIG. 12E, a display panel may be designed to include a pixel structure including a unit pixel P18 composed of one red sub-pixel SR18, two green sub-pixels SG181 and SG182, and two blue sub-pixels SB181 and SB182. While having the same or substantially the same arrangement as that of the unit pixel P15 illustrated in FIG. 11A, the unit pixel P18 may be composed of sub-pixels SR18, SG181, SG182, SB181, and SB182 that are designed in different shapes.

The red sub-pixel SR18 may have a quadrangular shape, which includes long sides extended along the third direction D3, and short sides extended along the fourth direction D4. The green sub-pixels SG181 and SG182 are disposed to be spaced apart from each other in the third direction D3, with the red sub-pixel SR18 interposed therebetween. Each of the green sub-pixels SG181 and SG182 may have a triangular shape, which includes a side facing the red sub-pixel SR18 in a quadrangular shape.

The blue sub-pixels SB181 and SB182 are disposed to be spaced apart from each other in the fourth direction D4, with the red sub-pixel SR18 interposed therebetween. Each of the blue sub-pixels SB181 and SB182 may have a triangular shape, which includes a side facing the red sub-pixel SR18 in a quadrangular shape.

In the present embodiment, the areas of the blue sub-pixels SB181 and SB182 may be designed to be relatively larger than the area of the red sub-pixel SR18. Accordingly, a blue light emission region with relatively low luminescence efficiency may be provided to be relatively large, so that the color reproducibility of the unit pixel P18 may be improved. A display panel according to an embodiment of the present disclosure may include various suitable pixel structures, and is not limited to any particular embodiment.

In addition, the green sub-pixels SG181 and SG182 are disposed to be symmetrical or substantially symmetrical to each other, and spaced apart from each other in the third direction D3. The areas of the green sub-pixels SG181 and SG182 may be smaller than those of the blue sub-pixels SB181 and SB182. Therefore, a problem in which a green light emission region with relatively high visibility is agglomerated and visually recognized may be prevented or substantially prevented. Accordingly, uniform color expression is possible, which may improve color reproducibility.

As illustrated in FIG. 12F, a display panel may be designed to include a pixel structure including a unit pixel P19 composed of one red sub-pixel SR19, two green sub-pixels SG191 and SG192, and two blue sub-pixels SB191 and SB192. While having the same or substantially the same arrangement as that of the unit pixel P15 illustrated in FIG. 11A, the unit pixel P19 may be composed of sub-pixels SR19, SG191, SG192, SB191, and SB192 that are designed in different shapes.

The red sub-pixel SR19 may have a quadrangular shape, which includes long sides extended along the third direction D3, and short sides extended along the fourth direction D4. The green sub-pixels SG191 and SG192 are disposed to be spaced apart from each other in the third direction D3, with the red sub-pixel SR19 interposed therebetween. Each of the green sub-pixels SG191 and SG192 may have a triangular shape, which includes a side facing the red sub-pixel SR19 in a quadrangular shape.

The blue sub-pixels SB191 and SB192 are disposed to be spaced apart from each other in the fourth direction D4, with the red sub-pixel SR19 interposed therebetween. Each of the blue sub-pixels SB191 and SB192 may have a triangular shape, which includes a side facing the red sub-pixel SR19 in a quadrangular shape.

In the present embodiment, the areas of the blue sub-pixels SB191 and SB189 may be designed to be relatively larger than the area of the red sub-pixel SR19. Accordingly, a blue light emission region with relatively low luminescence efficiency may be provided to be relatively large, so that the color reproducibility of the unit pixel P19 may be improved. A display panel according to an embodiment of the present disclosure may include various suitable pixel structures, and is not limited to any particular embodiment.

In addition, the green sub-pixels SG191 and SG192 are disposed to be symmetrical or substantially symmetrical to each other, and spaced apart from each other in the third direction D3. The areas of the green sub-pixels SG191 and SG192 may be smaller than those of the blue sub-pixels SB191 and SB192. Therefore, a problem in which green light emission regions with relatively high visibility are agglomerated and visually recognized may be prevented or substantially prevented. Accordingly, uniform color expression is possible, which may improve color reproducibility.

As illustrated in FIG. 12G, a display panel may be designed to include a pixel structure including a unit pixel P20 composed of one red sub-pixel SR20, two green sub-pixels SG201 and SG202, and two blue sub-pixels SB201 and SB202. While having the same or substantially the same arrangement as that of the unit pixel P15 illustrated in FIG. 11A, the unit pixel P20 may be composed of sub-pixels SR20, SG201, SG202, SB201, and SB202 that are designed in different shapes.

The red sub-pixel SR20 may have a triangular shape, with a base extended along the first direction D1, and a height extended along the second direction D2. The green sub-pixels SG201 and SG202 are disposed to be spaced apart from each other, with the red sub-pixel SR20 interposed therebetween. One SG201 of the green sub-pixels SG201 and SG202 may have a triangular shape, and the other one SG201 may have a quadrangular shape.

The blue sub-pixels SB201 and SB202 are disposed to be spaced apart from each other in the fourth direction D4, with the red sub-pixel SR20 interposed therebetween. One SB201 of the blue sub-pixels SB201 and SB202 may have a triangular shape, and the other one SG201 may have a quadrangular shape.

The sub-pixels SG201 and SB201 of a triangular shape are spaced apart from each other in the first direction D1, with the red sub-pixel SR20 interposed therebetween. Each of the sub-pixels SG202 and SB202 of a quadrangular shape includes a side facing the red sub-pixel SR20 and extended along the first direction D1, and the sub-pixels SG202 and SB202 of a quadrangular shape may be disposed facing each other in the first direction D1.

In the present embodiment, the areas of the blue sub-pixels SB201 and SB202 may be designed to be relatively larger than the area of the red sub-pixel SR20. Accordingly, a blue light emission region with relatively low luminescence efficiency may be provided to be relatively large, so that the color reproducibility of the unit pixel P20 may be improved. A display panel according to an embodiment of the present disclosure may include various suitable pixel structures, and is not limited to any particular embodiment.

In addition, the green sub-pixels SG201 and SG202 are disposed to be spaced apart from each other in the third direction D3, and the blue sub-pixels SB201 and SB202 are disposed to be spaced apart from each other in the fourth direction D4. According to an embodiment of the present disclosure, by disposing the green sub-pixels SG201 and SG202 and the blue sub-pixels SB201 and SB202 to be spaced apart from each other with the red sub-pixel SR20 interposed therebetween, a problem in which green light emission regions are agglomerated and visually recognized may be prevented or substantially prevented. Accordingly, uniform color expression is possible, which may improve color reproducibility. A display panel according to an embodiment of the present disclosure may include various suitable pixel structures, and is not limited to any particular embodiment.

FIG. 13A and FIG. 13B are plan views illustrating pixel structures according to one or more embodiments of the present disclosure. For convenience of illustration, FIG. 13A and FIG. 13B illustrate partial regions. Hereinafter, embodiments of the present disclosure will be described with reference to FIG. 13A and FIG. 13B.

As illustrated in FIG. 13A, a display panel may be designed to include a pixel structure including a plurality of unit pixels P21. The unit pixel P21 may include a first unit P211 and a second unit P212.

The first unit P211 and the second unit P212 may be disposed along the second direction D2. The second unit P212 may correspond to a shape in which the first unit P211 is rotated by 180 degrees. With respect to a symmetry point, which is the center point of the unit pixel P21, the first unit P211 and the second unit P212 may be in a relationship that is point-symmetrical to each other.

The first unit P211 may be composed of four red sub-pixels SR211, SR212, SR213 and SR214, three green sub-pixel groups Sg211, Sg212 and Sg213, and four blue sub-pixels SB211, SB212, SB213 and SB214.

In the present embodiment, the four red sub-pixels SR211, SR212, SR212 and SR213 and the four blue sub-pixels SB211, SB211 and SB212 may be in a relationship that is line-symmetrical to each other. At positions at which the red sub-pixels SR211, SR212, SR213, and SR214 are line-symmetrical, the blue sub-pixels SB211, SB212, SB213, and SB214 may be respectively disposed. A line symmetry axis may be extended along the second direction D2, and may be defined passing through the center of the first unit P211.

The three green sub-pixel groups Sg211, Sg212 and Sg213 are disposed to be spaced apart from each other. Each of the three green sub-pixel groups Sg211, Sg212 and Sg213 may be composed of a plurality of sub-pixels. In more detail, from among the green sub-pixel groups Sg211, Sg212 and Sg213, a first group Sg211 is disposed at the center of the first unit P211. The line symmetry axis may pass through the center of the first group Sg211. For example, the first group Sg211 may have a rhombic shape, and may be composed of four green sub-pixels, each having a triangular shape.

From among the green sub-pixel groups Sg211, Sg212 and Sg213, a second group Sg212 and a third group Sg213 are disposed to be spaced apart from each other, with the first group Sg211 interposed therebetween. The second group Sg212 and the third group Sg213 may be in a relationship that is line-symmetrical to each other with respect to the above-described line symmetry axis. For example, the second group Sg212 and the third group Sg213 may each have a triangular shape, and may be composed of two green sub-pixels, each having a triangular shape.

The second unit P212 may have a shape that is point-symmetrical to the first unit P211. In other words, the second unit P212 may have a shape corresponding to a shape in which the first unit P211 is rotated by 180 degrees. Accordingly, the sub-pixels constituting the second unit P212 may be in a relationship that is point-symmetrical to the four red sub-pixels SR211, SR212, SR213 and SR214, the three green sub-pixel groups Sg211, Sg212 and Sg213, and the four blue sub-pixels SB211, SB212, SB213 and SB214.

The unit pixel P21 may be provided in a plurality and arranged along the first direction D1, and may be arranged by being shifted by a suitable interval (e.g., a predetermined interval) in the second direction D2. Accordingly, the centers of the plurality of unit pixels may coincide with each other along the first direction D1, but may be positioned to be shifted from each other along the second direction D2. Accordingly, the area of an empty space between the unit pixels may be minimized or reduced, so that a high-resolution display panel may be provided. However, the present disclosure is not limited thereto. In a display panel according to an embodiment of the present disclosure, the unit pixel P21 may be arranged in a matrix form, and is not limited to any particular embodiment.

As illustrated in FIG. 13B, a display panel may be designed to include a pixel structure including a plurality of unit pixels P22. The unit pixel P22 may have a roughly rhombic shape. The unit pixel P22 may include a first unit P221 and a second unit P222, which are in a relationship that is point-symmetrical to each other.

The first unit P221 may be composed of one red sub-pixel SR22, two green sub-pixels SG221 and SG222, and one blue sub-pixel SB22. In the present embodiment, the red sub-pixel SR22 and the blue sub-pixel SB22 may be in a relationship that is line-symmetrical to each other. A line symmetry axis may be extended along the second direction D2, and may be defined passing through the center of the first unit P221.

The two green sub-pixels SG221 and SG222 may have triangular shapes, which are in a relationship that is line-symmetrical with respect to the line symmetry axis. According to an embodiment of the present disclosure, by dispersing a plurality of green light emission regions with relatively high visibility, a defect in which green light emission regions are agglomerated and visually recognized may be prevented or substantially prevented.

As described above, the second unit P222 may have a shape that is point-symmetrical to the first unit P221. In other words, the second unit P222 may have a shape corresponding to a shape in which the first unit P221 is rotated by 180 degrees. Accordingly, the sub-pixels constituting the second unit P222 may be in a relationship that is point-symmetrical to one red sub-pixel and SR22, one green sub-pixel group Sg22, and one blue sub-pixel SB22.

The unit pixel P22 may be provided in a plurality, and arranged along the third direction D3 and the fourth direction D4. Accordingly, the area of an empty space between the unit pixels may be reduced, so that a high-resolution display panel may be easily provided. A display panel according to an embodiment of the present disclosure may include various suitable pixel structures, and is not limited to any particular embodiment.

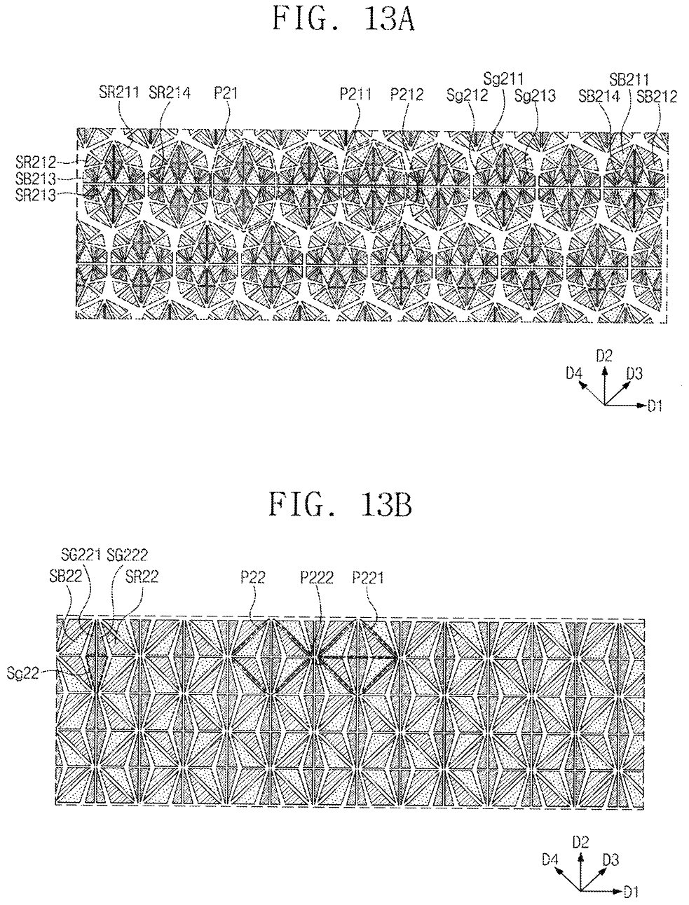

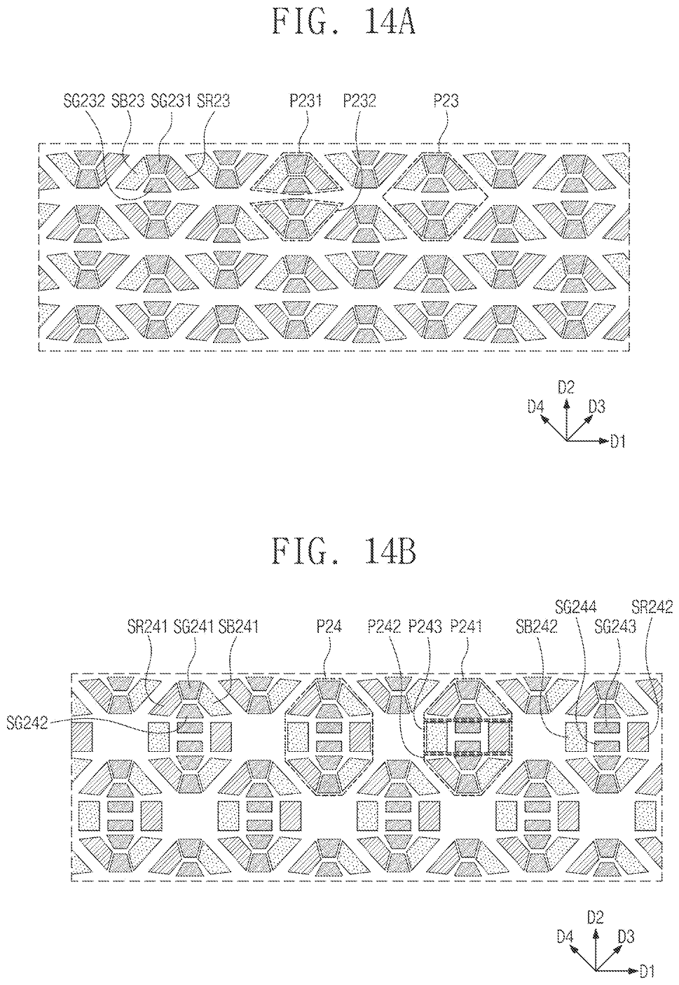

FIG. 14A and FIG. 14B are plan views illustrating pixel structures according to one or more embodiments of the present disclosure. For convenience of illustration, FIG. 14A and FIG. 14B illustrate partial regions. Hereinafter, embodiments of the present disclosure will be described with reference to FIG. 14A and FIG. 14B.

As illustrated in FIG. 14A, a display panel may be designed to include a pixel structure including a plurality of unit pixels P23. The unit pixel P23 may include a first unit P231 and a second unit P232, which are in a relationship that is point-symmetrical to each other.

The first unit P231 may be composed of one red sub-pixel SR23, two green sub-pixels SG231 and SG232, and one blue sub-pixel SB23. In the present embodiment, the red sub-pixel SR23 and the blue sub-pixel SB23 may be in a relationship that is line-symmetrical to each other. A line symmetry axis may be extended along the second direction D2, and may be defined passing through the center of the first unit P231.

The two green sub-pixels SG231 and SG232 are arranged along the second direction D2. Each of the green sub-pixels SG231 and SG232 may have a quadrangular shape. In the present embodiment, each of the green sub-pixels SG231 and SG232 is illustrated as having a trapezoidal shape. According to an embodiment of the present disclosure, by dispersing a plurality of green light emission regions with relatively high visibility, a defect in which green light emission regions are agglomerated and visually recognized may be prevented or substantially prevented.

As described above, the second unit P232 may have a shape that is point-symmetrical to the first unit P231. In other words, the second unit P232 may have a shape corresponding to a shape in which the first unit P231 is rotated by 180 degrees. Accordingly, sub-pixels constituting the second unit P232 may be in a relationship that is point-symmetrical to one red sub-pixel and SR23, two green sub-pixels SG231 and SG232, and one blue sub-pixel SB23.

The unit pixel P23 may be provided in a plurality, and arranged along the third direction D3 and the fourth direction D4. Accordingly, the area of an empty space between the unit pixels may be reduced, so that a high-resolution display panel may be easily provided.

As illustrated in FIG. 14B, a display panel may be designed to include a pixel structure including a plurality of unit pixels P24. The unit pixel P24 may include a first unit P241, a second unit P242, and a third unit P243 disposed between the first unit P241 and the second unit P242. The unit pixel P24 may correspond to a pixel structure in which the third unit P243 is added to the unit pixel P24 illustrated in FIG. 14A.

In more detail, the first unit P241 may be composed of one red sub-pixel SR241, two green sub-pixels SG241 and SG242, and one blue sub-pixel SB241. The first unit P241 corresponds to the first unit P231 of FIG. 14A, and thus, redundant description thereof may not be repeated.

The second unit P242 may be in a relationship that is point-symmetrical to the first unit P241. A symmetry point corresponds to the center of the unit pixel P24, and may overlap with the center of the third unit P243 in the present embodiment. The shape of the second unit P242 corresponds to the shape of the second unit P232 illustrated in FIG. 14A, and thus, redundant description thereof may not be repeated.

The third unit P243 may have a roughly quadrangular shape. In more detail, the third unit P243 may be composed of one red sub-pixel SR242, two green sub-pixels SG243 and SG244, and one blue sub-pixel SB242. Each of the red sub-pixel SR242 and the blue sub-pixel SB242 may have a rectangular shape, with short sides extended along the first direction D1, and long sides extended along the second direction D2. In addition, the red sub-pixel SR242 and the blue sub-pixel SB242 may be in a relationship that is line-symmetrical to each other, and a symmetry axis of the line symmetry may be extended in the second direction D2, and may pass through the center of the unit pixel P24.

The green sub-pixels SG243 and SG244 are disposed between the red sub-pixel SR242 and the blue sub-pixel SB242. The green sub-pixels Sg243 and SG244 may be arranged along the second direction D2. Each of the green sub-pixels SG243 and SG244 may have a rectangular shape, with long sides extended along the first direction D1, and short sides extended along the second direction D2.

The unit pixel P24 may be designed, such that the green sub-pixels are relatively more than the red sub-pixels and/or the blue sub-pixels. According to an embodiment of the present disclosure, by dispersing a plurality of green light emission regions with relatively high visibility, a defect in which green light emission regions are agglomerated and visually recognized may be prevented or substantially prevented.

In addition, the unit pixel P24 may be provided in a plurality, and arranged along the third direction D3 and the fourth direction D4. Accordingly, the area of an empty space between the unit pixels may be reduced, so that a high-resolution display panel may be easily provided. A display panel according to an embodiment of the present disclosure may include various suitable pixel structures, and is not limited to any particular embodiment.

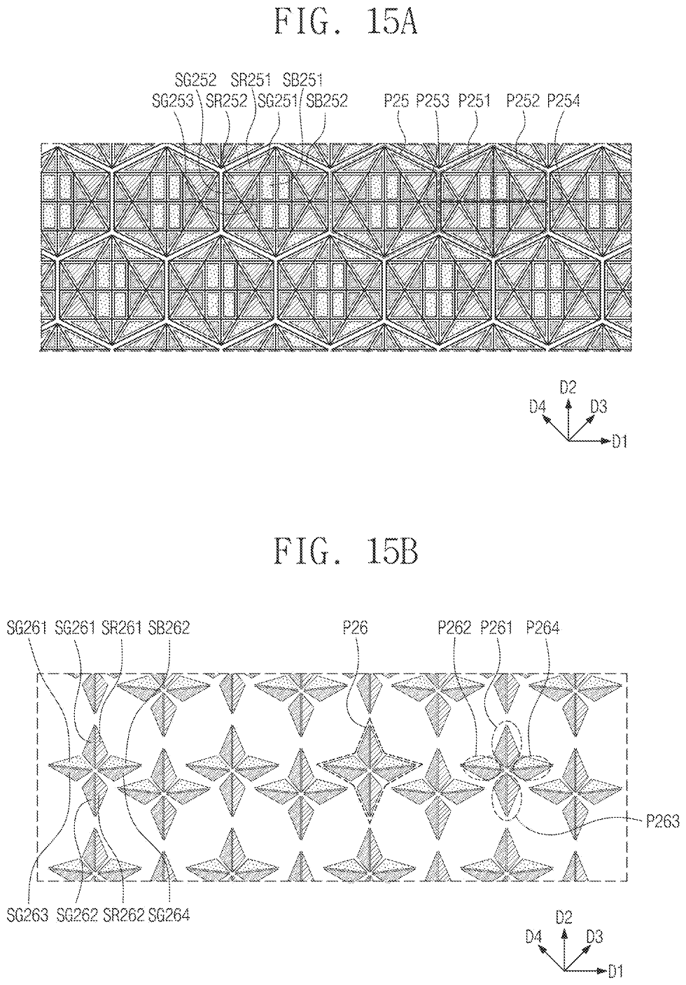

FIG. 15A and FIG. 15B are plan views illustrating pixel structures according to one or more embodiments of the present disclosure. For convenience of illustration, FIG. 15A and FIG. 15B illustrate partial regions. Hereinafter, embodiments of the present disclosure will be described with reference to FIG. 15A and FIG. 15B.

As illustrated in FIG. 15A, a display panel may be designed to include a pixel structure including a plurality of unit pixels P25. The unit pixel P25 may include first to fourth units P251, P252, P253, and P254.

The first unit P251 may be composed of two red sub-pixels SR251 and SR252, three green sub-pixels SG251, SG252, and SG253, and one blue sub-pixel SB251. The first unit P251 may have a trapezoidal shape, with a base and an upper side extended along the second direction D2, and with a height extended along the first direction D1.

The red sub-pixels SR251 and SR252 may face each other in the second direction D2. Each of the red sub-pixels SR251 and SR252 may have a triangular shape. The red sub-pixels SR251 and SR252 may have shapes that are different from each other.

Each of the green sub-pixels SG251, SG252 and SG253 may have a triangular shape. Each of the green sub-pixels SG251, SG252 and SG253 is illustrated as being in a right triangular shape. The blue sub-pixel SB251 may have a quadrangular shape. The blue sub-pixel SB251 is illustrated as being in a rectangular shape, with short sides extended along the first direction D1, and long sides extended along the second direction D2.

While the second unit P252 is in a relationship that is line-symmetrical to the first unit P251, some sub-pixels may be variously modified. In more detail, the sub-pixels constituting the second unit P252 may be in a relationship that is line-symmetrical to the two red sub-pixels SR251 and SR252, the three green sub-pixels SG251, SG252, and SG253, and the one blue sub-pixel SB251. However, the blue sub-pixel SB251 in the second unit P252 may be in a relationship that is line-symmetrical to the red sub-pixel SR251 in the first unit P251. Therefore, unlike the first unit P251, the second unit P252 may be composed of one red sub-pixel, three green sub-pixels, and two blue sub-pixels.

The third unit P253 may be in a relationship that is line-symmetrical to the first unit P251. A symmetry axis between the third unit P253 and the first unit P251 may be extended along the first direction D1, and may pass through the center of the unit pixel P25. The fourth unit P254 may be in a relationship that is line-symmetrical to the second unit P252. A symmetry axis between the fourth unit P254 and the second unit P252 may be extended along the first direction D1, and may pass through the center of the unit pixel P25.

The unit pixel P25 may have a hexagonal shape. The plurality of unit pixels may be disposed, such that each side faces one another. Accordingly, the area of an empty space between the unit pixels may be reduced, so that a high-resolution display panel may be easily provided.

As illustrated in FIG. 15B, a display panel may be designed to include a pixel structure including a plurality of unit pixels P26. The unit pixel P26 may include first to fourth units P261, P262, P263, and P264. The first to fourth units P261, P262, P263, and P264 may be disposed at positions rotated every 90 degrees along the counterclockwise direction, and each thereof may be composed of sub-pixels that are line-symmetrical to each other. The sub-pixels constituting each of the first to fourth units P261, P262, P263, and P264 may emit different colors from each other.

In more detail, the unit pixel P26 may correspond to a roughly quadrangular star shape. The shape of the unit pixel P26 includes four convex vertexes, and four concave vertexes disposed between the four convex vertexes, and is defined by eight sides that connect between the vertexes. The shape of the unit pixel P26 may have a shape that is convex at the convex vertexes toward the center, and concave at the concave vertexes. The shape of the unit pixel P26 may correspond to a shape in which four triangles are disposed in four directions, which are perpendicular to or substantially perpendicular to each other.

The unit pixel P26 may be composed of two red sub-pixels SR261 and SR262, four green sub-pixels SG261, SG262, SG263 and SG264, and two blue sub-pixels SB261 and SB262.

The red sub-pixels SR261 and SR262 may be in a relationship that is line-symmetrical to each other. A symmetry axis may be extended along the first direction D1, and may pass through the center of the unit pixel P26. Each of the red sub-pixels SR261 and SR262 may have a triangular shape, with a base extended along the second direction D2, and a height extended along the first direction D1.

The blue sub-pixels SB261 and SB262 may be in a relationship that is line-symmetrical to each other. A symmetry axis may be extended along the second direction D2, and may pass through the center of the unit pixel P26. Each of the blue sub-pixels SB261 and SB262 may have a triangular shape, with a base extended along the first direction D1, and a height extended along the second direction D2.

The green sub-pixels SG261, SG262, SG263, and SG264 may be disposed facing the red sub-pixels SR261 and SR262 and the blue sub-pixels SB261 and SB262. The green sub-pixels SG261, SG262, SG262 and SG263 may be in a relationship that is point-symmetrical to each other. For example, the green sub-pixels SG261, SG262, SG263, and SG264 may be shapes in which one green sub-pixel SG261 is rotated by 0 degrees, 90 degrees, 180 degrees, and 270 degrees.

In the unit pixel P26, it may be designed that the green sub-pixels are relatively more than the red sub-pixels and/or the blue sub-pixels. According to an embodiment of the present disclosure, by dispersing a plurality of green light emission regions with relatively high visibility, a defect in which green light emission regions are agglomerated and visually recognized may be prevented or substantially prevented.

In addition, the unit pixel P26 may be provided in a plurality, and arranged along the third direction D3 and the fourth direction D4. Accordingly, the area of an empty space between the unit pixels may be reduced, so that a high-resolution display panel may be easily provided.

The unit pixel P26 may be provided in a plurality, and arranged along the second direction D2, and may be arranged by being shifted by a suitable interval (e.g., a predetermined interval) in the first direction D1. Accordingly, the centers of the plurality of unit pixels P26 coincide with each other along the second direction D2, but may be positioned to be shifted from each other along the first direction D1. Accordingly, compared to an arrangement in which the unit pixels are disposed in one line along the first direction D1, an empty space may be relatively reduced, so that a display panel with a high pixel density may be provided, and a high resolution display panel may be designed. A display panel according to an embodiment of the present disclosure may include various suitable pixel structures, and is not limited to any particular embodiment.

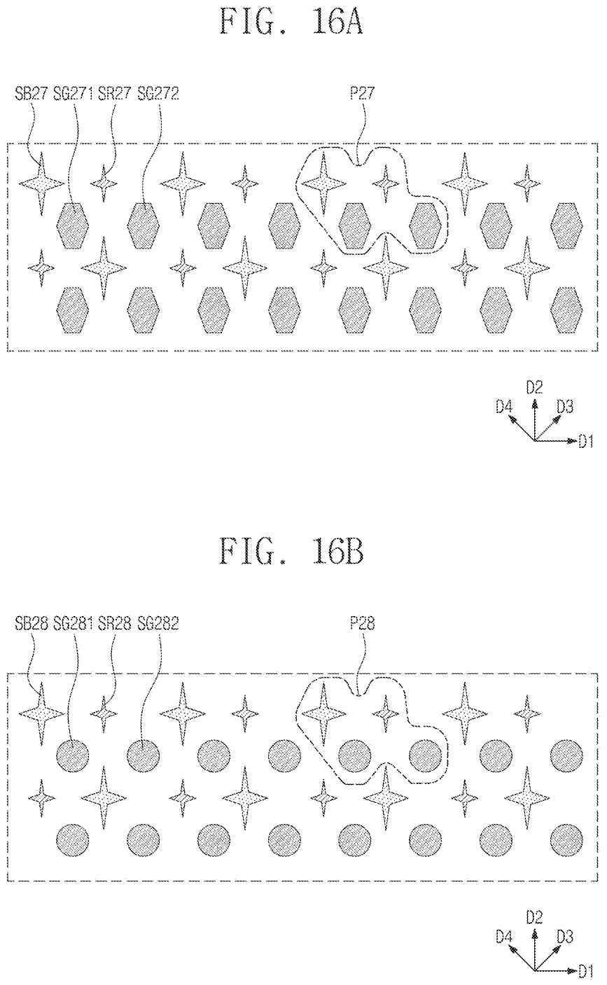

FIG. 16A and FIG. 16B are plan views illustrating pixel structures of a display panel according to one or more embodiments of the present disclosure. For convenience of illustration, FIG. 16A to FIG. 16D illustrate partial regions. Hereinafter, embodiments of the present disclosure will be described with reference to FIG. 16A to FIG. 16D.

As illustrated in FIG. 16A, a display panel may have a pixel structure including a plurality of unit pixels P27. The unit pixel P27 may be composed of one red sub-pixel SR27, one blue sub-pixel SB27, and two green sub-pixels SG271 and SG272. Each of the red sub-pixel SR27 and the blue sub-pixel SB27 may have a quadrangular star shape. Each of the red sub-pixel SR27 and the blue sub-pixel SB27 may correspond to a shape in which four triangles are disposed along four directions that are perpendicular or substantially perpendicular to each other. The shape of each of the red sub-pixel SR27 and the blue sub-pixel SB27 may be defined by four convex vertexes, four concave vertexes, and eight sides.

The green sub-pixels SG271 and SG272 are disposed to be spaced apart from each other in the first direction D1. The green sub-pixels SG271 and SG272 may have the same or substantially the same shape as each other. Each of the green sub-pixels SG271 and SG272 may have a regular hexagonal shape.

The unit pixel P27 may be provided in a plurality, and the centers of the unit pixels may be arranged in parallel or substantially in parallel with each other along the first direction D1, and may be arranged by being shifted along the second direction D2. The unit pixels may be arranged along the first direction D1 in the horizontal direction, and may be arranged along the third direction D3 or the fourth direction D4 in the vertical direction.

In the entire display panel, the red sub-pixel SR27 and the blue sub-pixel SB27 may be alternately arranged along the first direction D1 and the second direction D2. The green sub-pixels SG271 and SG272 may be arranged along the first direction D1 and the second direction D2.

The green sub-pixel SG271 and the red sub-pixel SR27 may be arranged along the third direction D3, and the green sub-pixel SG271 and the blue sub-pixel SB27 may be arranged along the fourth direction D4. The green sub-pixel SG272 and the blue sub-pixel SB27 may be arranged along the third direction D3, and the green sub-pixel SG272 and the red sub-pixel SR27 may be arranged along the fourth direction D4.

In the present embodiment, the blue sub-pixel SB27 may have a larger area than that of the red sub-pixel SR27. Accordingly, a blue light emission region with relatively low luminescence efficiency may be provided to be relatively large, so that the color reproducibility of the unit pixel P27 may be improved. In addition, in the unit pixel P27, it may be designed so that green sub-pixels are relatively more than red sub-pixels and/or blue sub-pixels. According to an embodiment of the present disclosure, by dispersing a plurality of green light emission regions with relatively high visibility, a defect in which green light emission regions are agglomerated and visually recognized may be prevented or substantially prevented.

As illustrated in FIG. 16B, a display panel may have a pixel structure including a plurality of unit pixels P28. The unit pixel P28 may be composed of one red sub-pixel SR28, one blue sub-pixel SB28, and two green sub-pixels SG281 and SG282. The red sub-pixel SR28 and the blue sub-pixel SB28 correspond to the red sub-pixel SR27 and the blue sub-pixel SB27, and thus, redundant description thereof may not be repeated.

The green sub-pixels SG281 and SG282 are disposed to be spaced apart from each other in the first direction D1. The green sub-pixels SG281 and SG282 may have the same or substantially the same shape as each other. Each of the green sub-pixels SG281 and SG282 may have a circular shape.

In the unit pixel P28, it may be designed so that green sub-pixels are relatively more than red sub-pixels or blue sub-pixels. According to an embodiment of the present disclosure, by dispersing a plurality of green light emission regions with relatively high visibility, a defect in which green light emission regions are agglomerated and visually recognized may be prevented or substantially prevented. A display panel according to an embodiment of the present disclosure may include various suitable pixel structures, and is not limited to any particular embodiment.

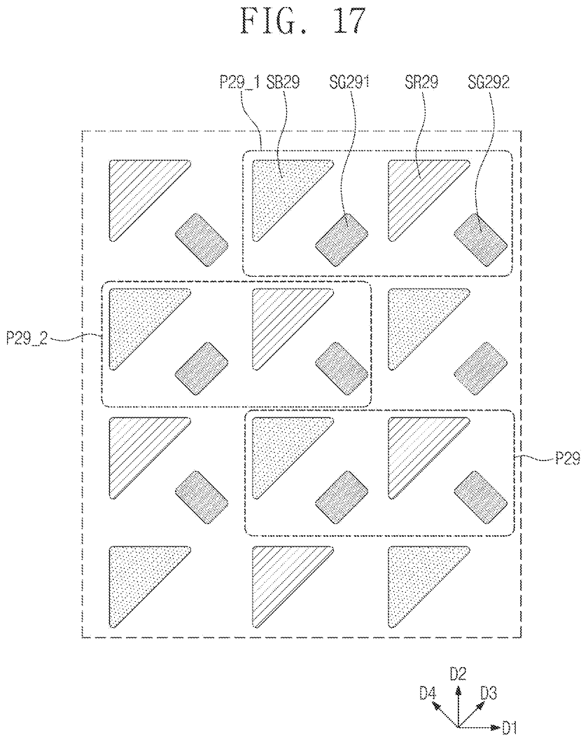

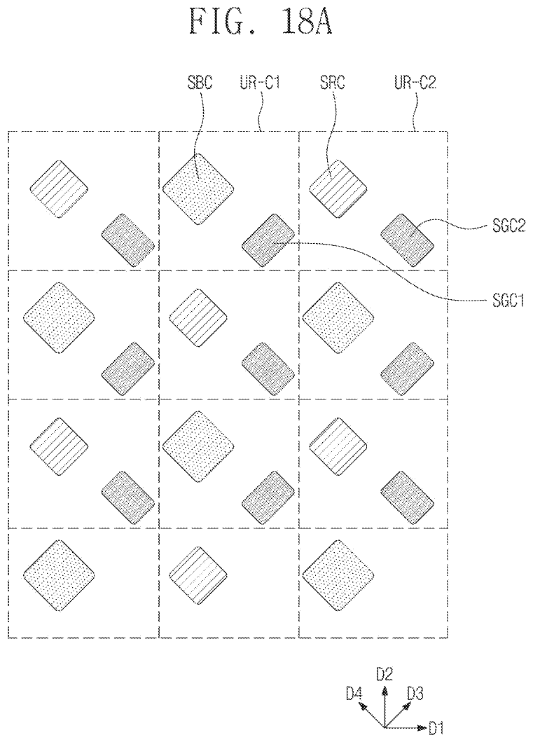

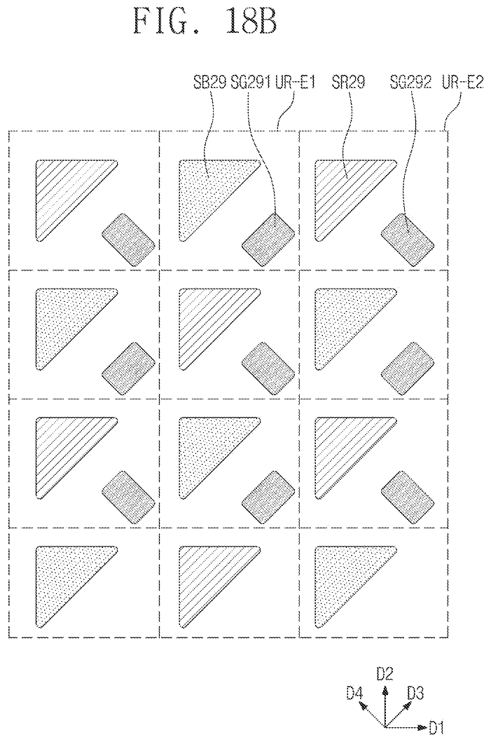

FIG. 17 is a plan view illustrating a pixel structure of a display panel according to an embodiment of the present disclosure. FIG. 18A is a plan view illustrating a pixel structure of a comparative example. FIG. 18B is a plan view illustrating the pixel structure illustrated in FIG. 17. Hereinafter, embodiments of the present disclosure will be described with reference to FIG. 17 to FIG. 18B.

As illustrated in FIG. 17, unit pixels P29_1 and P29_2 may be arranged along the first direction D1, and may be arranged by being shifted along the second direction D2. The unit pixels P29_1 and P29_2 may each be composed of one red sub-pixel SR29, two green sub-pixels SG291 and SG292, and one blue sub-pixel SB29.

The red sub-pixel SR29 may have a right triangular shape, with a base extended along the first direction D1, and a height extended along the second direction D2. The blue sub-pixel SB29 is spaced apart from the red sub-pixel SR29 in the first direction D1. The blue sub-pixel SB29 may have a shape same or substantially the same as the shape of the red sub-pixel SR29. The green sub-pixels SG291 and SG292 may each have a rectangular shape. The green sub-pixels SG291 and SG292 may be in a relationship that is line-symmetrical to each other. In the present embodiment, a triangle or a rectangle may include a shape with rounded vertexes.

One SG291 of the green sub-pixels SG291 and SG292 may have a rectangular shape, with long sides extended along the third direction D3, and short sides extended along the fourth direction D4. The other SG292 of the green sub-pixels SG291 and SG292 may have a rectangular shape, with short sides extended along the third direction D3, and long sides extended along the fourth direction D4.

The blue sub-pixel SB29 and the green sub-pixel SG291 may include sides facing each other. The facing sides may be parallel to or substantially parallel to each other. In the present embodiment, the blue sub-pixel SB29 and the green sub-pixel SG291 include sides facing each other in the fourth direction D4, and the sides may each be parallel to or substantially parallel to the third direction D3.

In addition, the red sub-pixel SR29 and the green sub-pixel SG292 may include sides facing each other. The facing sides may be parallel to or substantially parallel to each other. In the present embodiment, the red sub-pixel SR29 and the green sub-pixel SG292 include sides facing each other in the fourth direction D4, and the sides may each be parallel to or substantially parallel to the third direction D3.

Referring to FIG. 18A, a display panel according to the comparative example includes a unit pixel composed of one red sub-pixel SRC, one blue sub-pixel SBC, and two green sub-pixels SGC1 and SGC2. The two green sub-pixels SGC1 and SGC2 correspond to the green sub-pixels SG291 and SG292 of the unit pixel P29, and the red sub-pixel SRC and the blue sub-pixel SBC may have a rhombic shape.

Referring to FIG. 18A and FIG. 18B, the red sub-pixel SR29 and the blue sub-pixel SB29 according to an embodiment of the present disclosure may have a greater area then the red sub-pixel SRC and the blue sub-pixel SBC of the comparative example. Accordingly, unit regions in the present embodiment may have luminescence efficiency higher than that of unit regions UR-C1 and UR-C2 in the comparative example. According to an embodiment of the present disclosure, shapes of a red light emission region and a blue light emission region may be variously modified, so as to be designed to have a larger area.

In addition, while being provided in a smaller area than those of a red light emission region or a blue light emission region in the unit pixel P29, green light emission regions may be divided and provided in a larger number. Accordingly, a green light emission region with relatively high visibility may be dispersed to allow the green light emission region to be evenly distributed in the unit pixel P29. Therefore, a display panel with improved color reproducibility may be provided.

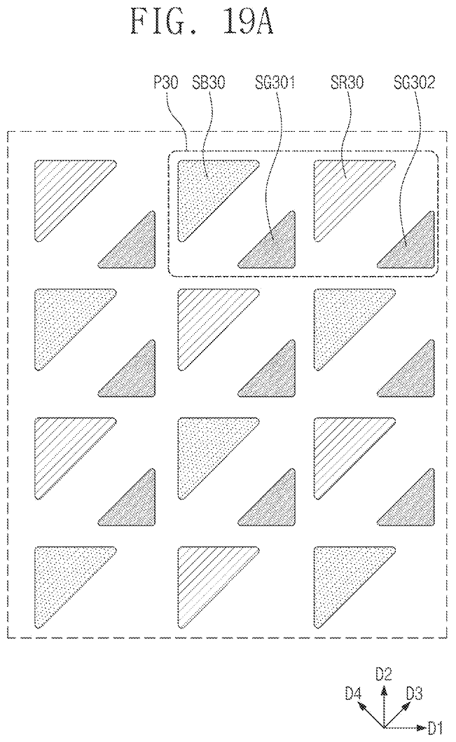

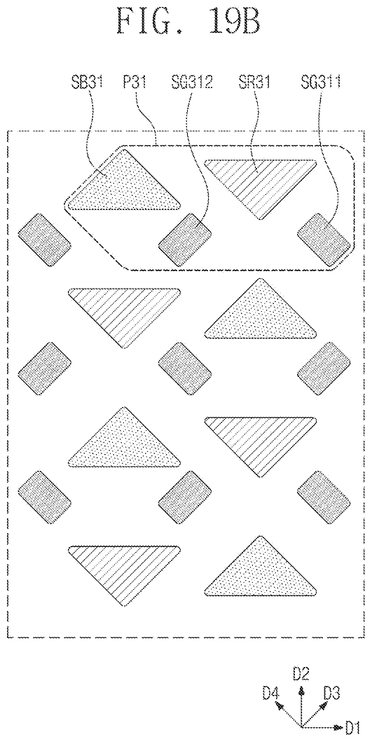

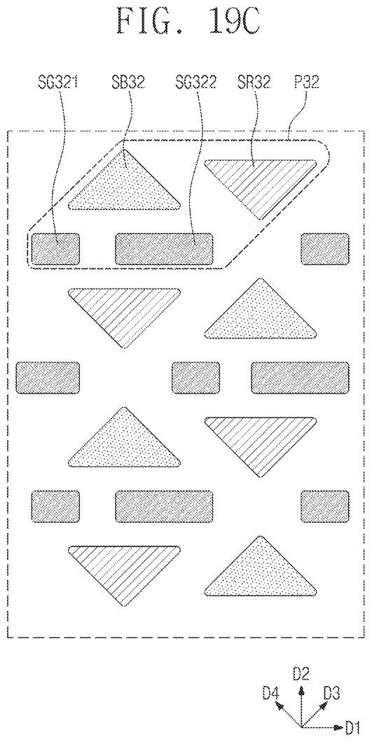

FIG. 19A to FIG. 19C are plan views illustrating pixel structures according to one or more embodiments of the present disclosure. FIG. 19A and FIG. 19C illustrate a region corresponding to that shown in FIG. 17.

As illustrated in FIG. 19A, a unit pixel P30 may be composed of one red sub-pixel SR30, two green sub-pixels SG301 and SG302, and one blue sub-pixel SB30. The red sub-pixel SR30 and the blue sub-pixel SB30 may respectively correspond to the red sub-pixel SR29 and the blue sub-pixel SB29 illustrated in FIG. 17. Therefore, redundant description thereof may not be repeated.

The green sub-pixels SG301 and SG302 are disposed the same as the green sub-pixels SG291 and SR292 illustrated in FIG. 17, but may have different shapes. The green sub-pixels SG301 and SG302 may each have a right triangular shape, with a base extended along the first direction D1, and a height extended along the second direction D2.

As illustrated in FIG. 19B, a unit pixel P31 may be composed of one red sub-pixel SR31, two green sub-pixels SG311 and SG312, and one blue sub-pixel SB31. The red sub-pixel SR31 may have a triangular shape, with a base extended along the first direction D1, and a height extended along the second direction D2. The blue sub-pixel SB31 may correspond to a shape in which the red sub-pixel SR31 is rotated by 180 degrees. The green sub-pixels SG311 and SG312 may respectively correspond to the sub-pixels SG301 and SG302 illustrated in FIG. 17. Therefore, redundant description thereof may not be repeated.

As illustrated in FIG. 19C, a unit pixel P32 may be composed of one red sub-pixel SR32, two green sub-pixels SG321 and SG322, and one blue sub-pixel SB32. The red sub-pixel SR32 and the blue sub-pixel SB32 may respectively correspond to the red sub-pixel SR31 and the blue sub-pixel SB31 illustrated in FIG. 19B. Therefore, redundant description thereof may not be repeated.

The green sub-pixels SG321 and SG322 are arranged along the first direction D1. The green sub-pixels SG321 and SG322 may each have a rectangular shape, which includes long sides extended along the first direction D1, and short sides extended along the second direction D2. The green sub-pixels SG321 and SG322 may have different shapes from each other. The green sub-pixels SG321 and SG322 may be provided in different areas from each other.

According to an embodiment of the present disclosure, because a red light emission region and a green light emission region have a triangular shape, the area of a light emission region occupying a predetermined region may be secured to be large. Accordingly, the luminescence efficiency of a display panel may be improved. In addition, while being provided in a smaller area than those of a red light emission region or a blue light emission region in a unit pixel, green light emission regions may be divided and provided in a larger number. Accordingly, a green light emission region with relatively high visibility may be dispersed to allow the green light emission region to be evenly distributed in the unit pixel. Therefore, a display panel with improved color reproducibility may be provided.

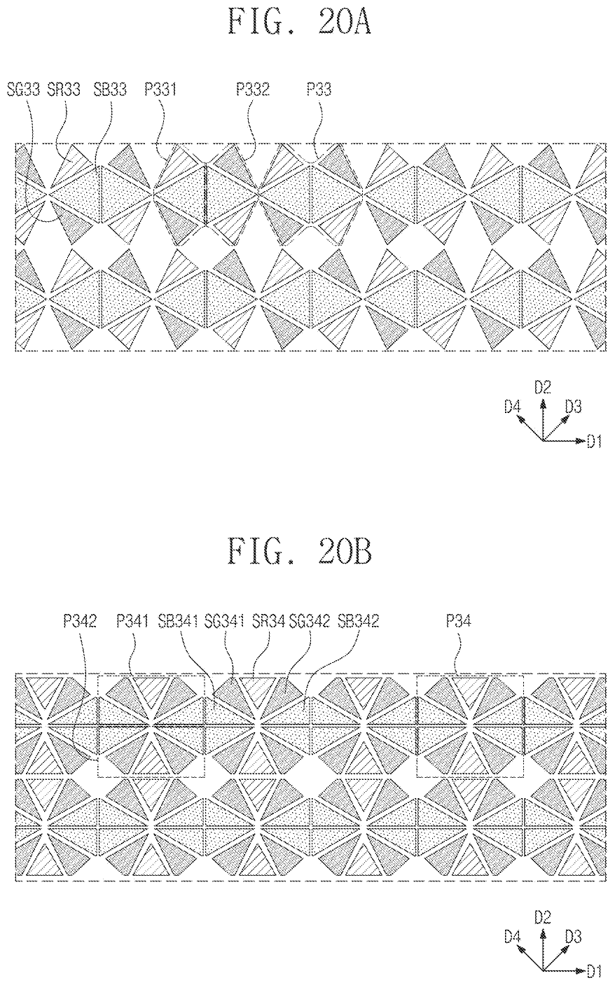

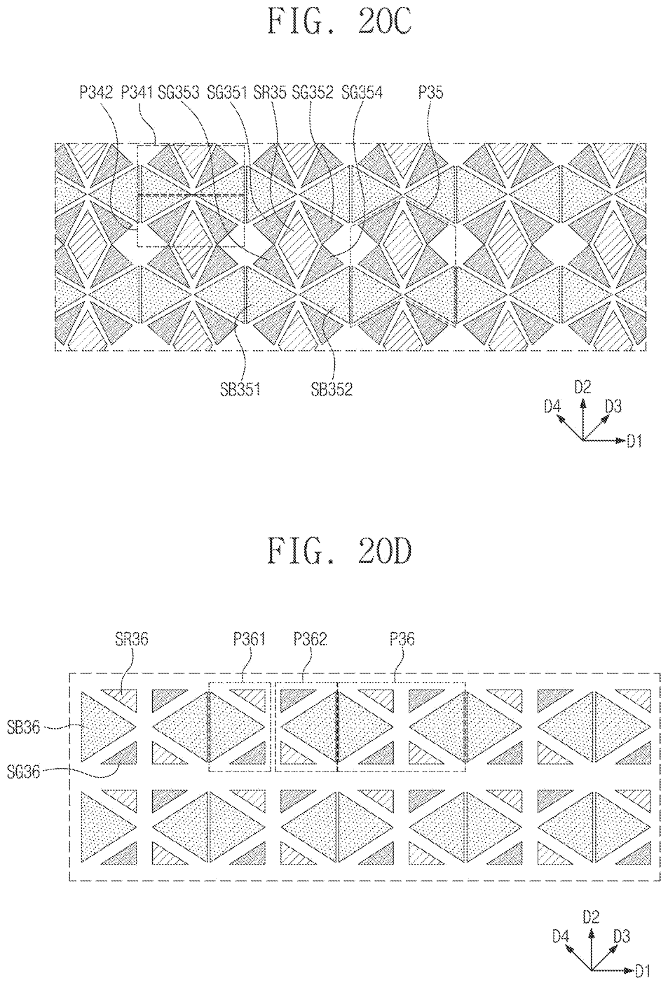

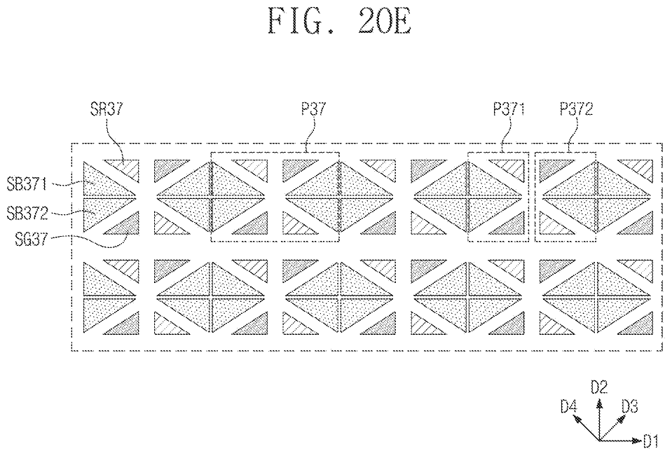

FIG. 20A to FIG. 20E are plan views illustrating pixel structures according to one or more embodiments of the present disclosure. For convenience of illustration, FIG. 20A to FIG. 20E illustrate partial regions. Hereinafter, embodiments of the present disclosure will be described with reference to FIG. 20A to FIG. 20E.

Referring to FIG. 20A, a display panel may be designed to include a pixel structure including a plurality of unit pixels P33. The unit pixel P33 may include a first unit P331 and a second unit P332.

The first unit P331 may be composed of one red sub-pixel SR33, one green sub-pixel SG33, and one blue sub-pixel SB33. In the first unit P331, the green sub-pixel SG33, the blue sub-pixel SB33, and the red sub-pixel SR33 may be arranged along the second direction D2.

The second unit P332 is disposed to be spaced apart from the first unit P331 in the first direction D1. The first unit P331 and the second unit P332 may be in a relationship that is point-symmetrical to each other. Sub-pixels constituting the second unit P332 may correspond to shapes in which the red sub-pixel SR33, the green sub-pixel SG33, and the blue sub-pixel SB33 are each rotated by 180 degrees with respect to the unit pixel P33.

Referring to FIG. 20B, a unit pixel P34 may include a first unit P341 and a second unit P342, which are arranged along the second direction D2. The first unit P341 may be composed of one red sub-pixel SR34, two green sub-pixels SG341 and SG342, and two blue sub-pixels SB341 and SB342.

The red sub-pixel SR34 may have a triangular shape, with a base extended along the first direction D1, and a height extended along the second direction D2. The green sub-pixels SG341 and SG342 may be disposed to be spaced apart from each other in the first direction D1, with the red sub-pixel SR34 interposed therebetween. The green sub-pixels SG341 and SG342 may be in a relationship that is line-symmetrical to each other. A symmetry axis may be extended along the second direction D2, and may pass through the center of the unit pixel P34. The symmetry axis may be extended and defined in a direction parallel to or substantially parallel to the height of the red sub-pixel SR34.

The blue sub-pixels SB341 and SB342 are spaced apart from each other and disposed in the first direction D1, with the red sub-pixel SR34 and the two green sub-pixels SG341 and SG341 interposed therebetween. The blue sub-pixels SB341 and SB342 may be in a relationship that is line-symmetrical to each other.

The second unit P342 may be in a relationship that is line-symmetrical to the first unit P341. Therefore, sub-pixels constituting the second unit P342 may correspond to shapes in which the red sub-pixel SR34, the green sub-pixels SG341 and SG342, and the blue sub-pixel SB341 are each line-symmetrical.

Referring to FIG. 20C, a unit pixel P35 may include one red sub-pixel SR35, four green sub-pixels SG351, SG352, SG353 and SG354, and two blue sub-pixels SB351 and SB352. The red sub-pixel SR35 may have a rhombic shape.

The green sub-pixels SG351, SG352, SG353 and SG354 are disposed to surround (e.g., around a periphery of) the edge of the red sub-pixel SR35. The green sub-pixels SG351, SG352, SG353 and SG354 may each have a triangular shape. The blue sub-pixels SB351 and SB352 may be in a relationship that is line-symmetrical to each other. A symmetry axis of the line symmetry may be extended along the second direction D2, and may pass through the center of the unit pixel P35

A pixel structure which includes the unit pixel P35 may correspond to a shape in which the units P341 and P342 constituting the unit pixel P34 of FIG. 20B are connected to each other without being spaced apart from each other. Accordingly, the pixel structure illustrated in FIG. 20C may secure a relatively large light emission area compared to the pixel structure illustrated in FIG. 20B.

Referring to FIG. 20D, a unit pixel P36 may have a quadrangular shape. The unit pixel P36 may include a first unit P361 and second unit P362, which are arranged along the first direction D1. The first unit P361 and the second unit P362 may each have a rectangular shape.

The first unit P361 may be composed of one red sub-pixel SR36, one green sub-pixel SG36, and one blue sub-pixel SB36. In the first unit P361, the red sub-pixel SR36, the blue sub-pixel SB36, and the greed sub-pixel SR36 may be arranged along the second direction D2.

The red sub-pixel SR36 and the green sub-pixel SG36 are spaced apart from each other in the second direction D2, with the blue sub-pixel SB36 interposed therebetween. The red sub-pixel SR36 and the green sub-pixel SG36 may be in a relationship that is line-symmetrical to each other. For example, the red sub-pixel SR36 and the green sub-pixel SG36 may each have a right triangular shape, and the right triangular shapes are extended along the first direction D1, and may be in a relationship that is line-symmetrical to each other based on a symmetry axis which pass through the center of the unit pixel P36.

The blue sub-pixel SB36 may have a triangular shape. The blue sub-pixel SB36 may have a triangular shape, which includes sides respectively facing the red sub-pixel SR36 and the green sub-pixel SG36, and a side constituting a portion of the edge of the unit pixel P36.

The second unit P362 may be in a relationship that is point-symmetrical to the first unit P361. The second unit P362 may correspond to a shape in which the first unit P361 is rotated by 180 degrees with respect to the center of the unit pixel P36. Accordingly, the blue sub-pixel SB36 may be disposed to face a blue sub-pixel of another adjacent unit pixel.

As illustrated in FIG. 20E, a unit pixel P37 may include a larger number of blue light emission regions compared to the unit pixel P36 illustrated in FIG. 20D. The unit pixel P37 may include a first unit P371 and a second unit P372, which are arranged along the first direction D1, and the first unit P371 and the second unit P372 may be in a relationship that is point-symmetrical to each other, or may be in a relationship 180-degree rotational symmetrical to each other.

The first unit P371 may be composed of one red sub-pixel SR37, one green sub-pixel SG37, and two blue sub-pixels SB371 and SB372. From among the above, sub-pixels constituting the first unit P371 correspond to the sub-pixels illustrated in FIG. 20D, and may correspond to a structure in which the blue sub-pixels SB36 are divided. In other words, the blue sub-pixels SB371 and SB372 may correspond to a structure in which the blue sub-pixel SB36 of FIG. 20D is divided with respect to a virtual line which passes through the center of the blue sub-pixel SB36, and is extended along the first direction D1. The two blue sub-pixels SB371 and SB372 may be in a relationship that is line-symmetrical to each other with respect to the virtual line. The unit pixel P37 may have improved color reproducibility by subdividing a blue light emission region.

According to an embodiment of the present disclosure, the area of a blue sub-pixel in a unit pixel may be larger than the area of a red sub-pixel. Accordingly, a blue light emission region with relatively low luminescence efficiency may be provided to be relatively large, so that the color reproducibility of the unit pixel may be improved.

In addition, according to an embodiment of the present disclosure, green sub-pixels may be spaced apart from each other and symmetrically disposed. Accordingly, a green light emission region with relatively high visibility may be dispersed to allow the green light emission region to be evenly distributed in the unit pixel. Therefore, a display panel with improved color reproducibility may be provided. A display panel according to an embodiment of the present disclosure may include various suitable pixel structures, and is not limited to any one embodiment.

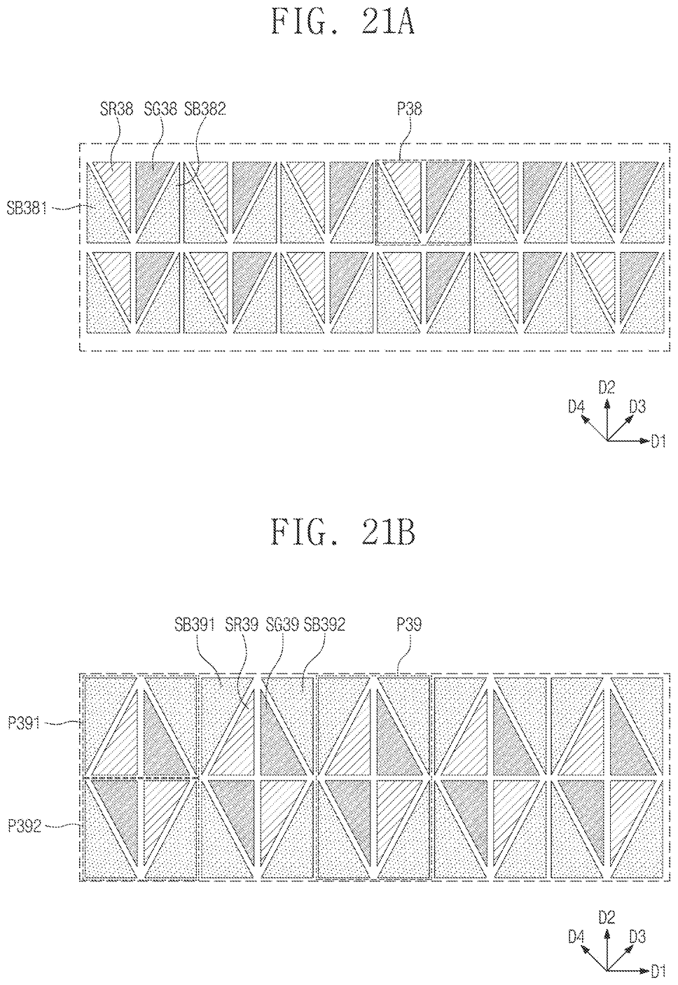

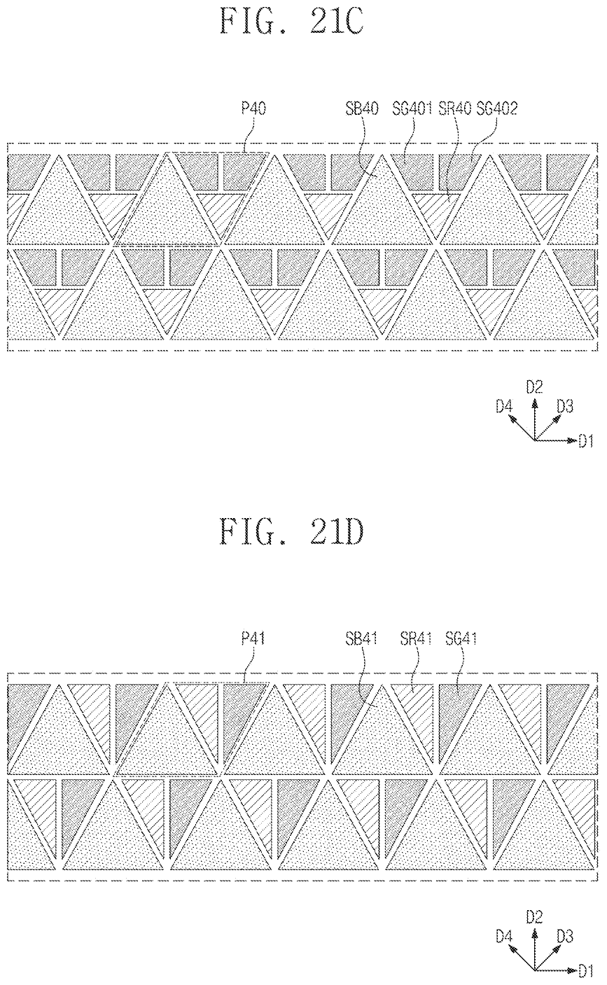

FIG. 21A to FIG. 21D are plan views illustrating pixel structures according to one or more embodiments of the present disclosure. For convenience of illustration, FIG. 21A to FIG. 21D illustrate partial regions. Hereinafter, embodiments of the present disclosure will be described with reference to FIG. 21A to FIG. 21D.

As illustrated in FIG. 21A, a unit pixel P38 may be composed of one red sub-pixel SR38, one green sub-pixel SG38, and two blue sub-pixels SB381 and SB382. The red sub-pixel SR38 and the green sub-pixel SG38 may be in a relationship that is line-symmetrical to each other with respect to a symmetry axis, which is extended along the second direction D2 and passes through the center of the unit pixel P38. For example, the red sub-pixel SR38 and the green sub-pixel SG38 may each have a right triangular shape, with a base extended along the first direction D1 and a height extended along the second direction D2.

The blue sub-pixels SB381 and SB382 are spaced apart from each other in the first direction D1, with the red sub-pixel SR38 and the green sub-pixel SG38 interposed therebetween. The blue sub-pixels SB381 and SB382 may be in a relationship line-symmetrical to each other with respect to the symmetry axis. For example, the blue sub-pixels SB381 and SB382 may each have a right triangular shape, with a base extended along the first direction D1 and a height extended along the second direction D2.

The unit pixel P38 may have a roughly square shape defined by four triangles. A display panel illustrated in FIG. 21A may have a pixel structure in which a plurality of unit pixels P38 are repeatedly arranged in a matrix form arranged along the first direction D1 and the second direction D2. Accordingly, the blue sub-pixels SB381 and SB382 are disposed to face blue sub-pixels of adjacent unit pixels in the first direction D1.

As illustrated in FIG. 21B, a unit pixel P39 may include a first unit P391 and a second unit P392, which are arranged along the second direction D2.

The first unit P391 may be composed of one red sub-pixel SR39, one green sub-pixel SG39, and two blue sub-pixels SB391 and SB392. The red sub-pixel SR39 and the green sub-pixel SG39 may be in a relationship line-symmetrical to each other with respect to a symmetry axis, which is extended along the second direction D2 and passes through the center of the unit pixel P39. For example, the red sub-pixel SR39 and the green sub-pixel SG39 may each have a right triangular shape, with a base extended along the first direction D1 and a height extended along the second direction D2.

The blue sub-pixels SB391 and SB392 are spaced apart from each other in the first direction D1, with the red sub-pixel SR39 and the green sub-pixel SG39 interposed therebetween. The blue sub-pixels SB391 and SB392 may be in a relationship line-symmetrical to each other with respect to the symmetry axis. For example, the blue sub-pixels SB391 and SB392 may each have a right triangular shape, with a base extended along the first direction D1 and a height extended along the second direction D2.

The second unit P392 may be in a relationship point-symmetrical to the first unit P391. The second unit P392 may correspond to a shape in which the first unit P391 is rotated by 180 degrees. Therefore, sub-pixels constituting the second unit P392 may have shapes in which the red sub-pixel SR39, the green sub-pixel SG39, and the blue sub-pixels SB391 and SB392 are each line-symmetrical.

The unit pixel P39 may have a roughly quadrangular shape defined by eight triangles. A display panel illustrated in FIG. 21B has a pixel structure in which the blue sub-pixels SB391 and SB392 are disposed to face a blue sub-pixel of an adjacent unit pixel.

As illustrated in FIG. 21C, a unit pixel P40 may be composed of one red sub-pixel SR40, two green sub-pixels SG401 and SG402, and one blue sub-pixel SB40. The red sub-pixel SR40 may have a triangular shape. The green sub-pixels SG401 and SG402 may be in a relationship line-symmetrical to each other. For example, the green sub-pixels SG401 and SG402 may each have a trapezoidal shape, which is line symmetrical to or substantially symmetrical to each other with respect to a symmetry axis extended along the second direction D2.

The green sub-pixels SG401 and SG402 are disposed along the second direction D2 with the red sub-pixel SR40. The green sub-pixels SG401 and SG402 each face one red sub-pixel SR40. The arrangement of the red sub-pixel SR40 and the green sub-pixels SG401 and SG401 may have a roughly triangular shape.

The blue sub-pixel SB40 may have a triangular shape. The triangular shape of the blue sub-pixel SB40 may be in a relationship point-symmetrical to the triangular shape defined by the arrangement of the red sub-pixel SR40 and the green sub-pixels SG401 and SG401. Accordingly, in the unit pixel P40, the blue sub-pixel SB40 may be provided in the same or substantially the same area as the sum of the areas of the red sub-pixel SR40 and the green sub-pixels SG401 and SG401.

The unit pixel P40 may have a trapezoidal shape. The unit pixel P40 may be arranged along the first direction D1 and the third direction D3. Therefore, a display panel may have a pixel structure which may minimize or reduce the area of an empty space.

As illustrated in FIG. 21D, a unit pixel P41 may be composed of one red sub-pixel SR41, one green sub-pixel SG41, and one blue sub-pixel SB41. The unit pixel P41 may have a trapezoidal shape, and may have a shape and an arrangement which correspond to those of the unit pixel P40 illustrated in FIG. 21C. The blue sub-pixel SB41 may correspond to the blue sub-pixel SB40 illustrated in FIG. 21C, and thus, redundant description thereof may not be repeated.

The red sub-pixel SR41 and the green sub-pixel SG41 may be in a relationship line-symmetrical to each other. For example, the red sub-pixel SR41 and the green sub-pixel SG41 may each have a triangular shape, which is line symmetrical or substantially symmetrical to each other with respect to a symmetry axis extended along the second direction D2. The arrangement of the red sub-pixel SR41 and the green sub-pixels SG41 may have a roughly triangular shape. Sum of the red sub-pixel SR41 and the green sub-pixel SG41 may have the same or substantially the same size and shape as those of the blue sub-pixel SB41.

According to an embodiment of the present disclosure, blue light emission regions may be disposed to be gathered at roughly one place, or the area of a blue light emission region may be designed to be larger than the area of a red light emission region. Accordingly, a blue light emission region with relatively low luminescence efficiency may be provided to be relatively large, so that the color reproducibility of a display panel may be improved. A display panel according to an embodiment of the present disclosure may include various suitable pixel structures, and is not limited to any particular embodiment.

In addition, according to an embodiment of the present disclosure, green sub-pixels may be disposed to be spaced apart from each other, unlike the blue sub-pixels. Accordingly, a green light emission region with relatively high visibility may be dispersed to allow the green light emission region to be evenly distributed in the unit pixel. Therefore, a display panel with improved color reproducibility may be provided. A display panel according to an embodiment of the present disclosure may include various suitable pixel structures, and is not limited to any one embodiment.

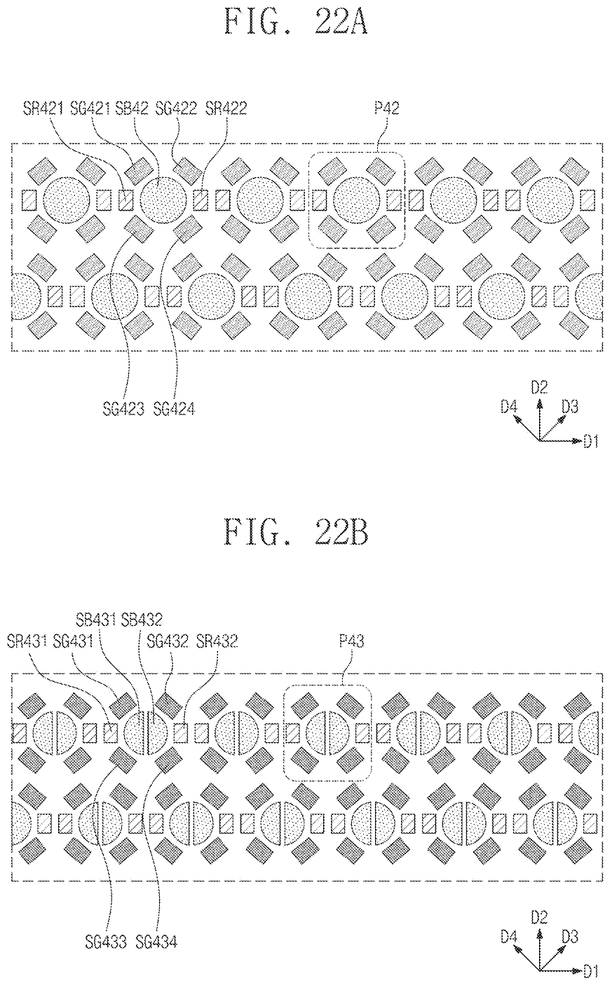

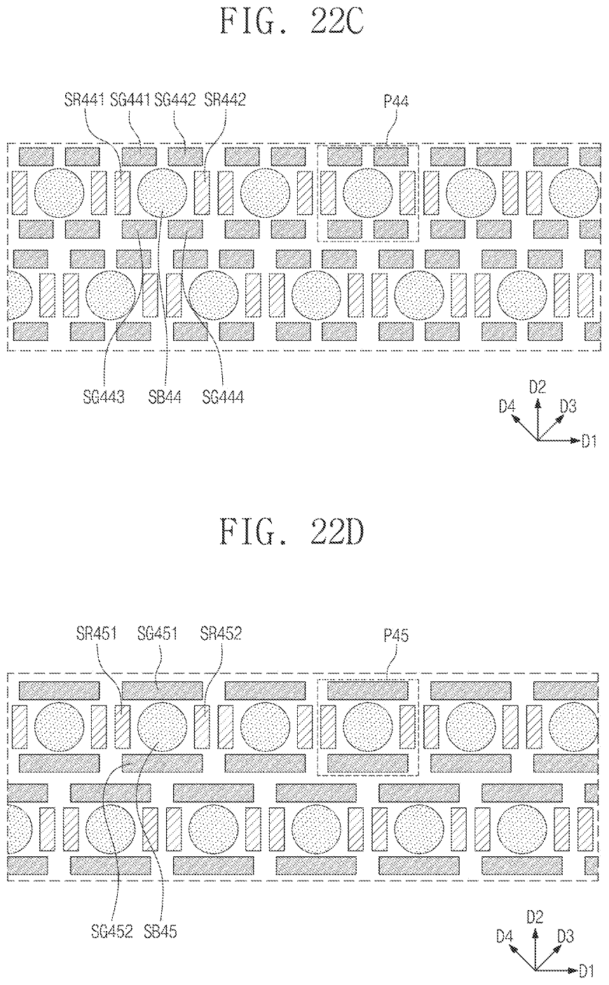

FIG. 22A to FIG. 22D are plan views illustrating pixel structures according to one or more embodiments of the present disclosure. For convenience of illustration, FIG. 22A to FIG. 22D illustrate partial regions. Hereinafter, embodiments of the present disclosure will be described with reference to FIG. 22A to FIG. 22D.

As illustrated in FIG. 22A, a unit pixel P42 may be composed of two red sub-pixels SR421 and SR422, four green sub-pixels SG421, SG422, SG423, and SG424, and one blue sub-pixel SB42. The blue sub-pixel SB42 may have a circular shape. The blue sub-pixel SB42 may be disposed in the center of the unit pixel P42.

The red sub-pixels SR421 and SR422 and the green sub-pixels SG421, SG422, SG423, and SG424 may be arranged to be spaced apart from each other along the edge of the blue sub-pixel SB42. The red sub-pixels SR421 and SR422 are disposed to be spaced apart from each other in the first direction D1, with the blue sub-pixel SB42 interposed therebetween. The red sub-pixels SR421 and SR422 may be in a relationship line-symmetrical to each other. For example, the red sub-pixels SR421 and SR422 may each have a quadrangular shape, and may be line-symmetrical to each other with respect to a symmetry axis, which is extended along the second direction D2 and passes through the center of the unit pixel P42.

The green sub-pixels SG421, SG422, SG423, and SG424 are disposed to be spaced apart from each other in the second direction D2, with the blue sub-pixel SB42 interposed therebetween. For example, from among the green sub-pixels SG421, SG422, SG423, and SG424, two sub-pixels SG421 and SG422 are disposed on an upper side of the blue sub-pixel SB42, and spaced apart from each other in the first direction D1. The two sub-pixels SG421 and SG422 may be in a relationship line-symmetrical to each other with respect to the symmetry axis.

The other two sub-pixels SG423 and SG424 of the green sub-pixels SG421, SG422, SG423, and SG424 are disposed on a lower side of the blue sub-pixel SB42, and spaced apart from each other in the first direction D1. The two sub-pixels SG423 and SG424 may be in a relationship line-symmetrical to each other with respect to the symmetry axis. The unit pixels P42 are arranged along the first direction D1, and may be arranged by being shifted along the second direction D2.

As illustrated in FIG. 22B, a unit pixel P43 may be composed of two red sub-pixels SR431 and SR432, four green sub-pixels SG431, SG432, SG433, and SG434, and two blue sub-pixels SB431 and SB432. There may be a difference between the unit pixel P42 illustrated in FIG. 22A and the unit pixel P43 in the blue sub-pixels SB431 and SB432.

The red sub-pixels SR431 and SR432, and the green sub-pixels SG431, SG432, SG433, and SG434 may correspond to the red sub-pixels SR421 and SR422 and the green sub-pixels SG421, SG422, SG423, and SG424, which are illustrated in FIG. 22A. Therefore, redundant description thereof may not be repeated.

The blue sub-pixels SB431 and SB432 are arranged along the first direction D1. The blue sub-pixels SB431 and SB432 may be in a relationship line-symmetrical to each other. For example, the blue sub-pixels SB431 and SB432 may each have a semi-circular shape, and may be line-symmetrical to each other with respect to a symmetry axis, which is extended along the second direction D2 and passes through the center of the unit pixel P43.

The blue sub-pixels SB431 and SB432 may correspond to a structure in which the blue sub-pixel SB42 illustrated in FIG. 22A is divided. The unit pixel P43 includes divided blue sub-pixels SB431 and SB432, and thus, may drive each of sub-pixels independently.

As illustrated in FIG. 22C, a unit pixel P44 may be composed of two red sub-pixels SR441 and SR442, four green sub-pixels SG441, SG442, SG443, and SG444, and one blue sub-pixel SB44. The blue sub-pixel SB44 may have a circular shape. The blue sub-pixel SB44 may be disposed in the center of the unit pixel P44.

The red sub-pixels SR441 and SR442 are disposed to be spaced apart from each other in the first direction D1, with the blue sub-pixel SB44 interposed therebetween. The red sub-pixels SR441 and SR442 may be in a relationship line-symmetrical to each other. For example, the red sub-pixels SR441 and SR442 may each have a quadrangular shape, and may be line-symmetrical to each other with respect to a symmetry axis, which is extended along the second direction D2 and passes through the center of the unit pixel P44.

The green sub-pixels SG441, SG442, SG443, and SG444 are disposed to be spaced apart from each other in the second direction D2, with the blue sub-pixel SB44 interposed therebetween. For example, from among the green sub-pixels SG441, SG442, SG443, and SG444, two sub-pixels SG441 and SG442 are disposed on an upper side of the blue sub-pixel SB44, and spaced apart from each other in the first direction D1. The two sub-pixels SG441 and SG442 may be in a relationship line-symmetrical to each other with respect to the symmetry axis. The two sub-pixels SG441 and SG442 may each have a rectangular shape, with long sides extended along the first direction D1 and short sides extended along the second direction D2.

The other two sub-pixels SG443 and SG444 of the green sub-pixels SG441, SG442, SG443, and SG444 are disposed on a lower side of the blue sub-pixel SB44, and spaced apart from each other in the first direction D1. The two sub-pixels SG443 and SG444 may be in a relationship line-symmetrical to each other with respect to the symmetry axis. The two sub-pixels SG443 and SG444 may each have a rectangular shape, with long sides extended along the first direction D1 and short sides extended in the second direction D2. The unit pixels P44 are arranged along the first direction D1, and may be arranged by being shifted along the second direction D2.

As illustrated in FIG. 22D, a unit pixel P45 may be composed of two red sub-pixels SR451 and SR452, two green sub-pixels SG451 and SG452, and one blue sub-pixel SB45.

The blue sub-pixel SB45 may have a circular shape disposed in the center of the unit pixel P45. The red sub-pixels SR451 and SR452 may be disposed to be spaced apart from each other in the first direction D1, with the blue sub-pixel SB45 interposed therebetween. The red sub-pixels SR451 and SR452 may be rectangular shapes, which are in a relationship line-symmetrical to each other.

The green sub-pixels SG451 and SG452 may be disposed to be spaced each apart from each other in the second direction D2, with the blue sub-pixel SB45 interposed therebetween. The green sub-pixels SG451 and SG452 may be rectangular shapes, which are in a relationship line-symmetrical to each other.

According to an embodiment of the present embodiment, a blue light emission region may be disposed in a single large area, or may be divided and provided, and disposed to be gathered in a central region of a unit pixel. This may be pixel structures designed to allow a blue light emission region to be prominently visually recognized relative to other color regions. Accordingly, a blue light emission region with relatively low luminescence efficiency may be provided to be relatively large, so that the color reproducibility of a display panel may be improved.

In addition, according to an embodiment of the present disclosure, green sub-pixels may be spaced apart from each other and symmetrically disposed. Accordingly, a green light emission region with relatively high visibility may be dispersed to allow the green light emission region to be evenly distributed in the unit pixel. Therefore, a display panel with improved color reproducibility may be provided. A display panel according to an embodiment of the present disclosure may include various suitable pixel structures, and is not limited to any one embodiment.

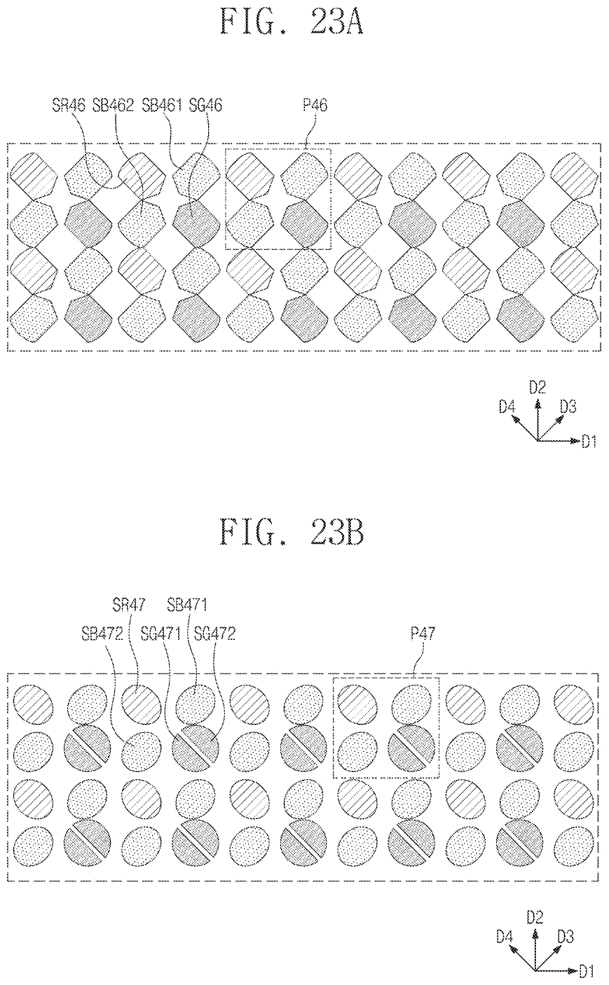

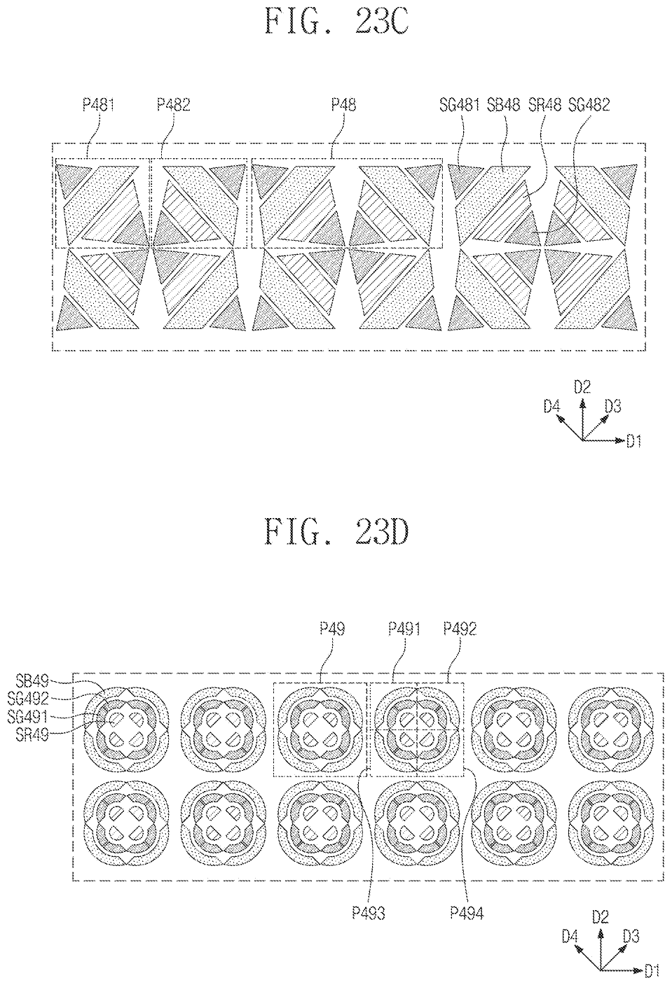

FIG. 23A to FIG. 23D are plan views illustrating pixel structures according to one or more embodiments of the present disclosure. For convenience of illustration, FIG. 23A to FIG. 23D illustrate partial regions. Hereinafter, embodiments of the present disclosure will be described with reference to FIG. 23A to FIG. 23D.

As illustrated in FIG. 23A, a unit pixel P46 may be composed of one red sub-pixel SR46, one green sub-pixel SG46, and two blue sub-pixels SB461 and SB462. The unit pixel P46 may have a square shape. A plurality of unit pixels P46 may be arranged in a matrix form along the first direction D1 and the second direction D2.

The red sub-pixel SR46 and the green sub-pixel SG46 may be in a relationship 180-degree point-symmetrical to each other. In addition, the red sub-pixel SR46 and the green sub-pixel SG46 may be in a relationship line-symmetrical to each other with respect to a virtual line extended along the third direction D3. The blue sub-pixels SB461 and SB462 may be in a relationship 180-degree point-symmetrical to each other. In addition, the blue sub-pixels SB461 and SB462 may be in a relationship line-symmetrical to each other with respect to a virtual line extended along the fourth direction D4.

The blue sub-pixels SB461 and SB462 may be in a relationship line-symmetrical to the red sub-pixel SR46 and the green sub-pixel SG46. In more detail, a first sub-pixel SB461 of the blue sub-pixels SB461 and SB462 and the green sub-pixel SG46 may be in a relationship line-symmetrical to each other with respect to a symmetry axis extended along the first direction D1. In addition, the first sub-pixel SB461 and the red sub-pixel SR46 may be in a relationship line-symmetrical to each other with respect to a symmetry axis extended along the second direction D2.

A second sub-pixel SB462 of the blue sub-pixels SB461 and SB462 and the green sub-pixel SG46 may be in a relationship line-symmetrical to each other with respect to a symmetry axis extended along the second direction D2. In addition, the second sub-pixel SB462 and the red sub-pixel SR46 may be in a relationship line-symmetrical to each other with respect to a symmetry axis extended along the first direction D1.

As illustrated in FIG. 23B, a unit pixel P47 may be composed of one red sub-pixel SR47, two green sub-pixels SG471 and SG472, and two blue sub-pixels SB471 and SB472. The red sub-pixel SR47 may have an elliptical shape. The blue sub-pixels SB471 and SB472 are disposed along the third direction D3. The blue sub-pixels SB471 and SB472 may be elliptical shapes, which are in a relationship line-symmetrical to each other with respect to a symmetry axis extended along the fourth direction D4.

The green sub-pixels SG471 and SG472 are disposed to be spaced apart from the red sub-pixel SR47 in the third direction D3. The green sub-pixels SG471 and SG472 may each have a semi-circular shape. However, the present disclosure is not limited thereto, and the green sub-pixels SG471 and SG472 may each have a semi-elliptical shape, and are not limited to any one embodiment.

As illustrated in FIG. 23C, a unit pixel P48 may include a first unit P481 and a second unit P482, which are arranged along the first direction D1. The unit pixel P48 has a rectangular shape, and the first and second units P481 and P482 may each have a roughly square shape. The unit pixel P48 may be provided in a plurality, and arranged in a matrix form along the first direction D1 and the second direction D2.

The first unit P481 may be composed of one red sub-pixel SR48, two green sub-pixels SG481 and SG482, and one blue sub-pixel SB48. The red sub-pixel SR48 may have a trapezoidal shape, with a base extended along the third direction D3 and a height extended along the fourth direction D4. The blue sub-pixel SB48 may have a trapezoidal shape, with a base extended along the third direction D3 and a height extended along the fourth direction D4. The blue sub-pixel SB48 is disposed to be spaced apart from the red sub-pixel SR48 in the fourth direction D4.

The green sub-pixels SG481 and SG482 may be disposed to be spaced apart from each other in the fourth direction D4, with the red sub-pixel SR48 and the blue sub-pixel SB48 interposed therebetween. The green sub-pixels SG481 and SG482 may be in a relationship line-symmetrical to each other with respect to a symmetry axis extended along the third direction D3. For example, the green sub-pixels SG481 and SG482 may each have a triangular shape.

The second unit P482 may be in a relationship line-symmetrical to the first unit P481. Therefore, sub-pixels constituting the second unit P482 may have shapes in which the red sub-pixel SR48, the green sub-pixels SG481 and SG482, and the blue sub-pixels SB48 are each line-symmetrical with respect to a symmetry axis extended along the second direction D2.

As illustrated in FIG. 23D, a unit pixel P49 may have a square shape, and may be provided in a plurality and arranged in a matrix form along the first direction D1 and the second direction D2. The unit pixel P49 may include first to fourth units P491, P492, P493, and P494.

The first unit P491 may include one red sub-pixel SR49, two green sub-pixels SG491 and SG492, and one blue sub-pixel SB49. The red sub-pixel SR49, the green sub-pixels SG491 and SG492, and the blue sub-pixel SB49 are arranged along the fourth direction D4 from the center of the unit pixel P49.

The red sub-pixel SR49 may be most adjacent to the center of the unit pixel P49 in the first unit P491. The red sub-pixel SR49 may have a roughly semi-circular shape. The red sub-pixel SR49 may include a straight side disposed in parallel or substantially in parallel to the third direction D3.

The green sub-pixels SG491 and SG492 are disposed along the third direction D3. For example, from among the green sub-pixels SG491 and SG492, a first green sub-pixel SG491 may be disposed further to the left than a second green sub-pixel SG492. The green sub-pixels SG491 and SG492 may be disposed along a circular arc of the red sub-pixel SR49. The green sub-pixels SG491 and SG492 may correspond to a portion of a fan shape.

The blue sub-pixel SB49 is spaced apart from the red sub-pixel SR49 in the fourth direction D4, with the green sub-pixels SG491 and SG492 interposed therebetween. The blue sub-pixel SB49 may be disposed farthest from the center of the unit pixel P49 from among the sub-pixels in the unit pixel P49.

The blue sub-pixel SB49 may have a shape surrounding (e.g., around a periphery of) a circular arc side of the green sub-pixels SG491 and SG492. The blue sub-pixel SB49 may have a shape defined by a curve facing the green sub-pixels SG491 and SG492, another curve opposing thereto, and two straight lines connecting the curves.

The second unit P492 may be in a relationship line-symmetrical to the first unit P491 with respect to a symmetry axis extended along the second direction D2. The third unit P493 may be in a relationship line-symmetrical to the first unit P491 with respect to a symmetry axis extended along the first direction D1. The fourth unit P494 may be in a relationship 180-degree point-symmetrical to the first unit P491. In addition, the fourth unit P494 may be in a relationship line-symmetrical to the second unit P492 or the third unit P493.

In a pixel structure according to an embodiment of the present disclosure, a blue light emission region may have an area relatively larger than the area of the red light emission region. Accordingly, a blue light emission region with relatively low luminescence efficiency may be provided to be relatively large, so that the color reproducibility of a display panel may be improved.

In addition, a green light emission region with relatively high visibility may be dispersed to allow the green light emission region to be evenly distributed in a unit pixel. Therefore, a display panel with improved color reproducibility may be provided. A display panel according to an embodiment of the present disclosure may include various suitable pixel structures, and is not limited to any one embodiment.

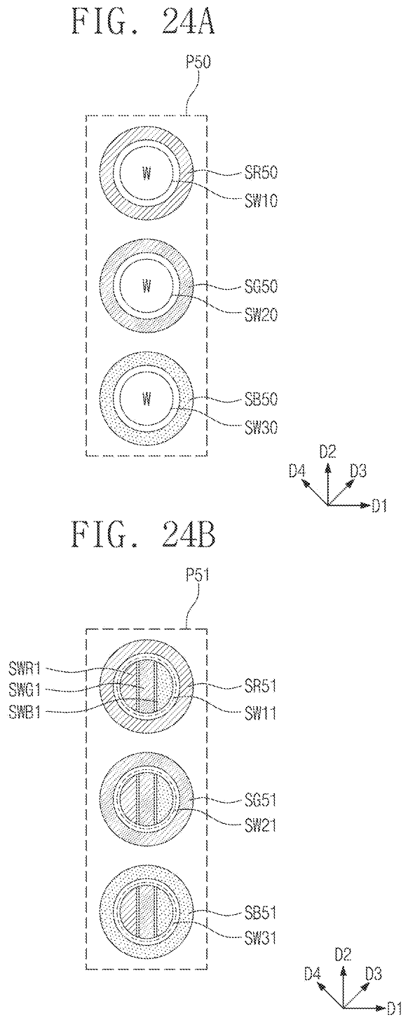

FIG. 24A and FIG. 24B are plan views illustrating unit pixels according to one or more embodiments of the present disclosure. For convenience of illustration, FIG. 24A and FIG. 24B illustrate a unit pixel. Hereinafter, embodiments of the present disclosure will be described with reference to FIG. 24A and FIG. 24B.

As illustrated in FIG. 24A, a unit pixel P50 may be composed of a red sub-pixel SR50, a green sub-pixel SG50, a blue sub-pixel SB50, and three white sub-pixels SW10, SW20, and SW30. The red sub-pixel SR50, the green sub-pixel SG50, and the blue sub-pixel SB50 may be arranged in parallel or substantially in parallel to the second direction D2. The three white sub-pixels SW10, SW20, and SW30 may be spaced apart from each other, and also may be arranged in parallel or substantially in parallel to the second direction D2.

The red sub-pixel SR50, the green sub-pixel SG50, and the blue sub-pixel SB50 may each have a circular ring shape. The three white sub-pixels SW10, SW20, and SW30 may each have a circular shape.

In more detail, the red sub-pixel SR50 may have a circular ring shape surrounding (e.g., around a periphery of) the edge of a first sub-pixel SW10 from among the white sub-pixels SW10, SW20, and SW30. The green sub-pixel SG50 may have a circular ring shape surrounding (e.g., around a periphery of) the edge of a second sub-pixel SW20 from among the white sub-pixels SW10, SW20, and SW30. In a similar manner, the blue sub-pixel SB50 may have a circular ring shape surrounding (e.g., around a periphery of) the edge of a third sub-pixel SW30 from among the white sub-pixels SW10, SW20, and SW30.

Referring to FIG. 24B, a unit pixel P51 may include white sub-pixels SW11, SW21, and SW31, which respectively include red, green, and blue light emission patterns. In more detail, the unit pixel P51 includes a red sub-pixel SR51, a green sub-pixel SG51, and a blue sub-pixel SB51, which respectively correspond to the red sub-pixel SR50, the green sub-pixel SG50, and the blue sub-pixel SB50 illustrated in FIG. 24A, and thus, redundant description thereof may not be repeated.

The white sub-pixels SW11, SW21, and SW31 are disposed at positions respectively corresponding to the red sub-pixel SR51, the green sub-pixel SG51, and the blue sub-pixel SB51. The white sub-pixels SW11, SW21, and SW31 may each include a red light emission region SWR1, a green light emission region SWG1, and a blue light emission region SWB1. The red light emission region SW R1, the green light emission region SWG1, and the blue light emission region SWB1 are disposed by dividing respective regions of the white sub-pixels SW11, SW21, and SW31. In the present embodiment, the red light emission region SWR1, the green light emission region SWG1, and the blue light emission region SWB1 may be arranged along the first direction D1, so as not to overlap with each other in a region having a circular shape.

However, the present disclosure is not limited thereto. In a display panel according to an embodiment of the present disclosure, as long as white sub-pixels SW10, SW20, SW30, SW11, SW21, and SW31 may be emitted in substantially a white color, light emission regions may be provided in various suitable combinations of shapes and colors. In other words, the area ratio of the red light emission region SWR1, the green light emission region SWG1, and the blue light emission region SWB1 may be variously designed, as long as a white color may be emitted.

As long as white sub-pixels SW10, SW20, SW30, SW11, SW21, and SW31 may be emitted in substantially a white color, the white sub-pixels SW10, SW20, SW30, SW11, SW21, and SW31 may include a light emission element having a tandem structure in which a plurality of light emission layers are laminated, and are not limited to any one embodiment.

According to an embodiment of the present disclosure, a pixel structure including red, green, and blue sub-pixels further includes a white sub-pixel, so that a display panel with improved color reproducibility may be provided. In addition, the design of a white sub-pixel is not limited to any one embodiment, and may be designed through various suitable combinations, so that the degree of design freedom may be improved.

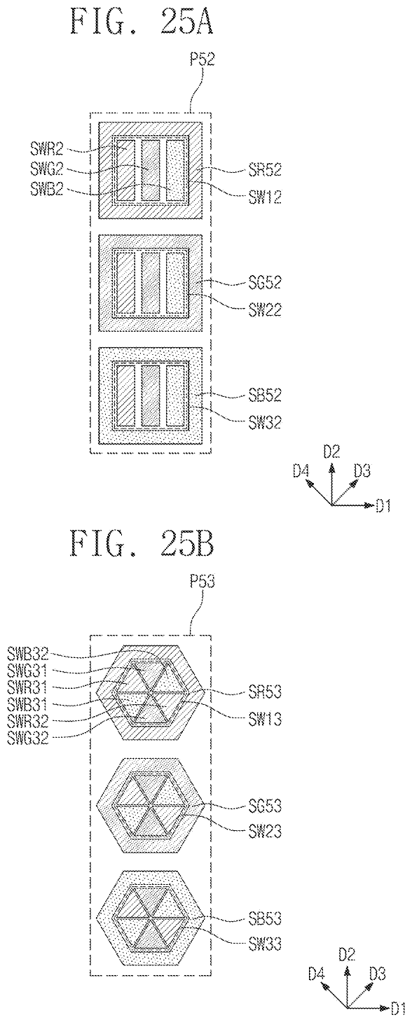

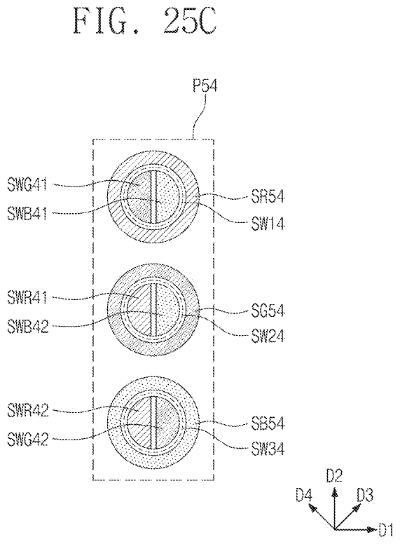

FIG. 25A to FIG. 25C are plan views illustrating unit pixels according to one or more embodiments of the present disclosure. For convenience of illustration, FIG. 25A to FIG. 25C illustrate a region corresponding to that of FIG. 24A. Hereinafter, embodiments of the present disclosure will be described with reference to FIG. 25A to FIG. 25C.

As illustrated in FIG. 25A, a unit pixel P52 may include white sub-pixels SW12, SW22, and SW32 in a quadrangular shape. Accordingly, a red sub-pixel SR52, a green sub-pixel SG52, and a blue sub-pixel SB52 may each have a quadrangular ring shape.

In more detail, the white sub-pixels SW12, SW22, and SW32 may each provide a white light emission region in a quadrangular shape. Accordingly, a red light emission region SWR2, a green light emission region SWG2, and a blue light emission region SWB2 may each have a quadrangular shape, and be disposed in a white light emission region. The red sub-pixel SR52, the green sub-pixel SG52, and the blue sub-pixel SB52 may each have a quadrangular ring shape surrounding (e.g., around a periphery of) a corresponding white sub-pixel from among the white sub-pixels SW12, SW22, and SW32.

As illustrated in FIG. 25B, a unit pixel P53 may include white sub-pixels SW13, SW23, and SW33 in a hexagonal shape. Accordingly, a red sub-pixel SR53, a green sub-pixel SG53, and a blue sub-pixel SB53 may each have a hexagonal ring shape.

In more detail, the white sub-pixels SW13, SW23, and SW33 may each provide a white light emission region in a hexagonal shape. In the white light emission region, two red light emission regions SWR31 and SWR32, two green light emission regions SWG2, and two blue light emission regions SWB2 may be disposed. The red light emission regions SWR31 and SWR32, the green light emission regions SWG2, and the blue light emission regions SWB2 may each have a triangular shape, and light emission regions of the same color may be symmetrically disposed to each other. The red sub-pixel SR53, the green sub-pixel SG53, and the blue sub-pixel SB53 each have a hexagonal ring shape surrounding (e.g., around a periphery of) a corresponding white sub-pixel from among the white sub-pixels SW13, SW23, and SW33.

As illustrated in FIG. 25C, a unit pixel P54 may include white sub-pixels SW14, SW24, and SW34 in a circular shape. The unit pixel P54 has a shape similar to the shape of the unit pixel P51 illustrated in FIG. 24B, except for differences in configurations of the white sub-pixels SW14, SW24, and SW34. In more detail, the red sub-pixel SR54, the green sub-pixel SG54, and the blue sub-pixel SB54 may each have a circular ring shape. The red sub-pixel SR54, the green sub-pixel SG54, and the blue sub-pixel SB54 respectively correspond to the red sub-pixel SR51, the green sub-pixel SG51, and the blue sub-pixel SB51, which are illustrated in FIG. 24B, and thus, redundant description thereof may not be repeated.

The white sub-pixels SW14, SW24, and SW34 may each provide a white light emission region in a circular shape. In this case, the white light emission region may be divided into light emission regions of only two colors, unlike in the embodiment of FIG. 24B. In more detail, a first sub-pixel SW14 may be composed of a green light emission region SWG41 of a semi-circular shape and a blue light emission region SWB41 of a semi-circular shape. The two light emission regions SWG41 and SWB41 may be in a relationship line-symmetrical to each other with respect to an axis extended along the second direction D2.

A second sub-pixel SW24 may be composed of a red light emission region SWR41 of a semi-circular shape and a blue light emission region SWB42 of a semi-circular shape. The two light emission regions SWR41 and SWB42 may be in a relationship line-symmetrical to each other with respect to an axis extended along the second direction D2.

A third sub-pixel SW34 may be composed of a red light emission region SWR42 of a semi-circular shape and a green light emission region SWG42 of a semi-circular shape. The two light emission regions SWR42 and SWG42 may be in a relationship line-symmetrical to each other with respect to an axis extended along the second direction D2.

According to an embodiment of the present disclosure, the white sub-pixels SW14, SW24, and SW34 are each composed of light emission regions of colors other than the colors of sub-pixels surrounding (e.g., around peripheries of) the edges thereof, so that a display panel in which a white color is emitted by the white sub-pixels SW14, SW24, and SW34 together with the red sub-pixel SR54, the green sub-pixel SG54, and the blue sub-pixel SB54 is provided. Accordingly, the color reproducibility of the display panel may be improved.

A display panel according to an embodiment of the present disclosure may include various suitable pixel structures, and is not limited to any one embodiment.

According to embodiments of the present disclosure, a display panel with improved color reproducibility and increased light efficiency may be provided. Accordingly, the display panel may have improved visibility and improved display properties.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a plurality of unit pixels, each of the plurality of unit pixels comprising a plurality of sub-pixels,
wherein:
each of the sub-pixels comprises a light emission pattern configured to emit light;
the sub-pixels of one of the unit pixels comprise one red sub-pixel, one blue sub-pixel, and two green sub-pixels;
each of the blue sub-pixel and the red sub-pixel has a triangular shape; and
a light emission area of each of the green sub-pixels is smaller than a light emission area of the blue sub-pixel.

2. The display panel of claim 1, wherein the blue sub-pixel and at least one of the green sub-pixels comprise sides facing each other, and the sides are parallel to each other.

3. The display panel of claim 2, wherein the blue sub-pixel has a right triangle shape.

4. The display panel of claim 2, wherein the green sub-pixels have shapes line-symmetrical to each other.

5. The display panel of claim 2, wherein the green sub-pixels have the same shape as each other.

6. The display panel of claim 2, wherein each of the green sub-pixels has a triangular shape.

7. The display panel of claim 2, wherein the red sub-pixel and the blue sub-pixel have the same shape as each other.

8. The display panel of claim 1, wherein the blue sub-pixel and the red sub-pixel have shapes point-symmetrical to each other.

9. The display panel of claim 8, wherein the green sub-pixels have quadrangular shapes that are in a relationship line-symmetrical to each other.

10. The display panel of claim 8, wherein the green sub-pixels have different areas from each other.

11. The display panel of claim 10, wherein each of the green sub-pixels has a rectangular shape having long sides extending in one direction.

12. The display panel of claim 1, wherein the unit pixels are located along a diagonal direction.

13. The display panel of claim 12, wherein the green sub-pixels comprise a first sub-pixel and a second sub-pixel located along one direction crossing the diagonal direction,
wherein the first sub-pixel and a blue sub-pixel of another adjacent unit pixel are located along the diagonal direction, and
wherein the first sub-pixel and a red sub-pixel of another adjacent unit pixel are located along a direction perpendicular to the diagonal direction.

14. A display panel comprising:
a plurality of unit pixels, each of the unit pixels comprising a plurality of sub-pixels,
wherein:
each of the sub-pixels comprises a light emission pattern configured to emit light;
the sub-pixels of one of the unit pixels comprise one red sub-pixel, one green sub-pixel, one blue sub-pixel, and three white sub-pixels; and
the red sub-pixel, the green sub-pixel, and the blue sub-pixel respectively surround the white sub-pixels.

15. The display panel of claim 14, wherein each of the white sub-pixels comprises a red light emission region, a green light emission region, and a blue light emission region.

16. The display panel of claim 15, wherein the red sub-pixel, the green sub-pixel, and the blue sub-pixel are located along one direction, and the red light emission region, the green light emission region, and the blue light emission region are located along another direction crossing the one direction.

17. The display panel of claim 14, wherein each of the white sub-pixels comprises two light emission regions, and
wherein the two light emission regions have a color different from a color of a surrounding sub-pixel from among the red sub-pixel, the green sub-pixel, and the blue sub-pixel.

18. The display panel of claim 14, wherein each of the white sub-pixels comprises a light emission element comprising a plurality of light emission patterns that overlap with each other.

19. The display panel of claim 14, wherein each of the white sub-pixels has a circular shape, and each of the red sub-pixel, the green sub-pixel, and the blue sub-pixel has a circular ring shape.

20. The display panel of claim 14, wherein each of the white sub-pixels has a polygonal shape, and each of the red sub-pixel, the green sub-pixel, and the blue sub-pixel has a polygonal ring shape.
